(19) United States
(12) Patent Application Publication
(10) Pub. No.: US 2008/0219816 A1
(43) Pub. Date: Sep. 11, 2008

(54) SMALL LOT LOADPORT CONFIGURATIONS

(76) Inventors: Michael R. Rice, Pleasanton, CA (US); Jeffrey C. Hudgens, San Francisco, CA (US); Vinay K. Shah, San Mateo, CA (US)

Correspondence Address: DUGAN & DUGAN, PC, 245 Saw Mill River Road, Suite 309, Hawthorne, NY, 10532, US

(21) Appl. No.: 12/026,452

(22) Filed: Feb. 5, 2008

Related U.S. Application Data
(63) Continuation-in-part of application No. 11/051,504, filed on Feb. 4, 2005.
Application No. 11/051,504 is a continuation-in-part of application No. 10/764,820, filed on Jan. 26, 2004.
(60) Provisional application No. 60/888,294, filed on Feb. 5, 2007.
(60) Provisional application No. 60/542,519, filed on Feb. 5, 2004.
(60) Provisional application No. 60/443,153, filed on Jan. 27, 2003.

(51) Int. Cl. H01L 21/677

(52) U.S. Cl. 414/277; 414/800

(57) ABSTRACT

A substrate handling apparatus and method include a small lot loadport configuration having a plurality of small lot loadports adapted to be coupled to an equipment front end module (EFEM) designed for use with a large lot substrate carrier and having a large lot loadport envelope, where the small lot loadport configuration has a combined envelope substantially similar to the large lot loadport envelope, and where each small lot loadport is adapted to dock with a small lot substrate carrier. A system also is provided that includes (1) the (EFEM) and (2) the small lot loadport configuration. Numerous other aspects are provided.

This application claims priority from U.S. provisional application Ser. No. 60/888,294, filed Feb. 5, 2007, and titled “METHODS AND APPARATUS FOR USING SMALL LOT LOADPORTS” (Attorney Docket No. 11855/L/SYNX/SYNX/HMM). This application also is a continuation-in-part of U.S. patent application Ser. No. 11/051,504, filed Feb. 4, 2005, and titled “SMALL LOT SIZE SUBSTRATE CARRIER” (Attorney Docket No. 8092/P01/SYNX/JW), which claims priority from U.S. Provisional Patent Application Ser. No. 60/542,519, filed Feb. 5, 2004 and is also a continuation-in-part of U.S. patent application Ser. No. 10/764,820, filed Jan. 26, 2004 and titled “OVERHEAD TRANSFER FLANGE AND SUPPORT FOR SUSPENDING A SUBSTRATE CARRIER” (Attorney Docket No. 8092), which claims priority from U.S. provisional application Ser. No. 60/443,153, filed Jan. 27, 2003 and titled “OVERHEAD TRANSFER FLANGE AND SUPPORT FOR SUSPENDING WAFER CARRIER” (Attorney Docket No. 8092/L). The content of each of the above patent applications is hereby incorporated by reference herein in its entirety.

### CROSS REFERENCE TO RELATED APPLICATIONS

The present application is related to the following commonly-assigned, co-pending U.S. patent applications, each of which is hereby incorporated by reference herein in its entirety:

U.S. patent application Ser. No. 10/650,310, filed Aug. 28, 2003, and titled “System For Transporting Substrate Carriers” (Attorney Docket No. 6900);

U.S. patent application Ser. No. 10/764,982, filed Jan. 26, 2004, and titled “Methods and Apparatus for Transporting Substrate Carriers” (Attorney Docket No. 7163);

U.S. patent application Ser. No. 10/650,480, filed Aug. 28, 2003, and titled “Substrate Carrier Handler That Unloads Substrate Carriers Directly From a Moving Conveyor” (Attorney Docket No. 7676); and

U.S. patent application Ser. No. 10/988,175, filed Nov. 12, 2004, and titled “Kinematic Pin With Shear Member And Substrate Carrier For Use Therewith” (Attorney Docket No. 8119).

### FIELD OF THE INVENTION

The present invention relates generally to semiconductor device manufacturing, and more particularly to small lot loadport configurations.

### BACKGROUND OF THE INVENTION

Semiconductor devices are made on substrates, such as silicon substrates, glass plates, etc., for use in computers, monitors, and the like. These devices are made by a sequence of fabrication steps, such as thin film deposition, oxidation or nitridization, etching, polishing, and thermal and lithographic processing. Although multiple fabrication steps may be performed in a single processing station, substrates typically must be transported between processing stations for at least some of the fabrication steps.

Substrates generally are stored in cassettes or pods (hereinafter referred to collectively as “substrate carriers”) for transfer between processing stations and other locations. Although substrate carriers may be carried manually between processing stations, the transfer of substrate carriers is typically automated. Such a system commonly is called an Automated Material Handling System (AMHS). For instance, automatic handling of a substrate carrier may be performed by a robot, which lifts the substrate carrier by means of an end effector.

To gain access to substrates stored within a substrate carrier, a door of the substrate carrier may be opened via a door opening mechanism, typically positioned at a loadport of a processing tool. Door opening operations should be performed in a manner that is efficient and does not lead to contamination of substrates within the substrate carrier. Door opening operations hence may be automated and performed by an Equipment Front End Module (EFEM), for instance.

An EFEM may serve several functions, but any given EFEM, however, is designed to accommodate substrate carriers having defined specifications. Historically, many EFEMs were designed for use with large lot substrate carriers (e.g., having 13 to 25 substrate slots) and therefore had large lot loadports, i.e., loadports designed to accommodate large lot substrate carriers. An exemplary industry standard relating to large lot substrate carriers is the SEMI E63 Mechanical Specification for 300 mm Box Opener/Loader to Tool Standard (BOLTS) Interface.

A BOLTS interface for a large lot substrate carrier, e.g., a large lot loadport, generally will have a standard-sized envelope within which the large lot substrate carrier is processed. In this robotics context, “envelope” may be defined as the work area or volume of working or reaching space of the interface, e.g., loadport or end effector, whereas in a mechanical context, the “envelope” may be a solid representing all positions which may be occupied by an object, e.g., a substrate carrier, during its normal range of motion. Broadly speaking, because a loadport needs to be accessible by a substrate carrier, the loadport envelope may include the reaching space traversed during movement of the loadport and EFEM robotics, as well as the space traversed by the substrate carrier in its normal range of motion to and from the loadport, which more specifically is the substrate carrier envelope.

### SUMMARY OF THE INVENTION

In an exemplary embodiment of the invention, a system is provided that includes (1) an equipment front end module (EFEM) designed for use with a large lot substrate carrier and having a large lot loadport envelope; and (2) a small lot loadport configuration having a plurality of small lot loadports adapted to be coupled to the EFEM and having a combined envelope substantially similar to the large lot loadport envelope, each small lot loadport adapted to dock with a small lot substrate carrier.

In another exemplary embodiment of the invention, a small lot loadport configuration includes a plurality of small lot loadports adapted to be coupled to an EFEM designed for use with a large lot substrate carrier and having a large lot loadport envelope; the small lot loadport configuration having a combined envelope substantially similar to the large lot loadport envelope, each small lot loadport adapted to dock with a small lot substrate carrier.

In a further exemplary embodiment of the invention, a method is provided that includes docking of a small lot substrate carrier at a small lot loadport within a small lot loadport configuration coupled to an equipment front end module (EFEM) designed for use with a large lot substrate carrier and having a large lot loadport envelope, where the small lot loadport configuration includes a plurality of small lot loadports adapted to be coupled to the EFEM and has a combined envelope substantially similar to the large lot loadport envelope, where each small lot loadport is adapted to dock with a small lot substrate carrier. The method also may include undocking, opening and/or closing of the small lot substrate carrier by the small lot loadport.

Additional embodiments may also include a plurality of small lot carrier supports to support a plurality of small lot substrate carriers. A preferred exemplary embodiment of the present invention may include three small lot loadports within a small lot loadport configuration having a large lot loadport envelope.

Numerous other aspects are provided in accordance with these and other aspects of the invention. Other features and aspects of the present invention will become more fully apparent from the following detailed description, the appended claims and the accompanying drawings.

### BRIEF DESCRIPTION OF THE DRAWINGS

FIG. 1 is a perspective view of a portion of an overhead transfer conveyor, as the overhead transfer conveyor transports a first and a second carrier;

FIG. 2 is a perspective view, exploded along the in-line direction, of the assembly of the overhead carrier support and the overhead transfer flange shown in FIG. 1;

FIG. 3 is a bottom plan view, of the exploded assembly of the overhead carrier support and the overhead transfer flange shown in FIG. 2;

FIG. 4 is a bottom plan view of the exploded assembly of the overhead carrier support and the overhead transfer flange shown in FIG. 2;

FIGS. 5 and 6 are perspective views of respective portions of the first blade receiver of the overhead carrier support, and of the first blade of the overhead transfer flange (including cross-sections);

FIGS. 7-8 are simple cross-sectional views of the same portions of the overhead carrier support and the overhead transfer flange;

FIG. 9 is a perspective cut-away view of a portion of the overhead transfer conveyor of FIG. 1 utilizing the coupling between the overhead carrier support and the overhead transfer flange, wherein an object, present in the path through which the overhead transfer conveyor carries a carrier, strikes the carrier;

FIGS. 10-12 are cross-sectional views of respective portions of the first blade receiver of the overhead carrier support, and the first blade of the overhead transfer flange, which depict a decoupling process that results in a carrier dislodging from the overhead transfer conveyor of FIG. 1;

FIG. 13 is a cross sectional view of a portion of the first blade receiver of the overhead carrier support and of the first blade of the overhead transfer flange illustrating an alternative embodiment of such components;

FIG. 14 is a perspective view of a plurality of shelves configured to support substrate carriers via an overhead transfer flange in accordance with the present invention;

FIG. 15 is a perspective view of the shelves of FIG. 14 wherein the top shelf supports a substrate carrier via its overhead transfer flange;

FIG. 16A is an exemplary embodiment of a substrate carrier having an overhead transfer flange and that is adapted to transport a single substrate;

FIGS. 16B-D are exemplary embodiments of substrate carriers;

FIGS. 17A-L illustrate a first exemplary embodiment of a door opening mechanism for opening the door of a substrate carrier;

FIGS. 18A-L illustrate a second exemplary embodiment of a door opening mechanism for opening the door of a substrate carrier;

FIGS. 19A-19H illustrate an exemplary clamping mechanism that may be employed to secure a substrate carrier;

FIGS. 20A-B illustrate a third exemplary embodiment of a door opening mechanism for opening the door of a substrate carrier;

FIG. 21 is a side view illustrating a plurality of 4-substrate substrate carriers positioned within a standard Box Opener/Loader to Tool Standard (BOLTS) opening;

FIGS. 22A-E illustrate a fourth exemplary embodiment of a door opening mechanism for opening the door of a substrate carrier;

FIGS. 23A-23G illustrate various components of an exemplary substrate carrier;

FIG. 24 is a perspective view of an exemplary small lot loadport configuration having three small lot substrate carriers;

FIG. 25 is a side elevational representation of a small lot loadport configuration compared next to a large lot loadport dimensioned for a 25-substrate large lot substrate carrier;

FIGS. 26A and 26B are perspective views of exemplary small lot substrate carriers supported, respectively, from below and above, by corresponding substrate carrier supports;

FIGS. 27A-C, respectively, are planar, front elevational and side elevational views of a simplified small lot loadport configuration;

FIGS. 28A-F illustrate cross-sectional side elevational views of exemplary steps 1 to 6 of an exemplary small lot substrate carrier docking and opening sequence;

FIGS. 29A-C illustrate an exemplary door opening mechanism of a small lot substrate carrier;

FIGS. 30A and 30B illustrate, respectively, a front elevational view and a side elevational view of an exemplary small lot loadport configuration as it may mount on an equipment front end module;

FIG. 31 illustrates an enlarged cross-sectional side elevational view of a detail portion of FIG. 30B;

FIG. 32 depicts a cross-sectional side elevational view of exemplary small lot substrate carriers supported by shelves at various stages of docking at loadports on a small lot loadport configuration;

FIGS. 33A and 33B illustrate, respectively, a front exterior elevational view and a cross-sectional planar view of an exemplary carrier door and exemplary loadport port door interface designed to be FOUP-compatible;

FIGS. 34A and 34B illustrate, respectively, a rear interior elevational view and a cross-sectional planar view of the exemplary carrier door and exemplary loadport port door interface of FIGS. 33A and 33B;

FIG. 35 illustrates a front planar view of an exemplary kinematic pin support comprising a loadport shelf and kinematic coupling pins;

FIG. 36 illustrates a front elevational view of an exemplary loadport tunnel of the exemplary loadport of the exemplary small lot loadport configuration;

FIG. 37 illustrates an enlarged side elevational cross-sectional view of the loadport tunnel and an exemplary door opening mechanism associated with the loadport port door of FIG. 36;

FIG. 38 illustrates a front perspective view of the loadport tunnel, loadport port door and external aspects of the door opening mechanism of FIG. 36;

FIG. 39 illustrates a front perspective view of an exemplary small lot substrate carrier with enlarged cut-away views of carrier configuration features;

FIG. 40 illustrates a front perspective view and an enlarged cut-away view of an exemplary small lot loadport configuration and an exemplary small lot substrate carrier; and

FIG. 41 illustrates an enlarged cross-sectional side elevational view of the corresponding configuration feature.

### DETAILED DESCRIPTION

Advances in substrate processing have increased the attractiveness of using small lots (e.g., 12 or fewer substrates). As such, methods and apparatus for economically switching from large lot technology to small lot technology are desirable.

The present invention provides a small lot loadport configuration for use with an equipment front end module (EFEM) designed for use with a large lot substrate carrier and having a large lot loadport envelope. Other novel substrate carriers and loadport configurations are also provided.

Insofar as there currently are no industry standards that specifically address automated small lot material handling requirements, this application introduces concepts useful to define new exemplary specifications and requirements for a small lot substrate carrier and a small lot loadport that are compatible with a small lot Automated Material Handling System (AMHS). By way of example, when designed in accordance with SEMI standards, such as SEMI E1.9, a substrate carrier used to transfer and store 300 mm substrates is often known as a Front-Opening Unified Pod (FOUP). Whenever possible, existing standards are maintained in order to leverage the vast industry experience with large lot (e.g., 25-wafer) FOUP designs. In areas where existing standards are inadequate for small lot manufacturing, modifications to existing standards are introduced and incorporate many new methods that have been developed.

In the absence of existing semiconductor industry standards for a small lot loadport or small lot carriers, the following SEMI standards may be applied (in whole or in part) to the small lot loadport example requirements, to the extent that they do not conflict the nature and requirements of small lots and a small lot AMHS.
SEMI E1.9 Provisional Mechanical Specification for Cassettes Used to Transport and Store 300 mm Wafers
SEMI E15.1 Specification for 300 mm Tool Load Port
SEMI E47.1 Provisional Mechanical Specification for Boxes and PODS Used to Transport and Store 300 mm Wafers
SEMI E57 Mechanical Specification for Kinematic Couplings Used to Align and Support 300 mm Wafer Carriers
SEMI E62 Provisional Specification for 300 mm Front-Opening Interface Mechanical Standard (FIMS)
SEMI E63 Mechanical Specification for 300 mm Box Opener/Loader to Tool Standard (BOLTS-M) Interface
SEMI E64 Specification for 300 mm Cart to Semi E15.1 Docking Interface Port
SEMI E83 Specification for 300 mm PGV Mechanical Docking Flange
SEMI E92 Specification for 300 mm Light Weight and Compact Box Opener/Loader to Tool-Interoperability Standard (BOLTS/Light)
SEMI E99 The Carrier ID Reader/Writer Functional Standard: Specification of Concepts, Behavior, and Services
SEMI E103 Provisional Mechanical Specification for a 300 mm Single-Wafer Box System that Emulates a FOUP
SEMI E110 Guideline for Indicator Placement Zone and Switch Placement Volume of Load Port Operation Interface for 300 mm Load Ports
SEMI S2 Environmental, Health, and Safety Guideline for Semiconductor Manufacturing Equipment
SEMI S8 Safety Guidelines for Ergonomics Engineering of Semiconductor Manufacturing Equipment
SEMI S17 Safety Guideline for Unmanned Transport Vehicle (UTV) Systems

This document discloses example requirements for a loadport that is compatible with a small lot AMHS and teaches example requirements for a small lot FOUP. A small lot AMHS may employ the use of small lot FOUPs whose capacity is less than 25 or 13 wafers, e.g., 2 wafers, because cost, storage density, and other issues make it impractical to use partially-filled 25-wafer FOUPs in volume production. Therefore, a new small lot FOUP is presented, as well as a new loadport for opening and closing a small lot FOUP.

The small lot substrate carrier may be a single substrate carrier adapted to store only one substrate or a multiple substrate carrier adapted to store a plurality of substrates. In one aspect, the overhead support is adapted such that the support provides a capture window (for capturing the overhead transfer flange) that varies from a wider window to a narrower window in a direction in which the overhead transfer flange can approach the support. In a second aspect the overhead transfer flange and overhead support are adapted such that when the overhead transfer flange is supported by the overhead support, the overhead transfer flange is prevented from moving relative to the overhead support in any direction except vertically. In a further aspect the overhead transfer flange and overhead support are adapted such that if a substrate carrier supported thereby is impacted in a direction opposite to the direction in which the carrier is traveling, the carrier's overhead transfer flange will decouple from the overhead support, allowing the carrier to fall.

The figures and the following description thereof provide various configurations that may be used in accordance with the present invention. The configurations of the figures are merely exemplary and it will be understood that alternative configurations may be designed that function in accordance with the invention. Before discussing the specifics of the small lot loadport configuration, exemplary conveyor and substrate carrier configurations are discussed to put the small lot loadport configuration in context of the broader system. Aspects of the broader system, including the conveyor and substrate carrier, are covered under related patent applications.

### Overhead Transfer Conveyor

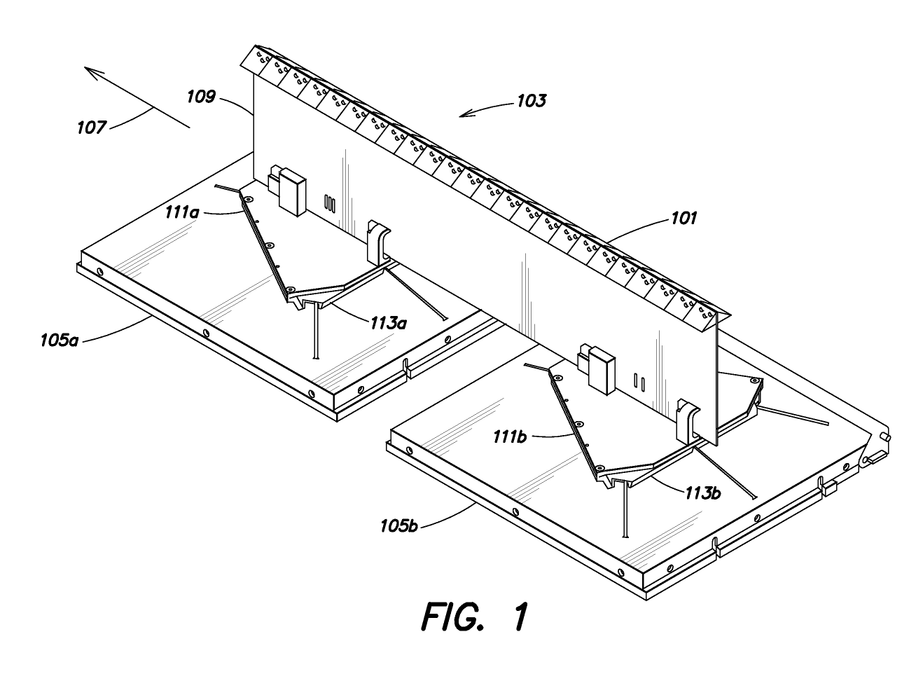

FIG. 1 is a perspective view of a portion 101 of an overhead transfer conveyor 103, as the overhead transfer conveyor 103 transports a first and a second carrier 105a, 105b in a first in-line direction 107 along a moveable track 109 of the overhead transfer conveyor 103. A first overhead carrier support 111a of the overhead transfer conveyor 103 supports the first carrier 105a via a first overhead transfer flange 113a fixed to and centered above the first carrier 105a, and a second overhead carrier support 111b of the overhead transfer conveyor 103 supports the second carrier 105b via a second overhead transfer flange 113b fixed to and centered above the second carrier 105b. Other positions of the overhead transfer flanges 113a, 113b relative to the substrate carriers 105a, 105b may be employed.

### Overhead Carrier Support & Overhead Transfer Flange

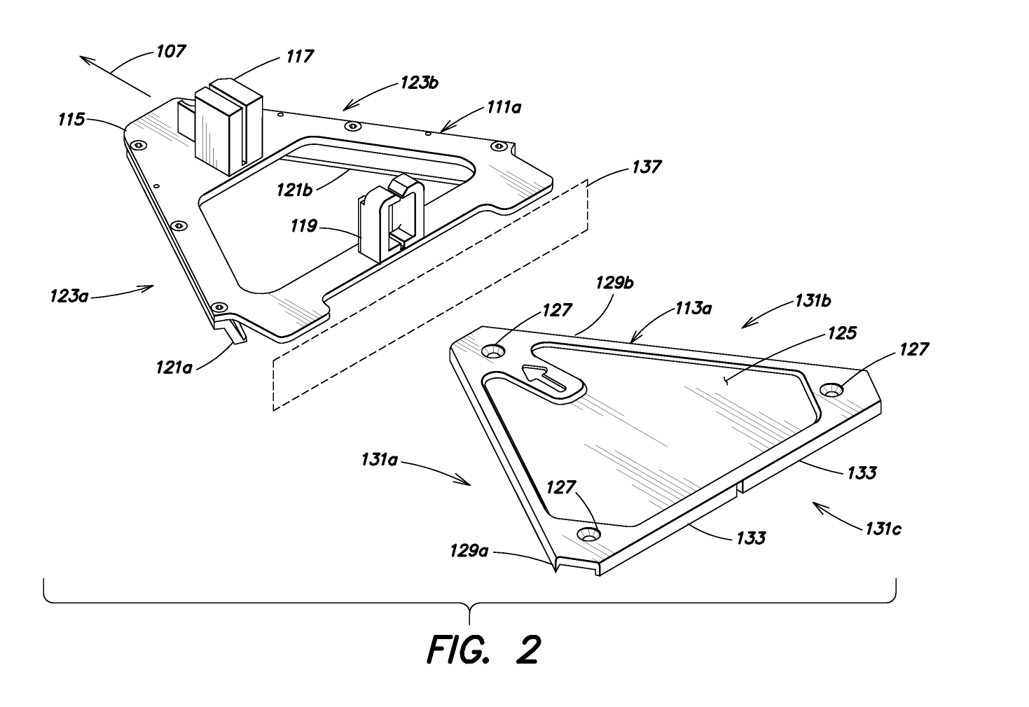

FIG. 2 is a perspective view, exploded along the in-line direction 107, of the assembly of the overhead carrier support 111a and the overhead transfer flange 113a shown in FIG. 1. The overhead carrier support 111a comprises a support plate 115 and a coupling clamp 117 fixed atop the support plate 115 and adapted to securely couple the overhead carrier support 111a to the moveable track 109 of the overhead transfer conveyor 103. The overhead carrier support 111a further includes a flexible hanger 119, also fixed atop the support plate 115, and adapted to provide additional support for the overhead carrier support 111a along the moveable track 109. A first blade receiver 121a is fixed below a first side 123a of the support plate 115, and a second blade receiver 121b is fixed below a second side 123b of the support plate 115, opposite the first side 123a. The various components of the overhead carrier support 111a may be coupled together using any suitable coupling mechanism (e.g., screws, bolts, adhesives, etc.). All or a portion of the components of the overhead carrier support 111a may be integrally formed.

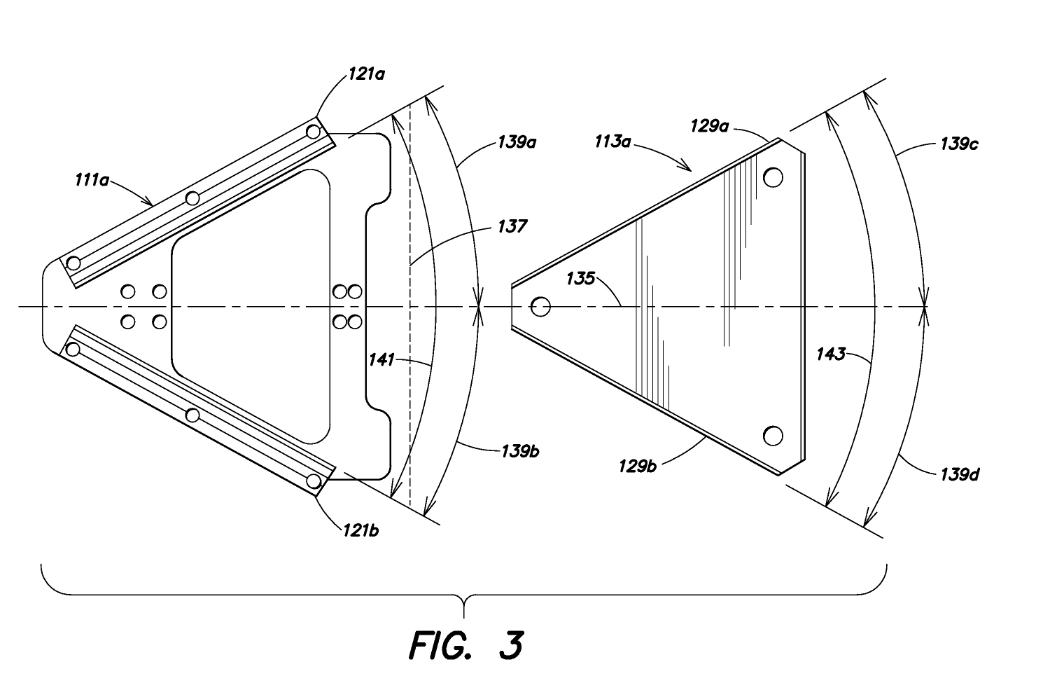

The overhead transfer flange 113a comprises a flange plate 125 adapted to attach to a carrier (e.g., the first carrier 105a (FIG. 1)) via a suitable fastening mechanism such as fastener holes 127 or the like. A first blade 129a extends down from a first side 131a of the flange plate 125, and a second blade 129b (obscured in FIG. 2 but see FIG. 3) extends down from a second side 131b of the flange plate 125. A stiffening extension 133 extends down from a third side 131c of the flange plate 125.

As will be explained further below, the first blade receiver 121a is adapted to receive the first blade 129a, and the second blade receiver 121b is adapted to receive the second blade 129b. And as will be also explained further below, the support plate 115, the first blade receiver 121a, and the second blade receiver 121b of the overhead carrier support 111a define an overhead flange capture window 137 through which the overhead transfer flange 113a is adapted to pass prior to the first and second blade receivers 121a, 121b of the overhead carrier support 111a receiving the respective first and second blades 129a, 129b of the overhead transfer flange 113a.

FIG. 3 is a bottom plan view of the exploded assembly of the overhead carrier support 111a and the overhead transfer flange 113a shown in FIG. 2. The overhead carrier support 111a and the overhead transfer flange 113a are aligned along a vertical plane 135 coinciding with a centerplane (not separately shown) of the overhead carrier support 111a and a centerplane (not separately shown) of the overhead transfer flange 113a. Referring to FIG. 1, the vertical plane 135 is preferably aligned with the vertically-oriented moveable track 109 of the overhead transfer conveyor 103, however other orientations (e.g., at an angle, or parallel but offset) can also be provided in accordance with the present invention.

The overhead flange capture window 137 appears as a line in the view of FIG. 3. The overhead carrier support 111a is adapted to permit the overhead transfer flange 113a to advance toward the overhead carrier support 111a from the relative position of the overhead transfer flange 113a shown in the view of FIG. 3 and through the overhead flange capture window 137.

The first blade receiver 121a is oriented at a first angle 139a to the centerplane (not separately shown) of the overhead carrier support 111a, and the second blade receiver 121b is oriented at a second angle 139b to the centerplane of the overhead carrier support 111a. Preferably the first angle 139a and the second angle 139b are equivalent so that the second blade receiver 121b mirrors the first blade receiver 121a from across the centerplane (not separately shown) of the overhead carrier support 111a. In one embodiment, a third angle 141 between the first blade receiver 121a and the second blade receiver 121b is about 60 degrees. Other angles may be employed (e.g., including angles as small as about 10-20 degrees). As will be apparent, the selection of the extent of the third angle 141 is related to other aspects of the geometry of the overhead carrier support 111a and the overhead transfer flange 113a, as will be explained below.

The first blade 129a is oriented at a fourth angle 139c to the centerplane (not separately shown) of the overhead transfer flange 113a, and the second blade 129b is oriented at a fifth angle 139d to the centerplane (not separately shown) of the overhead transfer flange 113a. Preferably the fourth angle 139c and the fifth angle 139d are equivalent so that the second blade 129b mirrors the first blade 129a from across the centerplane (not separately shown) of the overhead transfer flange 113a. In one embodiment, a sixth angle 143 between the first blade 129a and the second blade 129b is about 60 degrees. Other angles may be employed. For proper interaction between the overhead carrier support 111a and the overhead transfer flange 113a, the third angle 141 and the sixth angle 143 are preferably substantially equivalent.

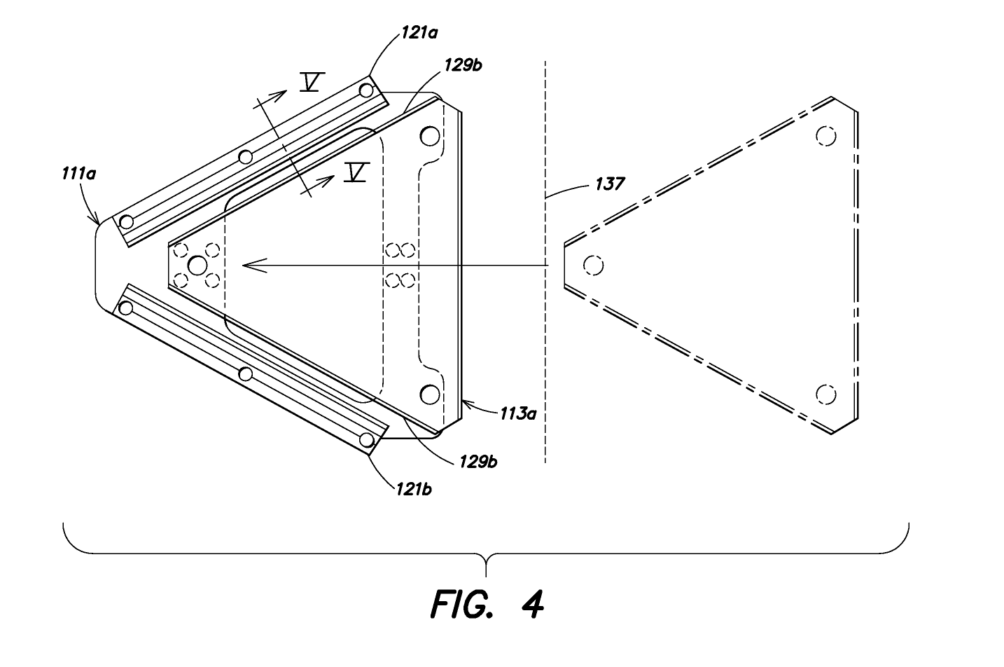

FIG. 4 is a bottom plan view of the exploded assembly of the overhead carrier support 111a and the overhead transfer flange 113a shown in FIG. 2. FIG. 4 is similar to FIG. 3 except that the overhead transfer flange 113a has advanced from the position relative to the overhead carrier support 111a (see phantom outline) that is occupied in the view of FIG. 3, passed through the overhead flange capture window 137, and is shown in a nested position with respect to the overhead carrier support 111a. In this nested position, the first and second blades 129a, 129b, which together substantially form a cropped “V” shape or a cropped chevron, are in close spaced relation with the respective first and second blade receivers 121a, 121b (which also substantially form a cropped “V” shape or a cropped chevron), but are not yet mated with the same. This may be referred to as a staging position for the overhead transfer flange 113a.

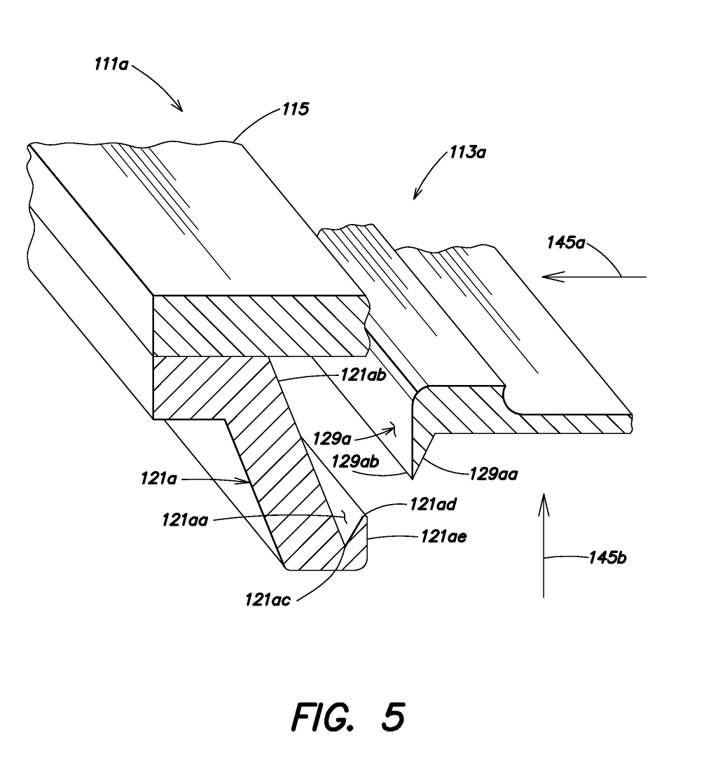

Although advancement of the overhead transfer flange 113a through the overhead flange capture window 137 may be employed to mate the overhead transfer flange 113a with the overhead carrier support 111a, the present invention provides, and the discussion below explains, that the overhead transfer flange 113a also can be raised up from below the overhead carrier support 111a to assume the nesting position of FIG. 4 (rather than approaching with a horizontal component). A continuation of the in-line advancement similar to that shown in FIG. 4 can then take place for the first blade 129a and the second blade 129b of the overhead transfer flange 113a to respectively mate with and be securely supported by the first blade receiver 121a and the second blade receiver 121b of the overhead carrier support 111a. Section V-V as depicted in FIG. 4 is representative of the cross-sections cut normal to the first blade receiver 121a and the first blade 129a as shown and described below with reference to FIGS. 5-12.

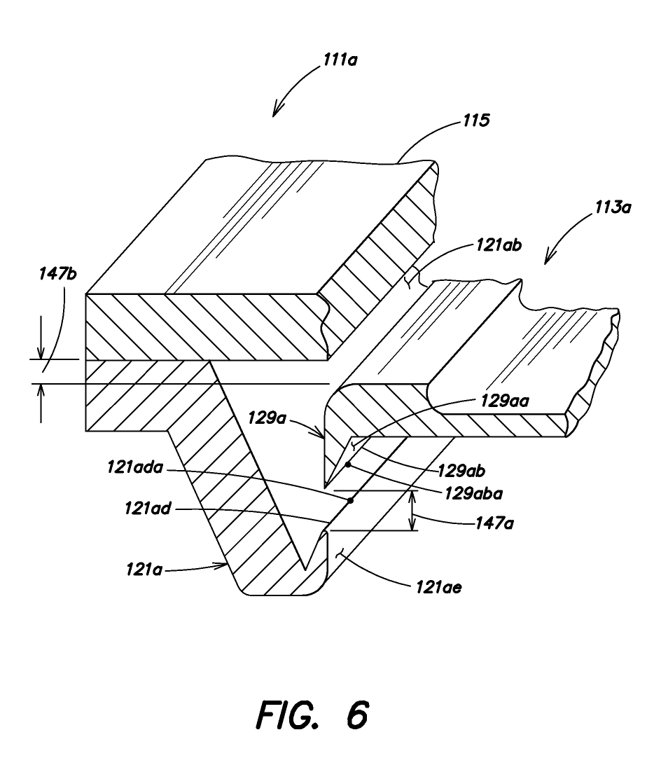

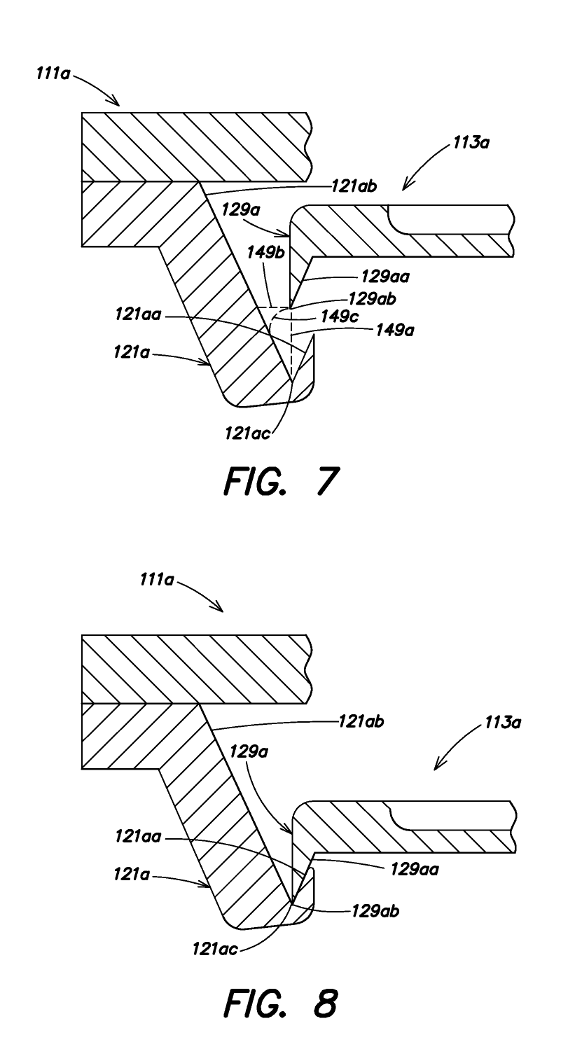

FIGS. 5 and 6 are perspective views of respective portions of the first blade receiver 121a of the overhead carrier support 111a, and of the first blade 129a of the overhead transfer flange 113a (including cross-sections), and FIGS. 7-8 are simple cross-sectional views of the same portions of the overhead carrier support 111a and the overhead transfer flange 113a. FIGS. 5-8 depict the coupling process that results in the first blade receiver 121a and the second blade receiver 121b (not shown) of the overhead carrier support 111a supporting the first blade 129a and the second blade 129b (not shown) of the overhead transfer flange 113a.

During the coupling process depicted in FIGS. 5-8, the first blade receiver 121a (shown coupled to, and below, the support plate 115 of the overhead transfer flange 113a) and the first blade 129a move relative to each other, and the second blade receiver 121b (not shown) and the second blade 129b (not shown) also move relative to each other. As between each respective pairing of blade and blade receiver, the relative motion is substantially similar, except that a relative motion between the second blade receiver 121b (not shown) and the second blade 129b (not shown) will tend to be the reverse of, or the mirror-image of, the relative motion between the first blade receiver 121a and the first blade 129a shown in FIGS. 5-8 and FIGS. 10-12. As such, FIGS. 5-8 and FIGS. 10-12 illustrate only the relative motion between the first blade receiver 121a and the first blade 129a, with the relative motion of the other blade-blade receiver pairing being understood to be the mirror image of the same.

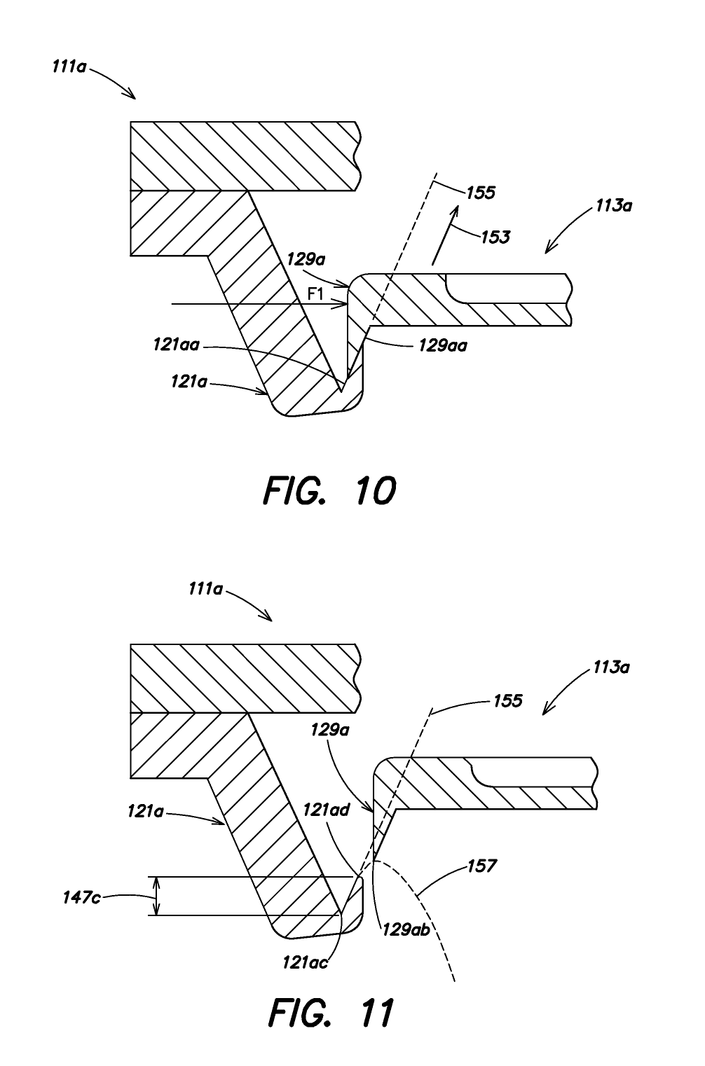

In FIGS. 5-8, as well as in FIGS. 10-12, the support plate 115 and first blade receiver 121a are shown as two pieces, coupled together. However, the support plate 115 and the first blade receiver 121a may be a single piece.

Referring to FIG. 5, a first receiving surface 121aa of the first blade receiver 121a is preferably planar, and is adapted to slidably communicate with a first blade surface 129aa (obscured) of the first blade 129a, also preferably planar, in conjunction with the first blade receiver 121a mating with the first blade 129a. A second receiving surface 121ab (obscured) of the first blade receiver 121a is also preferably planar, and is adapted to contact a first blade edge 129ab of the first blade 129a. In at least one embodiment of the invention, the first blade edge 129ab is adapted to settle into the first blade receiver 121a by the force of gravity and achieve contact with an extended vertex 121ac of the first blade receiver 121a, defined by the intersection between the first blade receiver's first receiving surface 121aa and the first blade receiver's second receiving surface 121ab. The first receiving surface 121aa of the first blade receiver 121a is also adapted to achieve contact with the first blade edge 129ab if necessary. An elongated lip 121ad of the first blade receiver 121a is preferably located at a right most extent 121ae of the first blade receiver 121a. Other locations of the lip 121ad may be employed.

The first blade 129a of the overhead transfer flange 113a is shown in FIG. 5 in a convenient staging position relative to the first blade receiver 121a of the overhead carrier support 111a as shown and described above with reference to FIG. 4, the view being that of section V-V, as indicated in FIG. 4. One reason why this staging position is convenient is because the first blade 129a is close to a lodging position within the first blade receiver 121a, requiring only to be urged toward the first blade receiver 121a in the in-line direction 107 (see FIG. 1) and lowered with respect to the first blade receiver 121a to achieve such lodging. Another reason why the staging position shown is convenient is that the first blade 129a can reach the position from multiple staging position access directions (e.g., a first staging position access direction 145a, a second staging position access direction 145b, etc.).

The first staging position access direction 145a is the horizontal access direction as shown and described with reference to FIG. 4 above. If sufficient in-line spacing exists between successive carrier supports (e.g., between the first carrier 105a and the second carrier 105b of FIG. 1) along the conveyor (e.g., the overhead transfer conveyor 103 of FIG. 1), the first staging position access direction 145a can easily be accommodated, and has the advantage of continuity and simplicity, since a simple continuation of motion of the overhead transfer flange 113a in the in-line direction 107 (see FIG. 1), past the staging position shown, is required to place the first blade 129a directly above a lodging position within the first blade receiver 121a.

The second staging position access direction 145b is a practical alternative to the first staging position access direction 145a when carriers are closely spaced along the conveyor (e.g., as closely spaced as the first carrier 105a and the second carrier 105b are along the moveable track 109 of the overhead transfer conveyor 103 as shown in FIG. 1). The second staging position access direction 145b is a vertical access direction, and it takes advantage of the fact that the chevron formed by the first blade 129a and the second blade 129b can nest closely behind the chevron formed by the first blade receiver 121a and the second blade receiver 121b without the blades coming in contact with the blade receivers 121a, 121b.

Because the chevron formed by the first blade 129a and the second blade 129b can nest behind the chevron formed by the first blade receiver 121a and the second blade receiver 121b, the overhead transfer flange 113a can rise up from below the overhead carrier support 111a and move upwards past the first blade receiver lip 121ad and past the rightmost extent 121ae of the first blade receiver 121a, such that the first blade 129a rises above the first blade receiver 121a from behind the first blade receiver 121a (e.g., behind in the in-line direction 107) to reach the convenient staging position shown in FIGS. 4 and 5. The second staging position access direction 145b has the advantage of introducing the overhead transfer flange 113a to the overhead transfer conveyor 103 at a position along the length of moveable track 109 of the overhead transfer conveyor 103 that is very close to the position at which the overhead carrier support 111a will support the overhead transfer flange 113a, so that only a minimum of in-line, lateral motion between the overhead transfer flange 113a and the overhead carrier support 111a is required to enable the overhead transfer flange 113a to lodge in the overhead carrier support 111a. For example, during raising of the overhead transfer flange 113a, a footprint of the overhead transfer flange 113a may overlap a footprint of the overhead carrier support 111a.

Referring to FIG. 6, the first blade receiver 121a, the first blade surface 129aa, and the rightmost extent 121ae of the first blade receiver 121a, all described above with reference to FIG. 5, are shown. The overhead transfer flange 113a has begun to move in the in-line direction 107 (see FIG. 4) such that relative motion between the overhead transfer flange 113a and the overhead carrier support 111a is occurring. Specifically the overhead transfer flange 113a has moved toward the overhead carrier support 111a such that the first blade edge 129ab is now directly above the first blade receiver lip 121ad, and is aligned with the rightmost extent 121ae of the first blade receiver 121a.

A first clearance 147a exists between the first blade edge 129ab of the first blade 129a and the lip 121ad of the first blade receiver 121a. In one embodiment of the invention, the first clearance 147a is preferably about 3 mm or less, and more preferably about 1.5 mm or less. Other clearances may be employed in addition, a second clearance 147b exists between the flange plate 125 (FIG. 2) of the overhead transfer flange 113a and the support plate 115 of the overhead carrier support 111a. In one embodiment of the related family of inventions, the second clearance 147b is also preferably about 3 mm or less, and more preferably about 1.5 mm or less. Other clearances may be employed. It is preferable to keep clearances such as the first clearance 147a and the second clearance 147b at a minimum since space in the clean room of a typical semiconductor device manufacturing facility can be exceptionally expensive.

It should be noted that when the overhead transfer flange 113a approaches the overhead carrier support 111a along the in-line direction 107 (see FIG. 1) the first blade 129a does not approach the first blade receiver 121a directly (e.g., parallel to the cross sections of FIG. 5) such that a particular point along the first blade 129a (e.g., point 129aba along the first blade edge 129ab of the first blade 129a, as shown in FIG. 6) will pass in a normal direction to the first blade receiver 121a and over a corresponding point (e.g., point 121ada along the first blade receiver lip 121ad, as shown in FIG. 6) on the first blade receiver lip 121ad. Rather, a combination of normal convergence between the first blade 129a and the first blade receiver 121a (e.g., the “line” of the first blade edge 129ab remains parallel with the “line” of the first blade receiver lip 121ad while advancing toward the same) and lateral, relative motion between the first blade 129a and the first blade receiver 121a (e.g., the first blade edge point 129aba moving laterally past the first blade receiver lip point 121ada) will occur as the overhead transfer flange 113a advances toward the overhead carrier support 111a in the in-line direction 107 (see FIG. 1).

As such the respective points (not separately shown) along the overhead transfer flange 113a and the overhead carrier support 111a at which the cross-sections of FIGS. 5-8 and FIGS. 10-12 are taken are not all to be presumed to be those of cross-sections V-V of FIG. 4 but should instead be presumed to change from figure to figure according to the distance between the overhead transfer flange 113a and the overhead carrier support 111a, (e.g., cross sectional views taken at points on the overhead transfer flange 113a and on the overhead carrier support 111a close to that of section V-V of FIG. 4), without necessarily affecting the manner in which the overhead transfer flange 113a and the overhead carrier support 111a are depicted therein.

Referring to FIG. 7, the overhead transfer flange 113a has moved further relative to the overhead carrier support 111a such that the first blade edge 129ab is directly above the first blade receiver's extended vertex 121ac. With the overhead transfer flange 113a in this position relative the overhead carrier support 111a, the first blade 129a can be allowed to drop relative to the first blade receiver 121a along a vertical path 149a such that the first blade edge 129ab can achieve linear contact with the first blade receiver's extended vertex 121ac.

Alternatively, the first blade 129a can be urged further toward the first blade receiver 121a along a horizontal path 149b in the same horizontal plane, resulting in linear contact between the first blade edge 129ab and the first blade receiver's second receiving surface 121ab. As yet another alternative, the first blade 129a can be moved through a sloping path 149c having both horizontal and vertical components to achieve a similar result as that achieved via the sloping path 149c. The sloping path 149c in particular can be achieved by allowing the overhead transfer flange 113a to lower or drop onto the overhead carrier support 111a after the contribution of an initial horizontal velocity component.

As an example, the overhead transfer flange 113a (e.g., the first carrier 105a of which the overhead transfer flange 113 is a part) can be propelled horizontally at the same speed as the moveable track 109 of the overhead transfer conveyor 103 (e.g., by an arrangement of motorized rollers providing a horizontal conveying surface or by any other means). The horizontal speed of the first carrier 105 may be increased, causing the overhead transfer flange 113a to “close” with the overhead carrier support 111a and the first carrier 105a (and the overhead transfer flange 113a attached thereto) may be lowered or dropped relative to the overhead carrier support 111a.

A curved path similar to the sloping path 149c can begin when the lateral position of the overhead transfer flange 113a relative to the overhead carrier support 111a is as shown in FIG. 6, or even before the first blade edge 129ab clears the first blade receiver lip 121ad, as shown in FIG. 5, provided the overhead transfer flange 113a passes over the first blade receiver lip 121ad without striking the first blade receiver lip 121ad, and contacts the first blade receiver's first receiving surface 121aa, the first blade receiver's second receiving surface 121ab, or the first blade receiver's extended vertex 121ac.

Referring to FIG. 8, the overhead transfer flange 113a is shown supported by the first blade receiver 121a, with the first blade 129a being lodged within the overhead carrier support 111a. The first blade edge 129ab is in linear contact with the first blade receiver's extended vertex 121ac, and the first blade 129a is in planar contact with the first blade receiver's first receiving surface 121aa.

As an example, just prior to the first blade edge 129ab achieving linear contact with the first blade receiver's extended vertex 121ac, the first blade 129a may have slid downward and rightward, with the first blade edge 129ab sliding atop and in linear contact with the first blade receiver's second receiving surface 121ab. In one embodiment of the invention, the first blade receiver's second receiving surface 121ab is preferably oriented at about a 25-degree to a 30-degree angle to the vertical plane. Such an inclination ensures that the first blade 129a will travel expeditiously downward from the point of contact of the first blade edge 129ab with the first blade receiver's second receiving surface 121ab. Other angles may be employed.

Alternatively, the first blade 129a may have slid downward and leftward, with the first blade surface 129aa sliding atop and in planar contact with the first blade receiver's first receiving surface 121aa. In at least one embodiment of the invention, the first blade receiver's first receiving surface 121aa is preferably oriented at about a 25-degree to a 30-degree angle to the vertical plane. Other angles may be employed.

While the first blade 129a is seated within the first blade receiver 121a (and the second blade 129b is seated within the second blade receiver 121b (see FIGS. 4-5)), the overhead transfer flange 113a is advantageously restricted in both lateral directions and in the rearward direction (e.g., opposite the in-line direction 107 (see FIG. 1)) by the obstacle to the first blade surface 129aa posed by the first blade receiver's first receiving surface 121aa. In at least one embodiment of the invention, the blade and receiving surfaces are preferably flat and have complementary orientations with regard to the vertical to ensure close mating communication between the first blade surface 129aa and the first blade receiver's first receiving surface 121aa. As previously noted, the second blade receiver restricts lateral motion in the same manner. Non-flat surfaces also may be employed.

At the same time, the overhead transfer flange 113a is advantageously restricted in the forward direction (e.g., the in-line direction 107 (See FIG. 1)) by the obstacle to the first blade edge 129ab posed by the first blade receiver's second receiving surface 121ab. The first blade edge 129ab may be somewhat rounded (e.g., a sharp corner that is broken, a radiused edge, a truncated cone, etc.) to ensure smooth sliding between the first blade edge 129ab and the first blade receiver's second receiving surface 121ab whenever the first blade edge 129ab and the first blade receiver's second receiving surface 121ab are caused to slidably communicate.

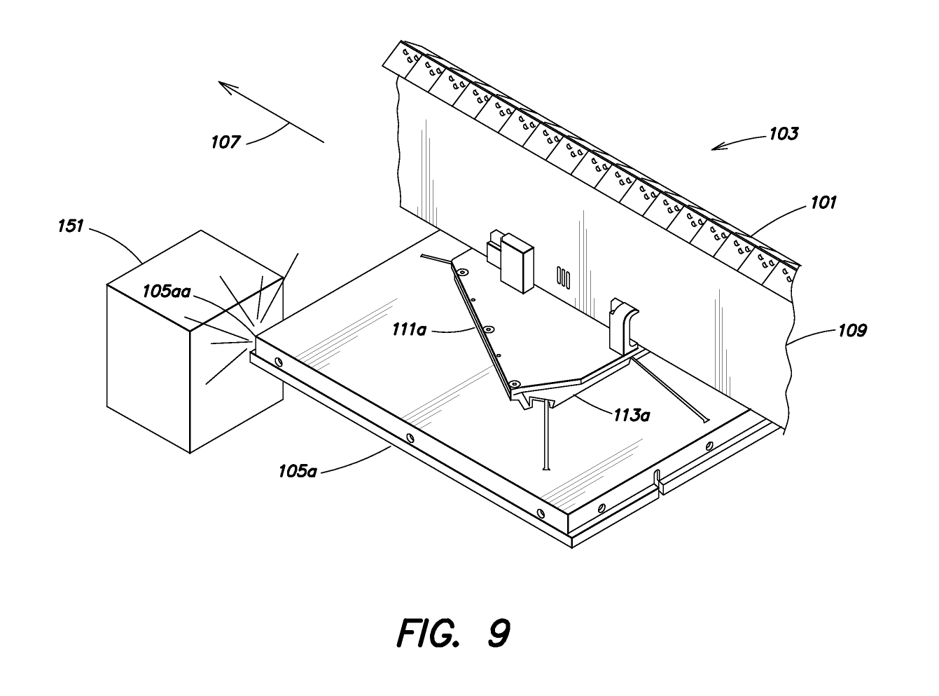

It should be noted, however, that communication between the first blade edge 129ab and the first blade receiver's second receiving surface 121ab is expected to occur almost exclusively during the process of depositing the overhead transfer flange 113a upon the overhead carrier support 111a. That is, once the first blade edge 129ab is lodged within the first blade receiver's extended vertex 121ac, and the first carrier 105a (see FIG. 1) is being transported in the in-line direction 107 by the overhead transfer conveyor 103, there may be relatively little likelihood of the first carrier 105a being subjected to a force tending to urge the overhead transfer flange 113a forward relative the overhead carrier support 111a. As will be explained further below, and with reference to FIGS. 9-12, it is more likely that the overhead transfer flange 113a will be subjected to forces tending to urge it laterally, or forces tending to urge it rearwardly, or a combination of such forces.

FIG. 9 is a perspective cut-away view of a portion of the overhead transfer conveyor 103 utilizing the coupling between the overhead carrier support 111a and the overhead transfer flange 113a to carry the first carrier 105a in the in-line direction 107. An object 151, present in the path through which the overhead transfer conveyor 103 carries the first carrier 105a, strikes a corner 105aa of the first carrier 105a. The object 151 may be a piece of machinery such as a robot that has moved away from its intended path due to a programming error, misplaced equipment or any other object. Many other objects or items may be placed, either intentionally or unintentionally, in positions near the overhead transfer conveyor 103 such that a collision with the first carrier 105a may take place at the first carrier corner 105aa.

Collisions with the first carrier 105a may also be caused by objects (not separately shown) striking the bottom, side, top or rear of the first carrier 105a. It would be unexpected for an object to strike the first carrier 105a from behind, since the moveable track 109 of the overhead transfer conveyor 103 preferably carries substrate carriers at a high rate of speed in the in-line direction 107.

An advantage of the overhead carrier support 111a and the overhead transfer flange 113a of the present invention is that the first carrier 105a can predictably and controllably dislodge from the overhead transfer conveyor 103 when subjected to a rearward or lateral force of a predetermined amount, such as, for example, 3 pounds or more, or preferably 5 pounds or more. That is, in one embodiment of the invention, if the first carrier 105a is struck by a force of 1 or 2 pounds, directed toward the first carrier 105a from the front or side, the overhead transfer flange 113a preferably remains within the overhead carrier support 111a so that the first carrier 105a continues to be carried by the overhead transfer conveyor 103 in the in-line direction 107. However, if the first carrier 105a is struck by a force of 7 or 8 pounds, directed toward the first carrier 105a from the front or side, the overhead transfer flange 113a preferably dislodges from the overhead carrier support 111a and falls downward away from the overhead transfer conveyor 103 and away from the other substrate carriers being carried by the overhead transfer conveyor 103.

As described above and with respect to FIG. 1, when the first carrier 105a is being carried by the overhead transfer conveyor 103 along the moveable track 109 in the in-line direction 107, lateral relative movement, front-to-rear relative movement, and rear-to-front relative movement on the part of the overhead transfer flange 113a relative to the overhead carrier support 111a is restricted, and in the normal operation of the overhead transfer conveyor 103, such movement is essentially prevented. Downward movement of the overhead transfer flange 113a relative to the overhead carrier support 111a is similarly restricted. Upward motion of the overhead transfer flange 113a relative to the overhead carrier support 111a however is generally unrestricted.

The object 151 depicted in FIG. 9 is likely to subject the first carrier 105a to lateral and rearward forces which will vary depending on the speed of the overhead transfer conveyor 103 in the in-line direction 107, the angle at which the first carrier 105a strikes the object 151, and the width of the first carrier 105a (e.g., the distance from the moveable track 109 at which the collision between the object 151 and the first carrier 105a takes place). The overhead carrier support 111a, however, preferably restricts twisting and translating motion of the overhead transfer flange 113a in the horizontal plane. As such, in order to prevent damage to the moveable track 109 of the overhead transfer conveyor 103, the horizontal forces resulting from the collision should be somehow redirected.

As viewed from the front of the overhead transfer flange 113a in the in-line direction 107, the first blade receiver's first receiving surface 121aa (FIG. 5) tilts backward, and the horizontally cropped chevron formed by the first blade receiver's first receiving surface 121aa and its counterpart surface (not shown) on the second blade receiver 121b (see FIG. 2) increases from a narrow aspect near the front of the overhead transfer flange 113a to a wider aspect near the rear of the overhead transfer flange 113a. This combination of two backward-tilting surfaces forming a rear-outward tapering chevron provides that the mating surface (e.g., the first blade surface 129aa and its counterpart surfaces (not shown) on the second blade 129b (see FIG. 2) may “ride” upward and rearward with regard to the overhead transfer flange 113a, sliding along and in mating communication with their corresponding support surfaces as they ride.

In operation, the chevron-shaped arrangement of rearward and upward tilting surfaces just described, cooperates with rearward and lateral impact forces to which the first carrier 105a may be subjected (e.g., during a collision) to cause the overhead transfer flange 113a of the first carrier 105a to move upward and rearward relative to the overhead carrier support 111a of the overhead transfer conveyor 103. The overhead transfer flange 113a may dislodge from the overhead carrier support 111a, and thereby cause the first carrier 105a to fall from the overhead transfer conveyor 103. This cooperation is explained below and with reference to FIGS. 10-12.

FIGS. 10-12 are cross-sectional views of respective portions of the first blade receiver 121a of the overhead carrier support 111a, and the first blade 129a of the overhead transfer flange 113a, which views depict the decoupling process that results in the first carrier 105a dislodging from the overhead transfer conveyor 103. Referring to FIG. 10, the force F1 is applied to the overhead transfer flange 113a normal to the direction in which the first blade 129a extends as shown in FIGS. 5 and 6, and is a force derived from an impact between the first carrier 105a and the object 151 as shown in FIG. 10.

If not for the obstacle posed by the first blade receiver's first receiving surface 121aa to the lateral motion of the first blade 129a of the overhead transfer flange 113a, the force F1 would urge the first blade 129a away from the first blade receiver 121a in a lateral direction within the horizontal plane in which the overhead transfer flange 113a is shown to reside in FIG. 8. However, because the first blade receiver's first receiving surface 121aa blocks direct lateral movement of the overhead transfer flange 113a due to the planar communication between the first blade receiver's first receiving surface 121aa and the first blade surface 129aa, the overhead transfer flange 113a reacts to the force F1 by the first blade surface 129aa sliding or “riding” upwards and rearward with respect to the overhead carrier support 111a as a whole.

As described above, rearward motion of the overhead transfer flange 113a relative to the overhead carrier support 111a means that the point (not shown) on the overhead transfer flange 113a at which the cross section of FIG. 10 is taken, moves into the page as the first blade surface 129aa slides upward along the first blade receiver's first receiving surface 121aa, and that cross-sections of the overhead transfer flange 113a in FIGS. 10-12 are taken at different points of the overhead transfer flange 113a.

Referring again to FIG. 10, in response to the force F1, the first blade surface 129aa of the first blade 129a rides up the first blade receiver's first receiving surface 121aa of the overhead carrier support 111a in direction 153, which is aligned with the slope 155 of the first blade receiver's first receiving surface 121aa. Because the first blade surface 129aa of the overhead transfer flange 113a and the first blade receiver's first receiving surface 121aa are in planar communication, and because complementary surfaces (not shown) on the other side of the overhead transfer flange 113a operate at the same time, the overhead transfer flange 113a can tend to retain, as it rises, the horizontal orientation it assumed while being carried by the overhead carrier support 111a along the overhead transfer conveyor 103 (see FIG. 8) prior to the impact between the first carrier 105a and the object 151 (see FIG. 9). In addition, the above-described arrangement of cooperating surfaces may cause the centerplane (not shown) of the overhead transfer flange 113a to remain roughly aligned with the moveable track 109 of the overhead transfer conveyor 103 as the overhead transfer flange 113a rises and moves rearward relative to the overhead carrier support 111a.

Referring to FIG. 11, the overhead transfer flange 113a has been fully dislodged from the overhead carrier support 111a and is in upward projectile motion, as shown by projectile motion path 157, departing from the slope 155 of the first blade receiver's first receiving surface 121aa. The overhead transfer flange 113a is now no longer restricted in its vertical motion and may pass downward and away from the overhead carrier support 111a.

The overhead transfer flange 113a is shown in FIG. 11 to have risen such that the first blade edge 129ab has at least achieved a clearance 147c with respect to the first blade receiver's extended vertex 121ac, which coincides with the height of the first blade receiver lip 121ad above the first blade receiver extended vertex 121ac. As such, the first blade edge 129ab can pass above the first blade receiver lip 121ad without risk of the first blade 129a striking the first blade receiver 121a. The clearance 147c is preferably about 3 mm, it being noted that the extent of the clearance 147c is to be selected based in part on the desired breakaway force, which in this embodiment is about 5 pounds, as described above. Should the desired breakaway force be less than 5 pounds, a lesser clearance 147c may be selected, and vice-versa. For example, in another embodiment of the invention, a force of up to 20 pounds may be required to dislodge the first carrier 105a from the overhead transfer conveyor 103. In such embodiments, a larger clearance 147c may be desired (e.g., about 0.5 inches in one embodiment).

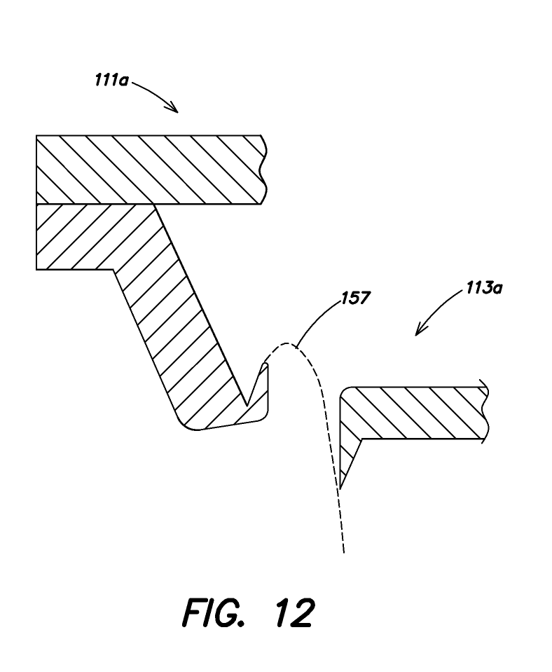

Referring to FIG. 12, the overhead transfer flange 113a has passed rearward, downward and away from the overhead carrier support 111a, with the progression of points on the first blade edge 129ab describing the remainder of the projectile motion path 157. The first carrier 105a (see FIG. 9) may now be caught in a net or other similar mechanism for gentle collection of the first carrier 105a after the impact with the object 151 (see FIG. 9).

The foregoing description discloses only exemplary embodiments of the family of inventions; modifications of the above disclosed apparatus and methods which fall within the scope of the invention will be readily apparent to those of ordinary skill in the art. For instance, the overhead carrier support 111a and the overhead transfer flange 113a may be formed from any suitable material (e.g., materials that slide freely and exhibit long term wear resistance). Exemplary materials for the overhead carrier support and/or the overhead transfer flange include metals (e.g., stainless steel, aluminum, etc.), plastics (e.g., polycarbonate, polyethelene, other ultra high molecular weight or high density plastics, nylon, PTFE, etc.), or other similar materials. Plastic components may be molded or otherwise fabricated.

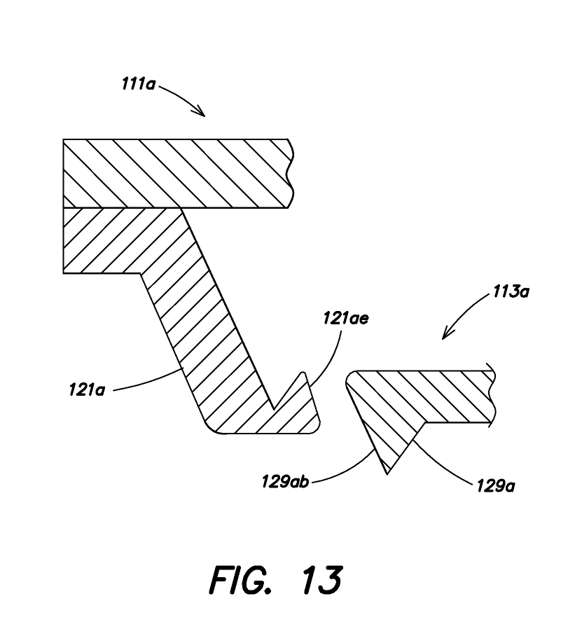

FIG. 13 is a cross sectional view of a portion of the first blade receiver 121a of the overhead carrier support 111a and of the first blade 129a of the overhead transfer flange 113a illustrating an alternative embodiment of such components. With reference to FIG. 13, both the right most extent 121ae of the first blade receiver 121a and the first blade edge 129ab of the first blade 129a are angled at about 45 degrees from vertical (although other angles may be employed). Such a configuration provides a larger capture window for the overhead transfer flange 113a than when the right most extent 121ae and the first blade edge 129ab are not angled. Also, when angled, these surfaces may slide relative to one another when misaligned and may assist in capture of the overhead transfer flange 113a by the overhead carrier support 111a.

While the overhead carrier support 111a and the overhead transfer flange 113a have been described herein primarily for use with overhead transport systems, it will be understood that the overhead carrier support 111a (or portions thereof) may be employed to support and/or position a substrate carrier having the overhead transfer flange 113a at any other location. For example, the overhead carrier support 111a (or portions thereof) may be used for supporting and/or positioning substrate carriers within stockers, substrate carrier cleaners, local storage buffers that are part of a processing tool, batch process tools such as a furnace or a wet clean station, etc.

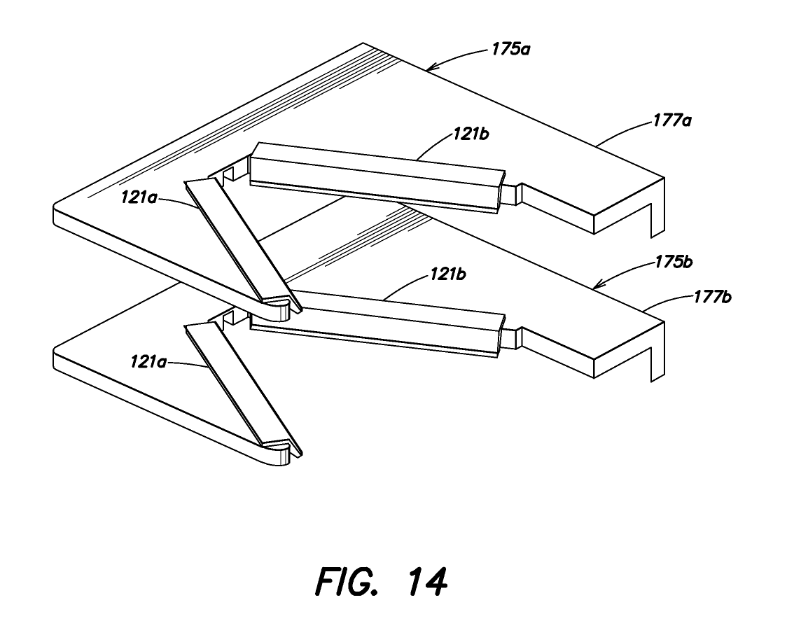

FIG. 14 is a perspective view of a plurality of shelves 175a-b configured to support substrate carriers via an overhead transfer flange in accordance with the present invention. More or fewer than two shelves may be employed. Each shelf 175a-b includes a support surface 177a-b having blade receivers 121a, 121b coupled thereto (or formed therein). The shelves 175a-b thus forms overhead carrier supports that may support substrate carriers having overhead transfer flanges such as the overhead transfer flange 113a (FIGS. 1-12). The angles/dimensions of the blade receivers 121a, 121b may be, for example, similar to those described previously. The shelves 177a-b may be mounted at any location at which a substrate carrier is to be supported (e.g., within stockers, substrate carrier cleaners, local storage buffers that are part of a processing tool, batch process tools, etc.). In one or more embodiments of the invention, the shelf 175a and/or 175b may be moveable. For example, the shelf 175a and/or 175b may be used to dock or undock a substrate carrier to/from a loadport of a processing tool.

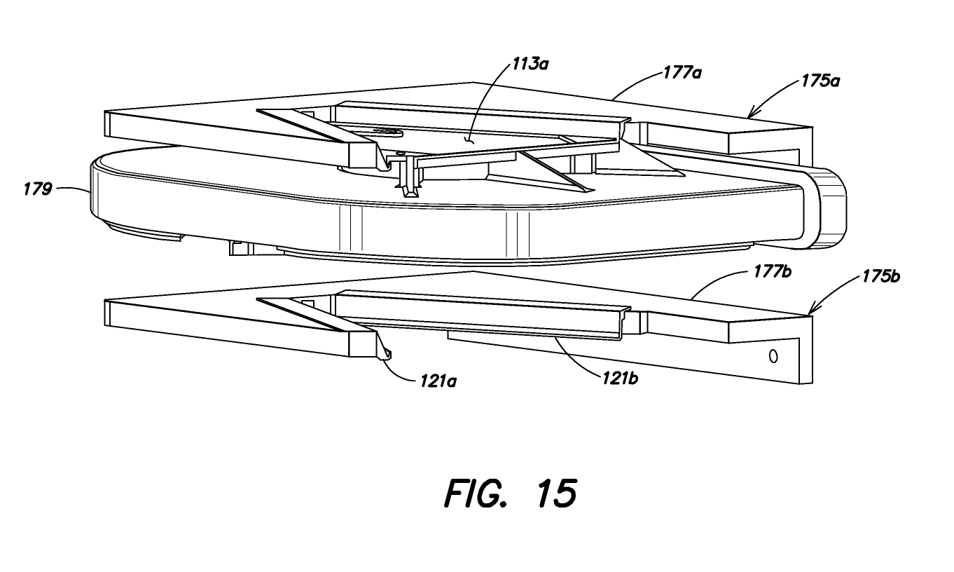

FIG. 15 is a perspective view of the shelves 175a-b of FIG. 14 wherein the top shelf 175a supports a substrate carrier 179 via its overhead transfer flange 113a. The substrate carrier 179 may be a single substrate carrier or adapted to house multiple substrate carriers. As will be apparent, use of the blade receivers 121a, 121b and the overhead transfer flange 113a allows substrate carriers to be stacked with a high packing density and stored on and removed from storage shelves with relatively few movements.

The overhead transfer flange 113a may be employed with open substrate containers or trays. The blade receivers of an overhead carrier support may be angled from front to back of the overhead carrier support (relative to horizontal); and/or the blade edges of an overhead transfer flange may be angled from front to back of the overhead transfer flange (relative to horizontal).

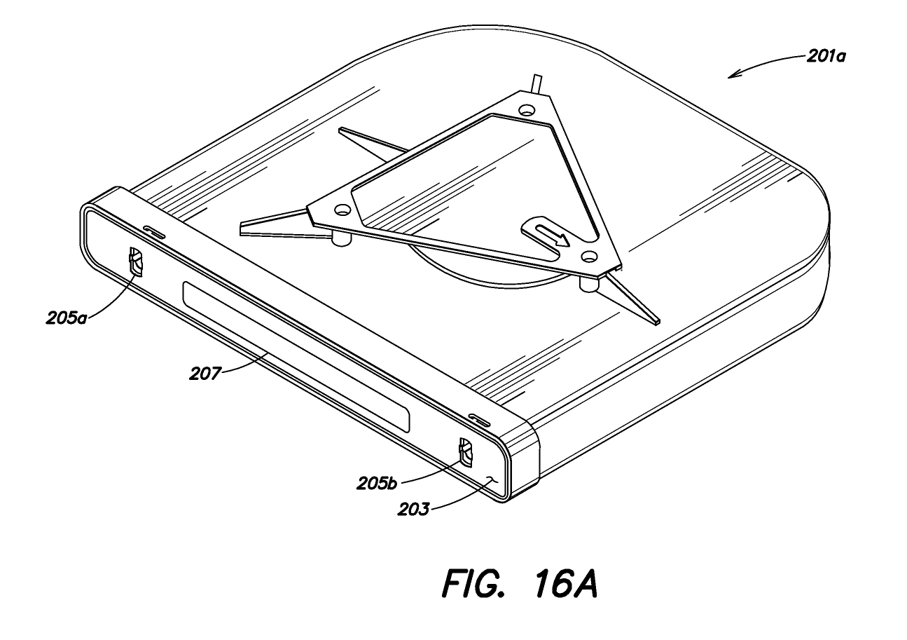

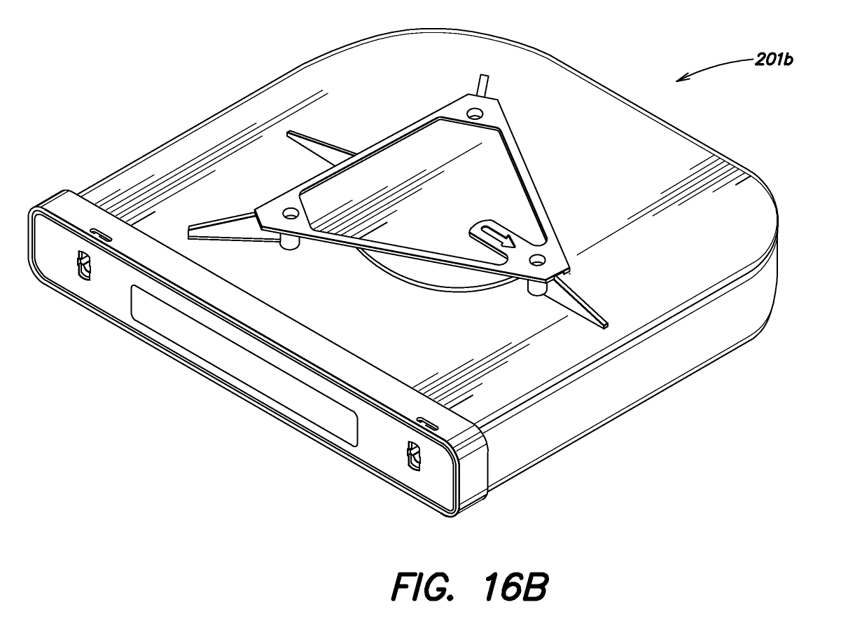

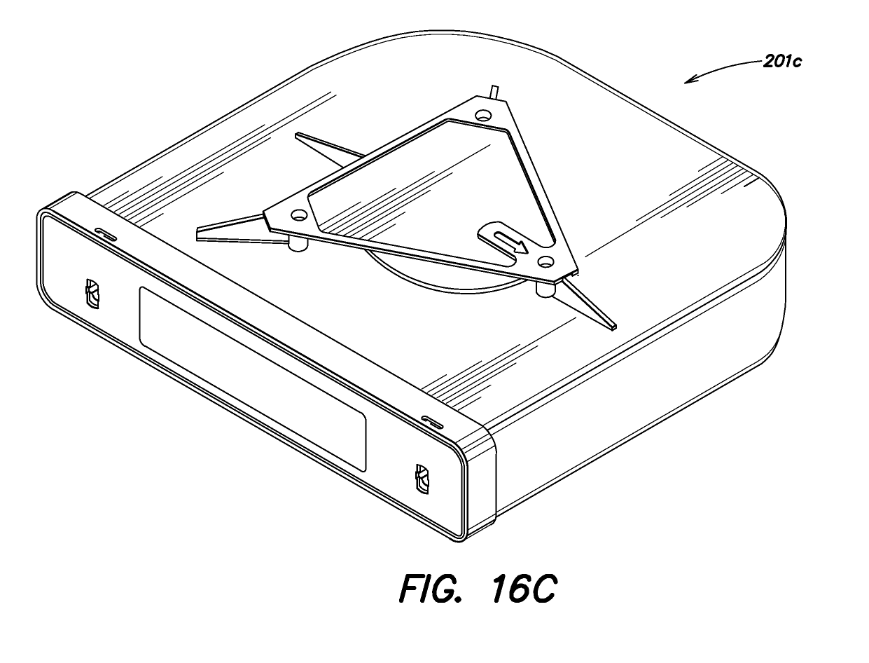

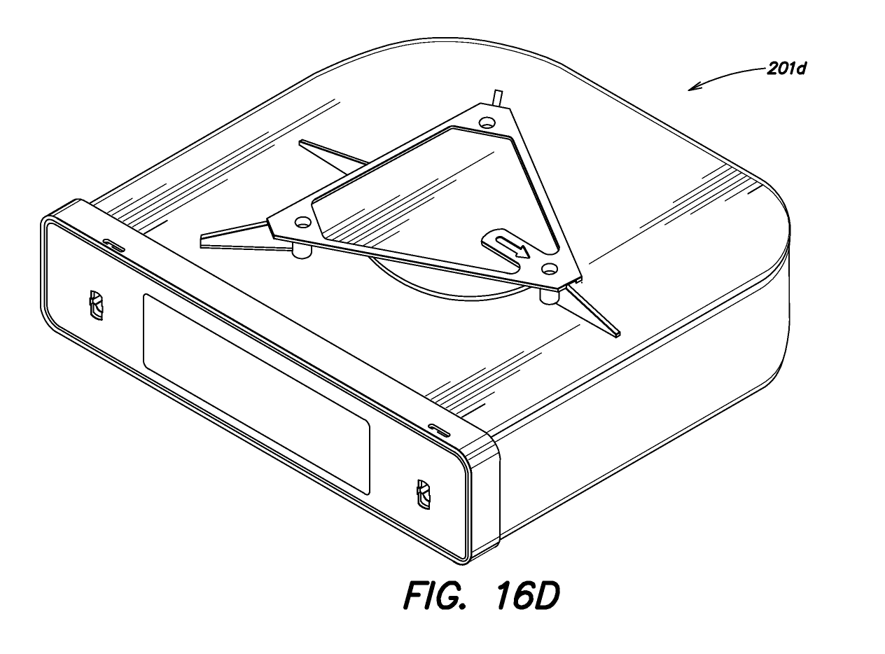

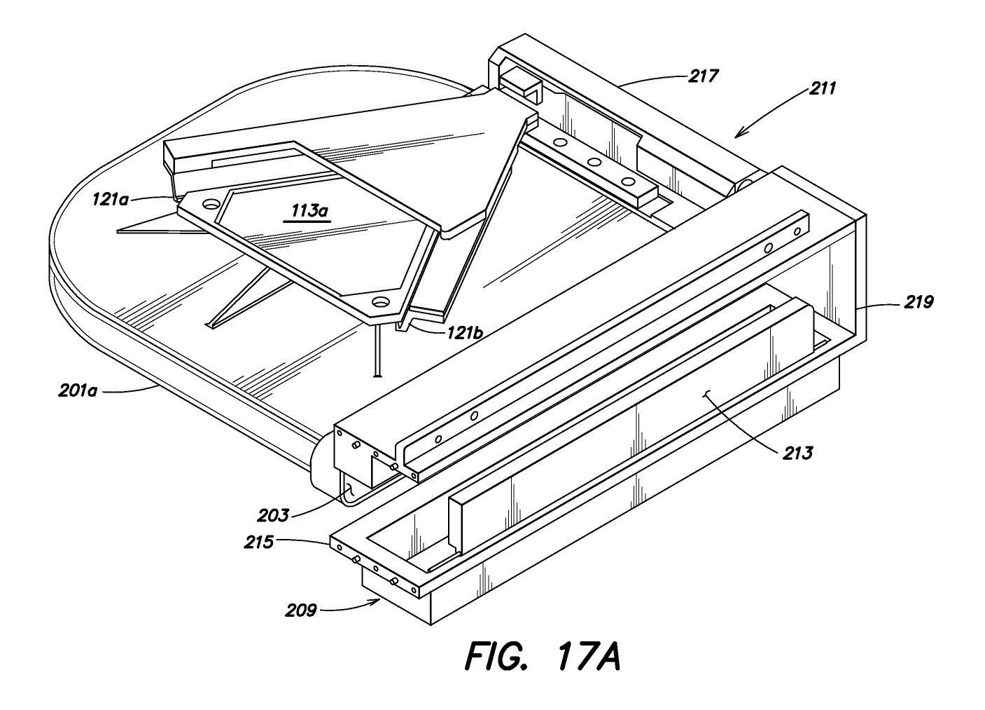

FIG. 16A is an exemplary embodiment of a substrate carrier 201a having an overhead transfer flange 113a and that is adapted to transport a single substrate. The substrate carrier 201a includes a door 203 that may be removed to allow access to a substrate stored within the substrate carrier 201a (as described further below). In the exemplary embodiment shown, the door 203 includes latches 205a,b that allow the door 203 to be selectively secured to and removed from the remainder of the substrate carrier 201a. The door 203 may include a region 207, such as a metallic or otherwise magnetic permeable region (e.g., iron, stainless steel, etc.), that allows the door 203 to be held securely by a door opening mechanism (described below) when access to an interior of the substrate carrier 201a is desired (e.g., for removing a substrate from or loading a substrate into the substrate carrier 201a). The remainder of the substrate carrier 201a may be fabricated from polycarbonate, PEEK or another suitable material.

FIGS. 16B-D are exemplary embodiments of substrate carriers 201b-d, respectively, that are similar to the substrate carrier 201a, but that are adapted to transport two, three and fourth substrates, respectively. As is will be understood from FIGS. 16A-D, the height of a substrate carrier increases as the substrate capacity of the substrate carrier increases. Substrate carriers having an ability to store more than four substrates also may be provided.

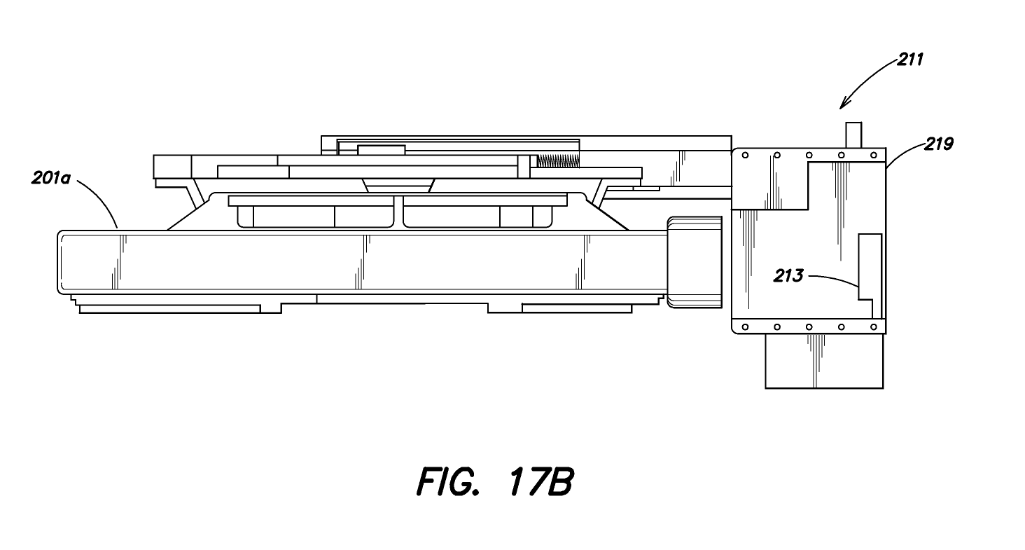

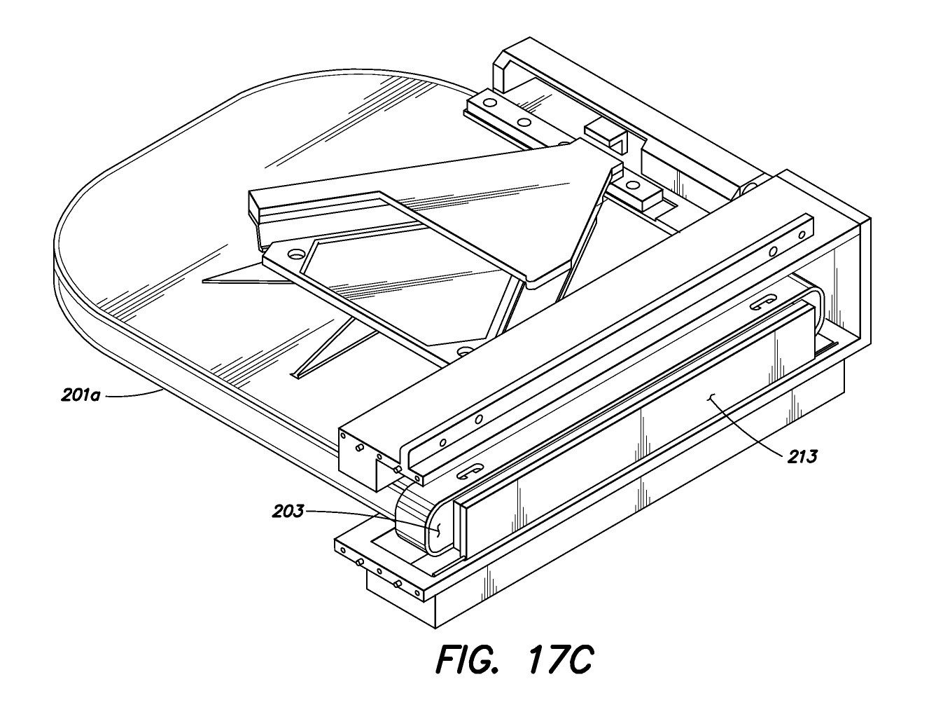

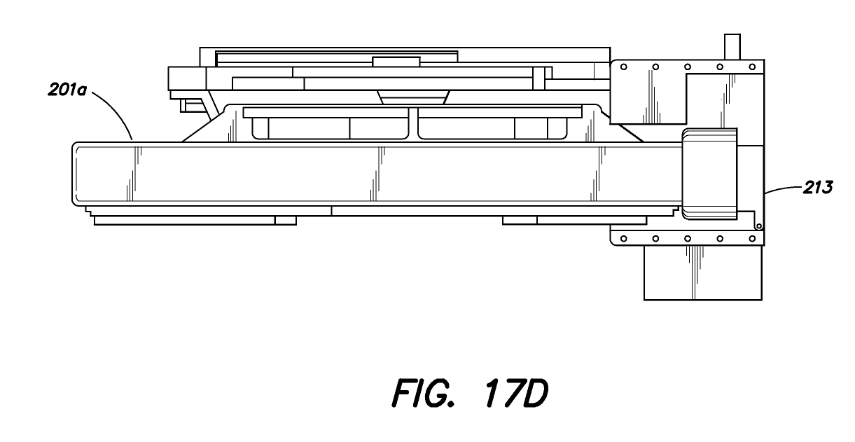

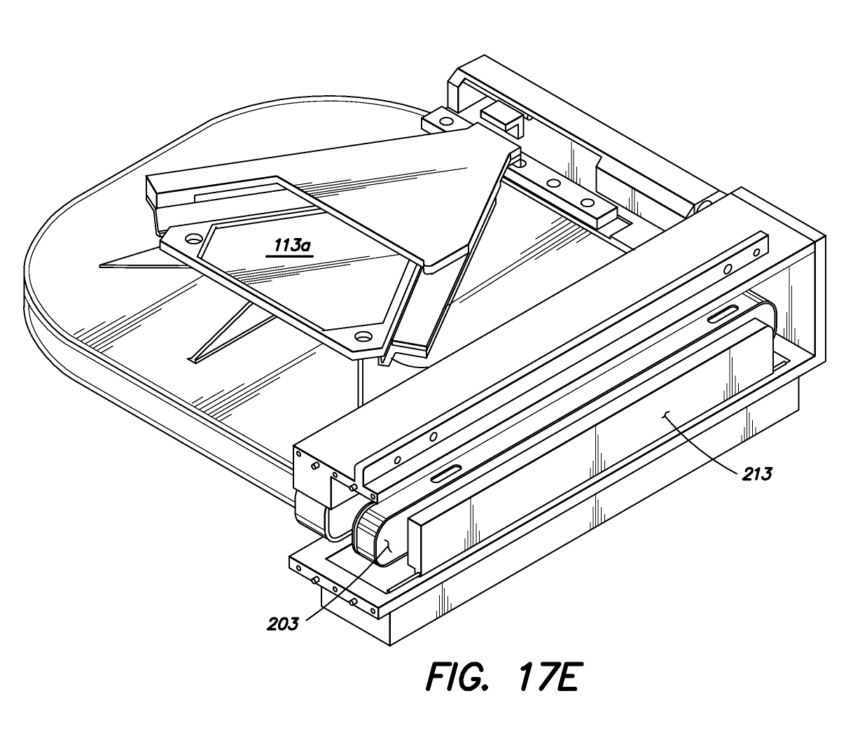

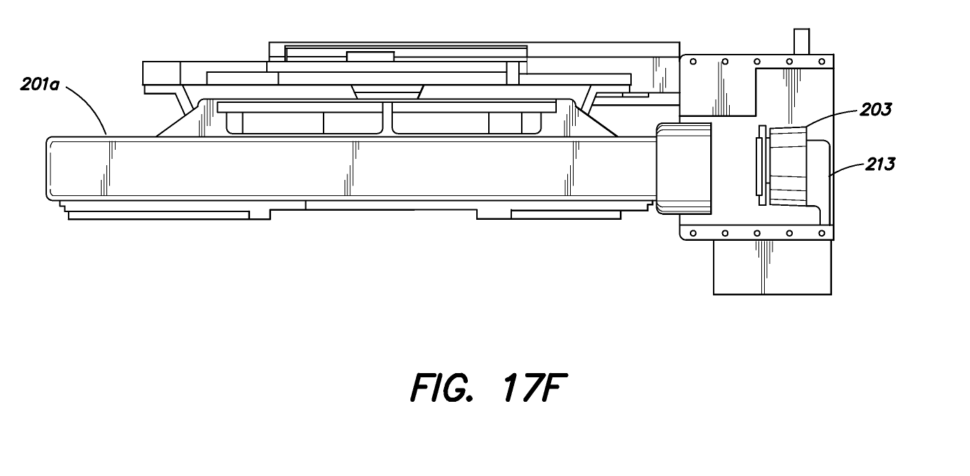

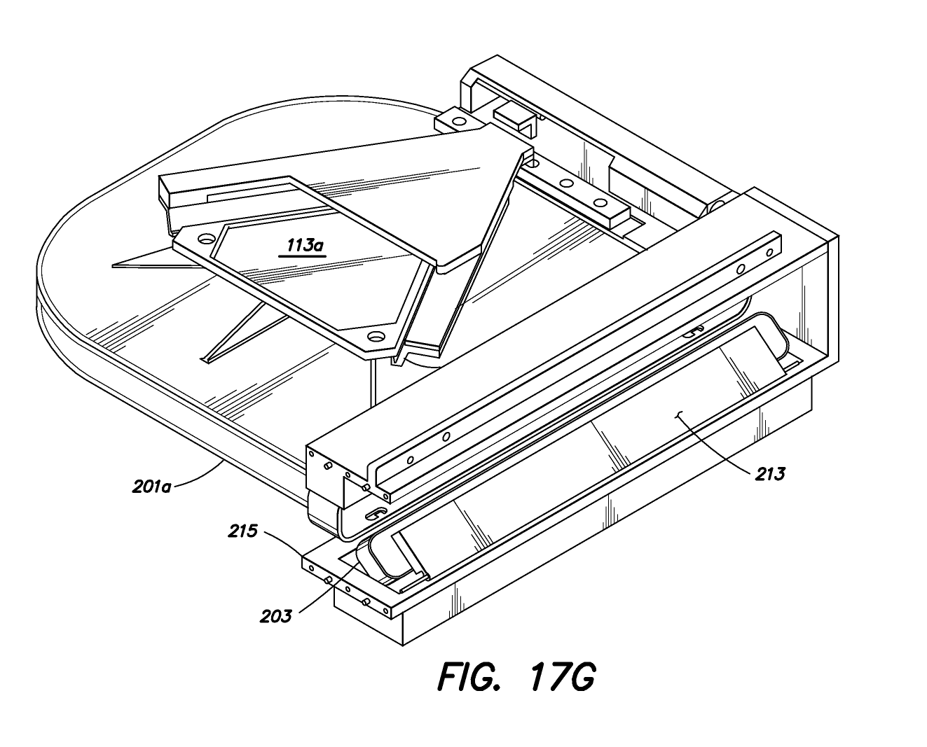

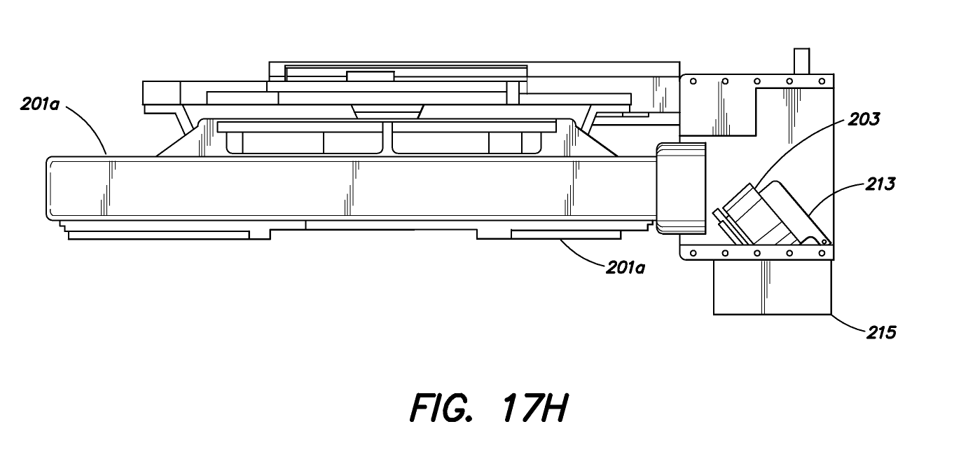

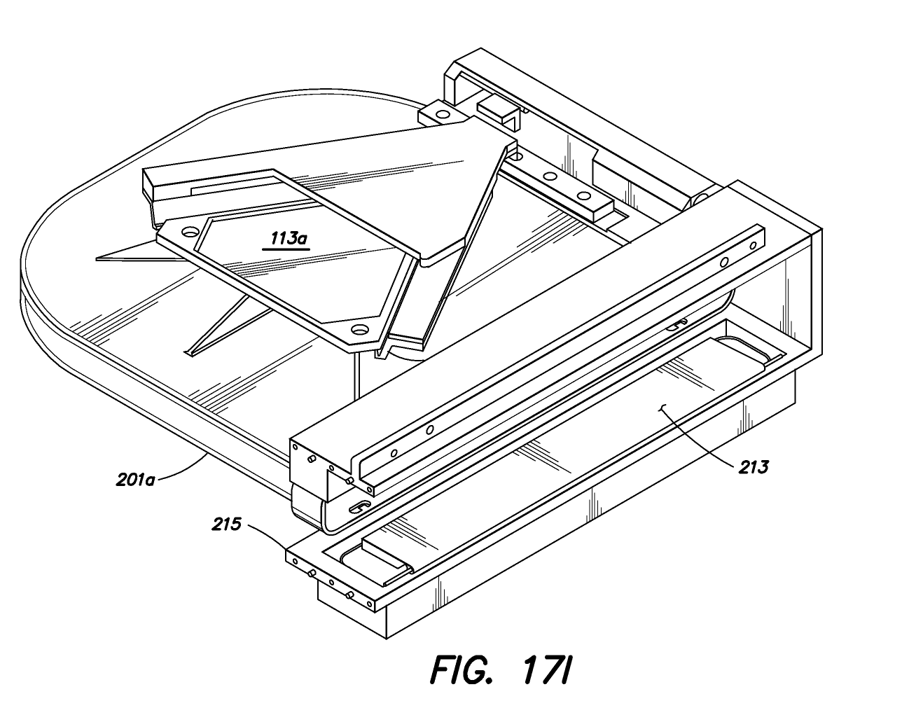

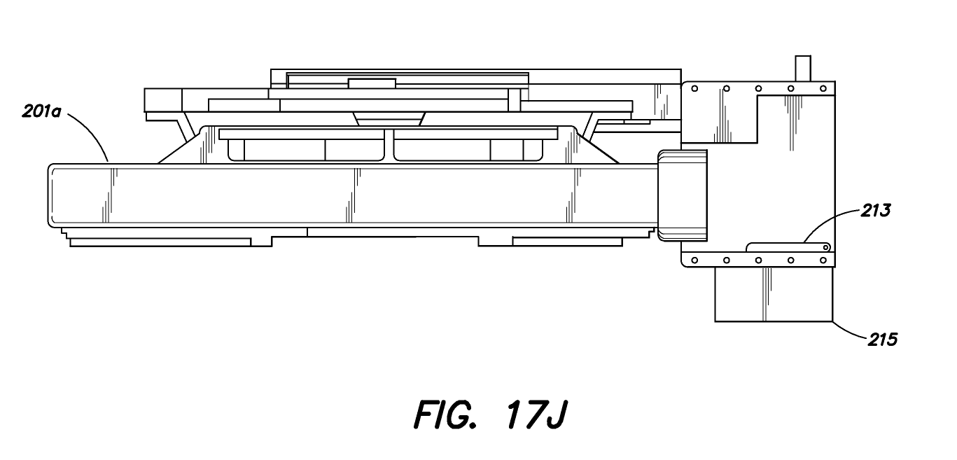

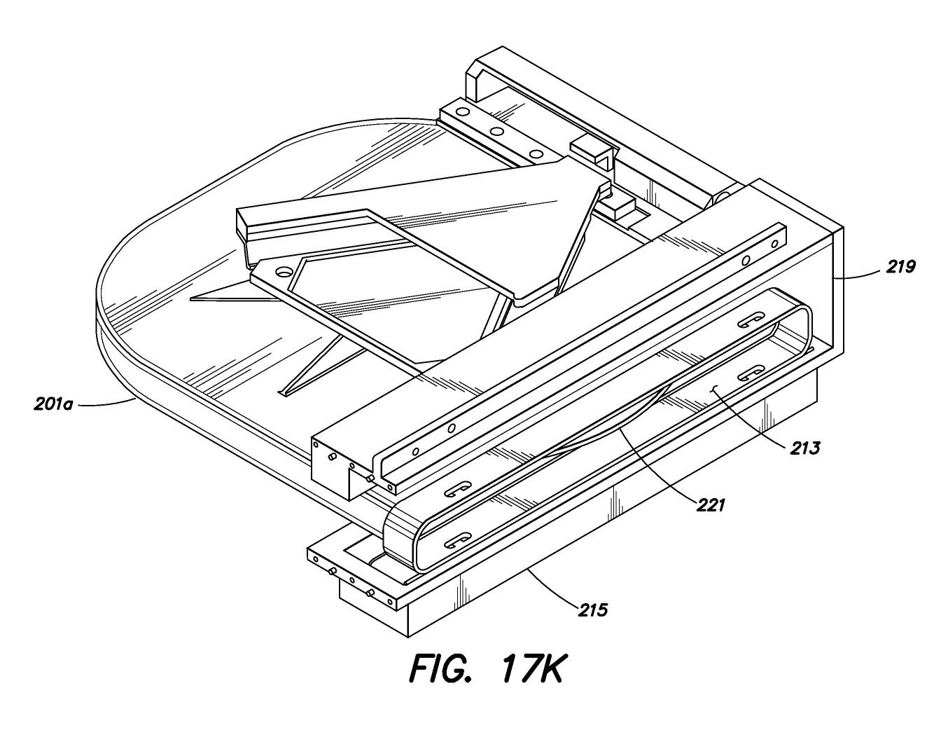

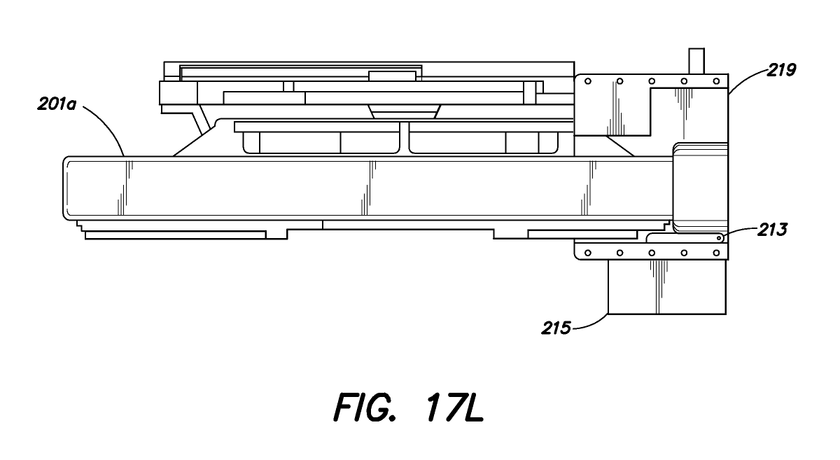

FIGS. 17A-L illustrate a first exemplary embodiment of a door opening mechanism 209 for opening the door 203 of the substrate carrier 201a. A similar door opening mechanism may be employed with substrate carriers 201b-d. With reference to FIGS. 17A-L, the substrate carrier 201a is supported at a loadport location 211 using the blade receivers 121a, 121b and the overhead transfer flange 113a (e.g., allowing substrate carriers to be stacked with a high packing density). The door opening mechanism 209 includes a supporting member 213 that is adapted to contact and support the door 203 of the substrate carrier 201a, and pivot the door 203 below the remainder of the substrate carrier 201a (e.g., into a housing 215) as described further below. A linear actuator or other actuator 217 (e.g., a pneumatic, motor driven, etc., actuator) may be employed to dock/undock the substrate carrier relative to the door opening mechanism 209 and/or a loadport 219 of the loadport location 211.

In operation, the substrate carrier 201a is supported at the loadport location 211 by the blades 121a, 121b (via the overhead transfer flange 113a of the substrate carrier 201a) as shown in FIGS. 17A and 17B. The door 203 of the substrate carrier 201a is then moved toward and brought into contact with the supporting member 213 via the actuator 217 (FIGS. 17C-D). As will be described further below, the supporting member 213 may unlatch and support the door 203 in response to such docking motion.

Following unlatching of the door 203, the substrate carrier 201a is moved away from the loadport 219, leaving the door 203 supported by the supporting member 213 (FIGS. 17E-F). The supporting member 213 then is lowered (e.g., via an actuating mechanism not shown) into the housing 215 (FIGS. 17G-J). In this position, the door 203 is positioned below the substrate carrier 201a, and in the embodiment shown, in a substantially horizontal plane. Such an embodiment reduces the amount of space required to accommodate the door 203 (e.g., allowing closer loadport stacking). Once the door has been lowered, the substrate carrier 201a may be re-docked with the loadport 219 (e.g., to allow a substrate 221 to be removed therefrom) as shown in FIGS. 17K-L. Note that in the above configuration, the supporting member 213 is positioned above the door 203 and may protect the door 203 from being contaminated by particles generated during docking or undocking of the substrate carrier 201a. The supporting member 213 may be formed from any suitable material (e.g., a metal such as aluminum or the like).

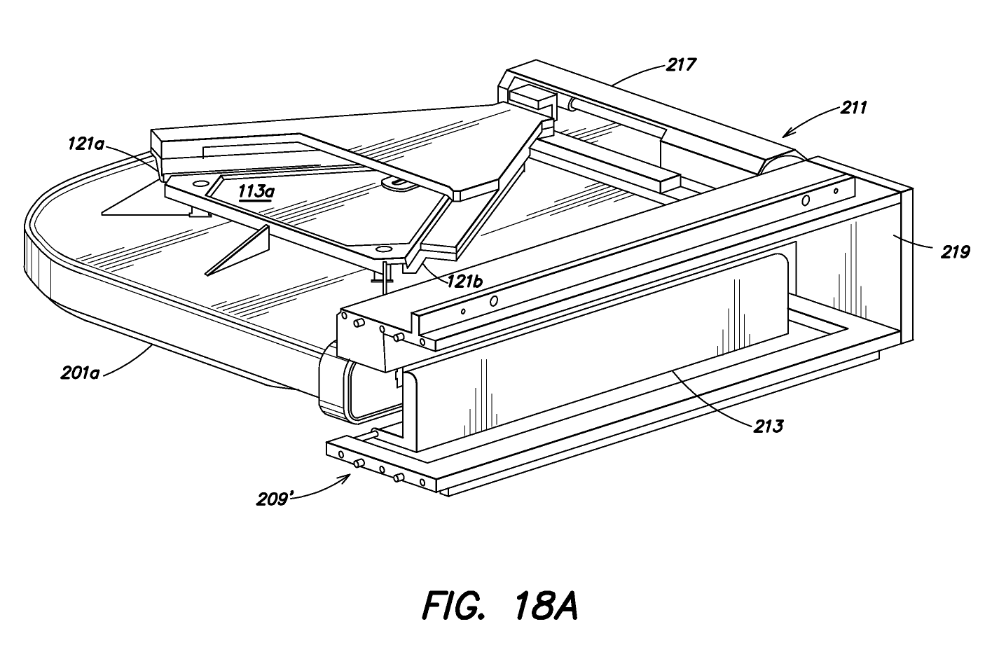

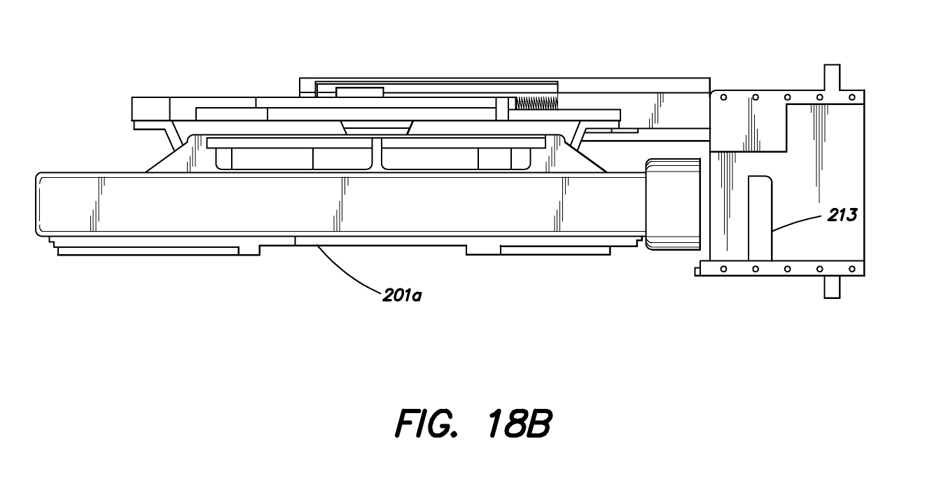

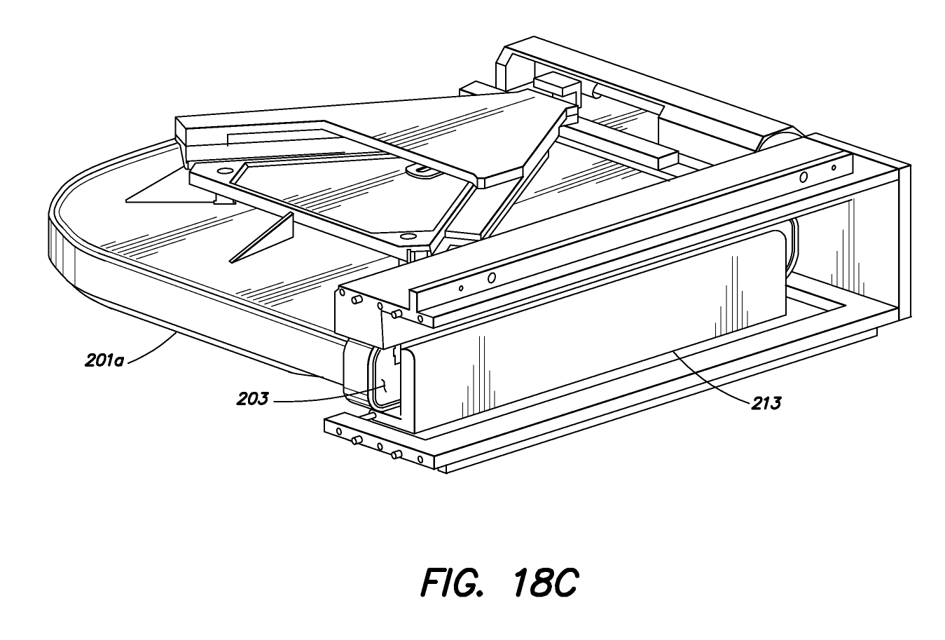

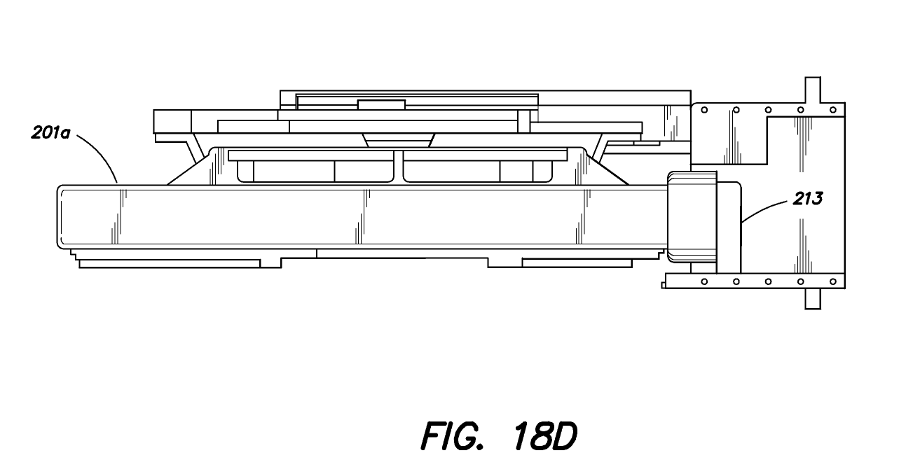

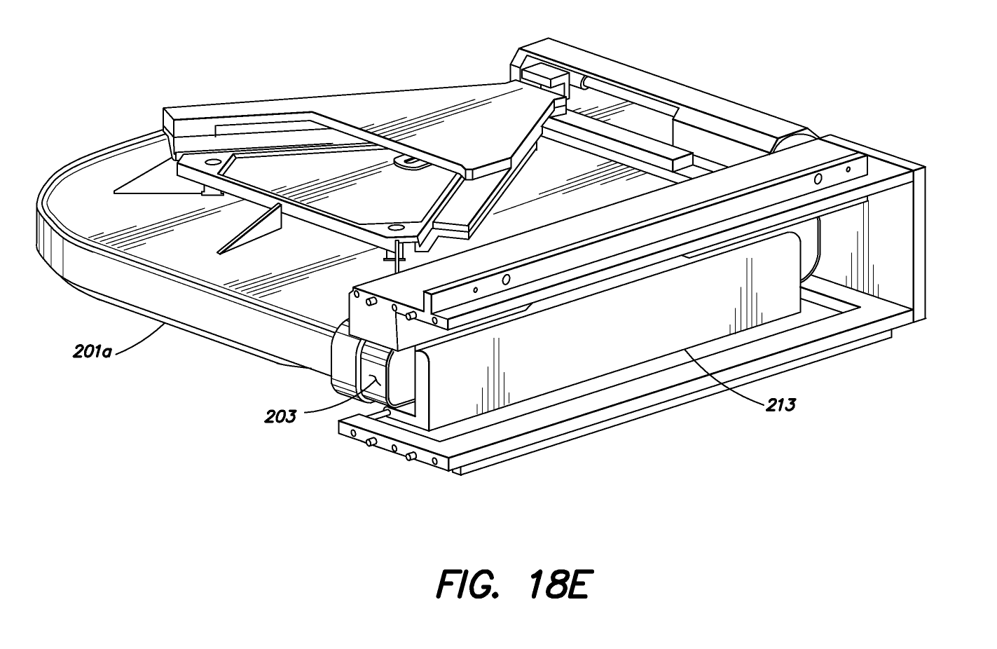

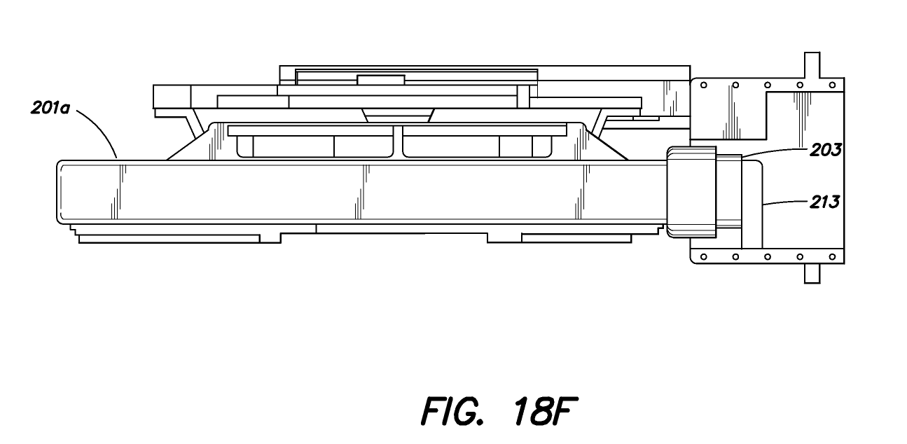

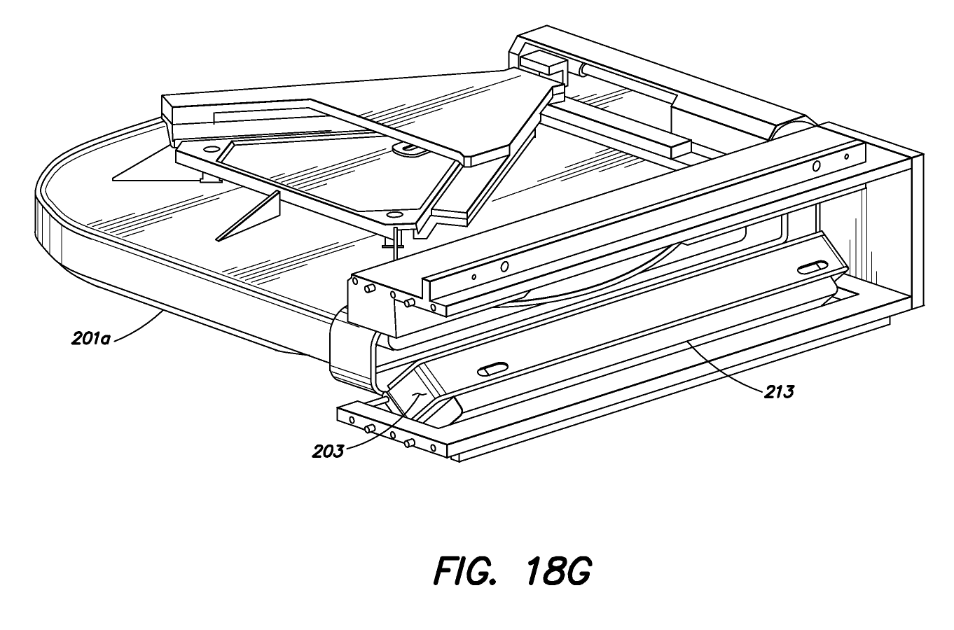

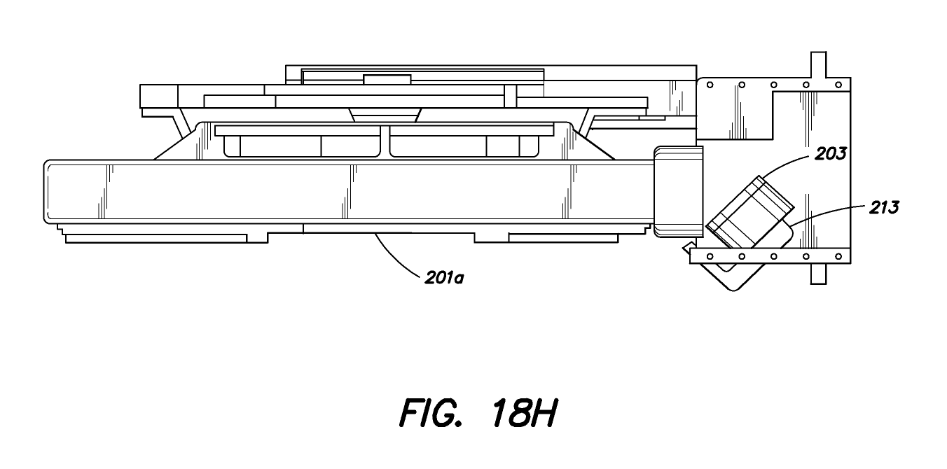

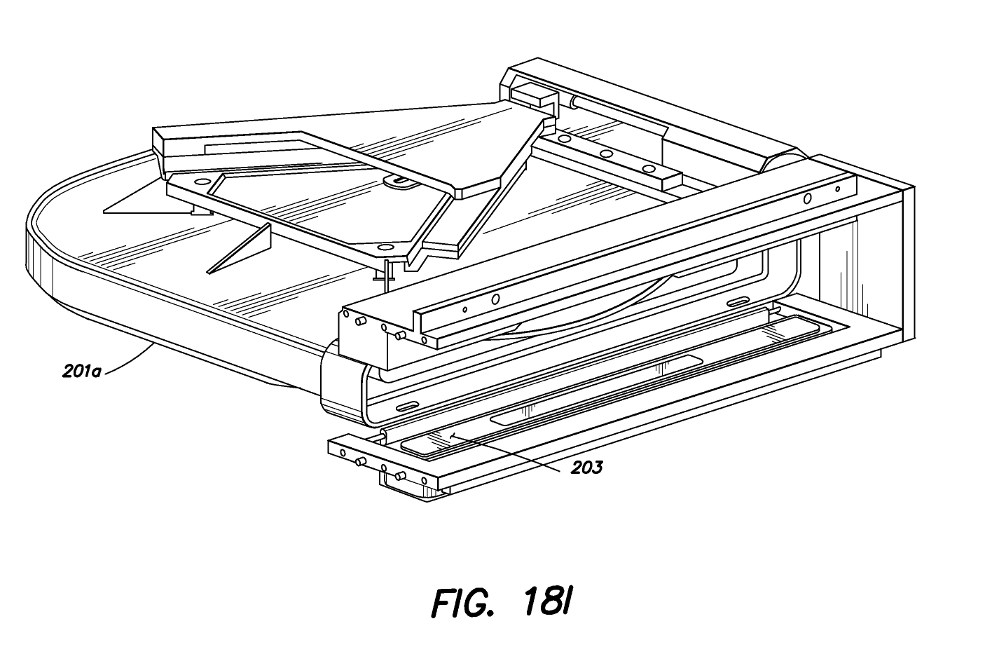

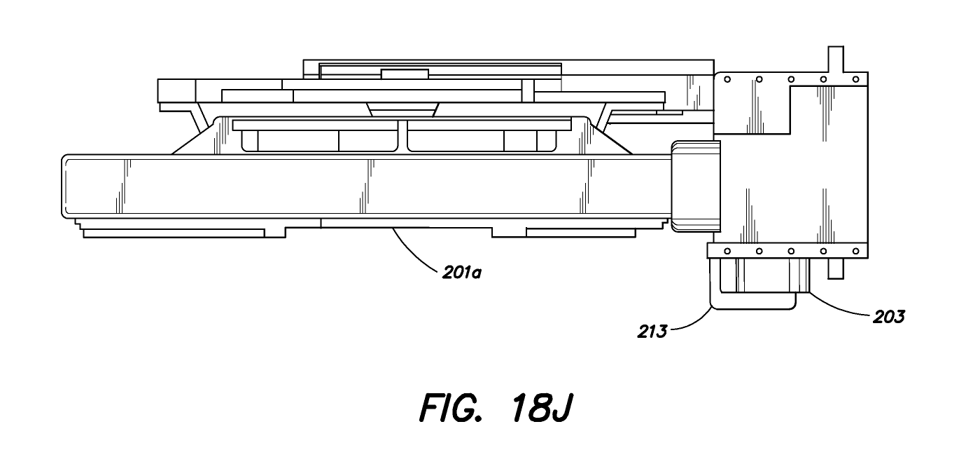

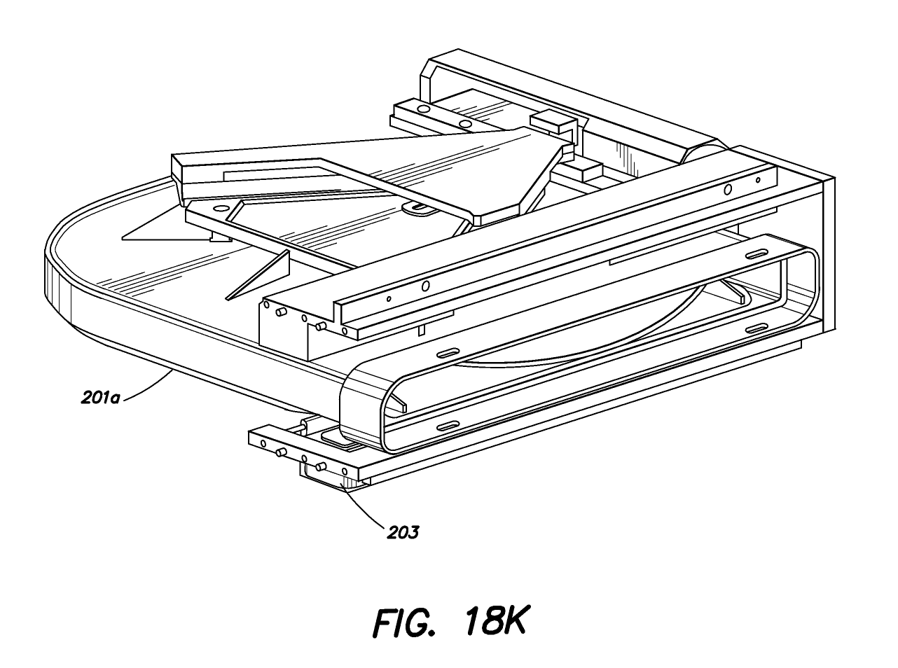

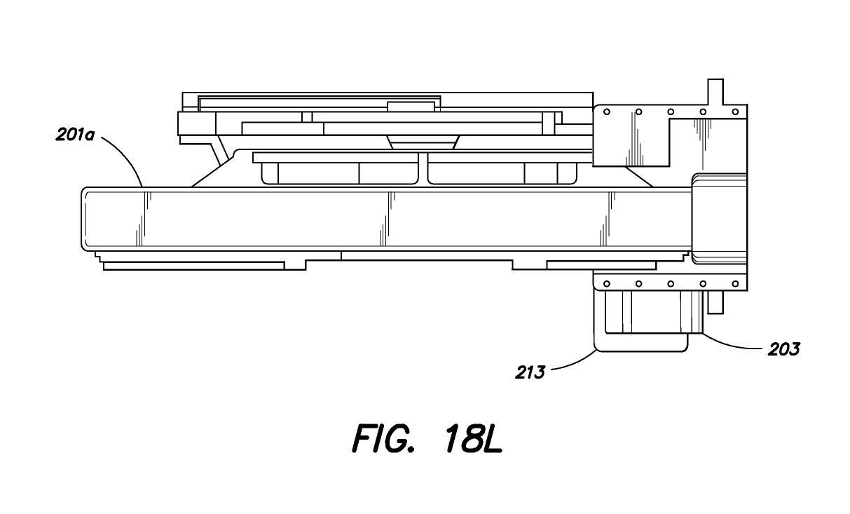

FIGS. 18A-L illustrate a second exemplary embodiment of a door opening mechanism 209′ for opening the door 203 of the substrate carrier 201a. A similar door opening mechanism may be employed with substrate carriers 201b-d. With reference to FIGS. 18A-L, the substrate carrier 201a is supported at a loadport location 211 using the blade receivers 121a, 121b and the overhead transfer flange 113a (e.g., allowing substrate carriers to be stacked with a high packing density). The door opening mechanism 209′ includes a supporting member 213 that is adapted to contact and support the door 203 of the substrate carrier 201a, and pivot the door 203 below the remainder of the substrate carrier 201a as described further below. A linear actuator or other actuator 217 (e.g., a pneumatic, motor driven, etc., actuator) may be employed to dock/undock the substrate carrier relative to the door opening mechanism 209′ and/or a loadport 219 of the loadport location 211. The door opening mechanism 209′ of FIGS. 18A-L operates similarly to the door opening mechanism 209 of FIGS. 17A-L, except that the door 203 faces toward the substrate carrier 201a when the supporting member 213 is pivoted downward as shown in FIGS. 18G-L. In such a configuration, the door 203 may be exposed to particles generated during docking/undocking of the substrate carrier 201a.

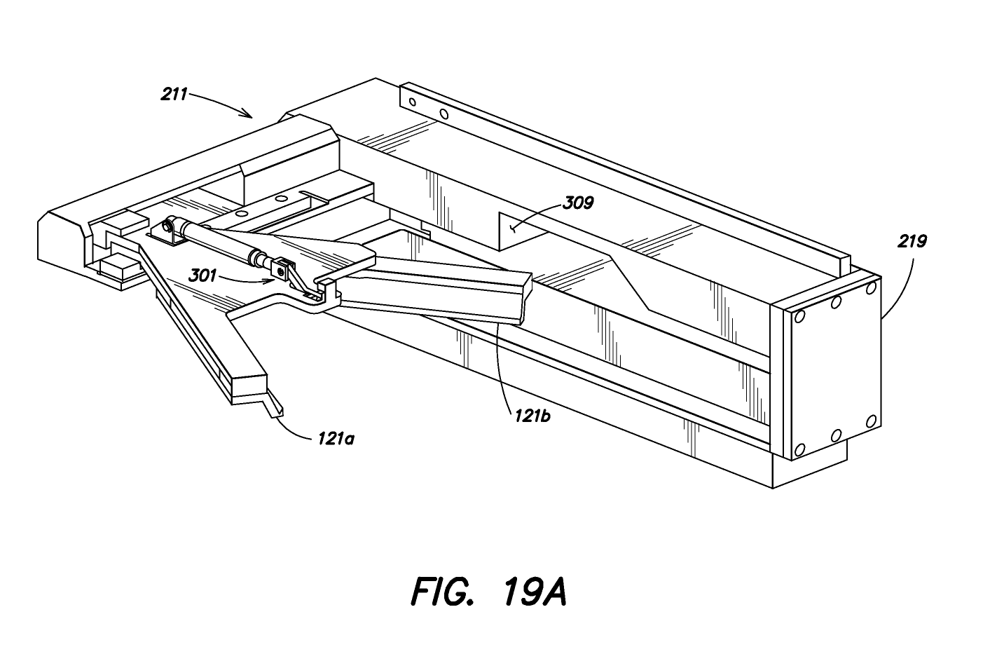

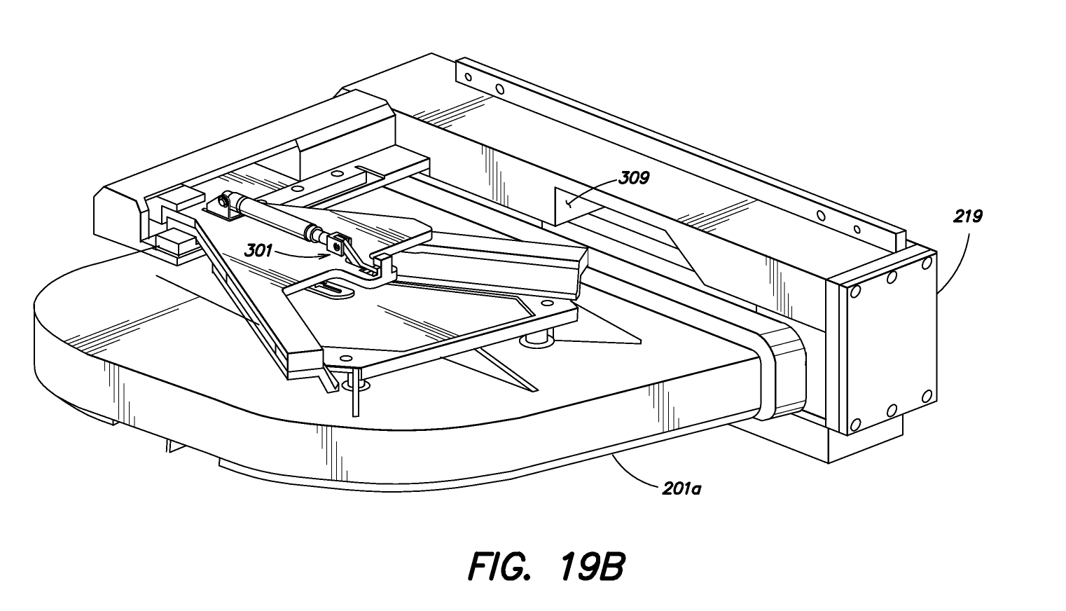

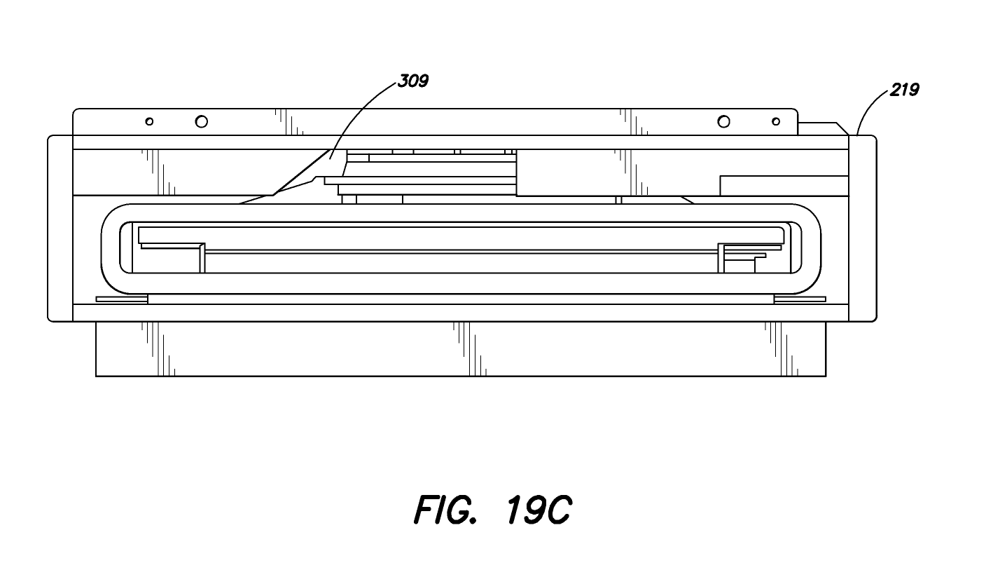

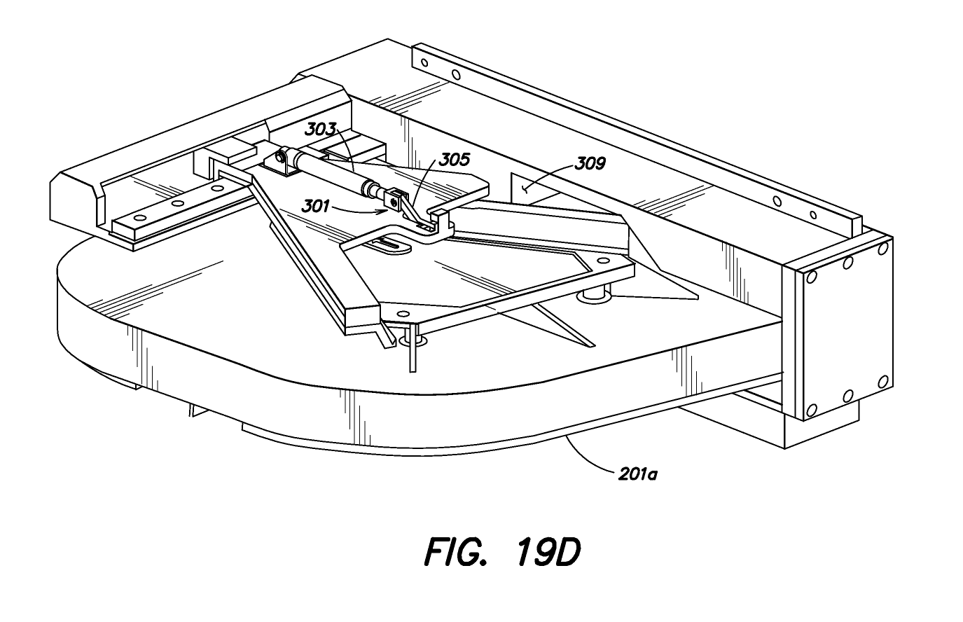

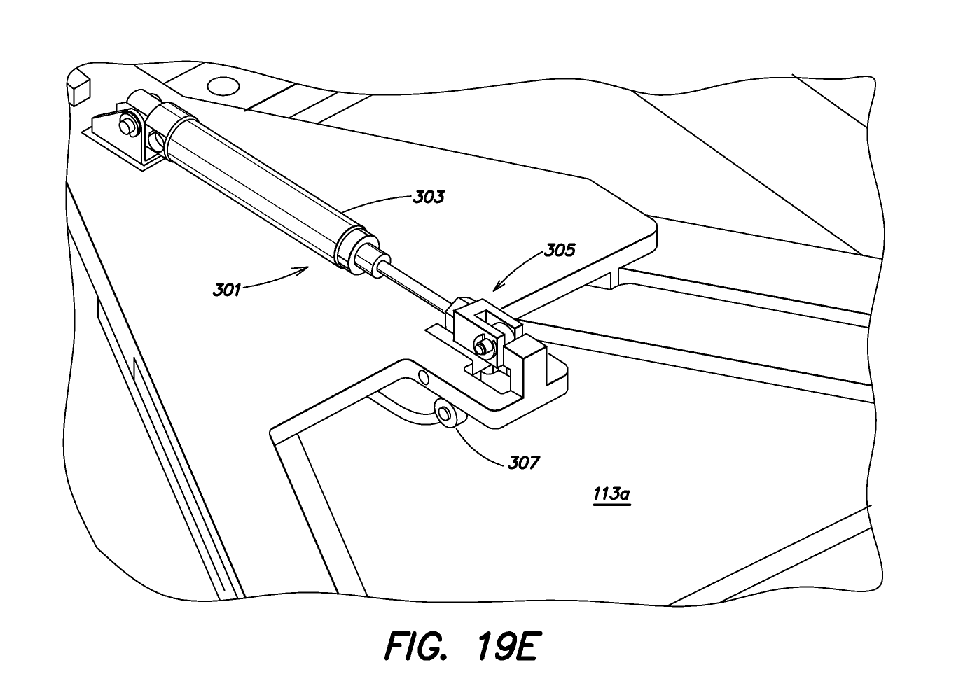

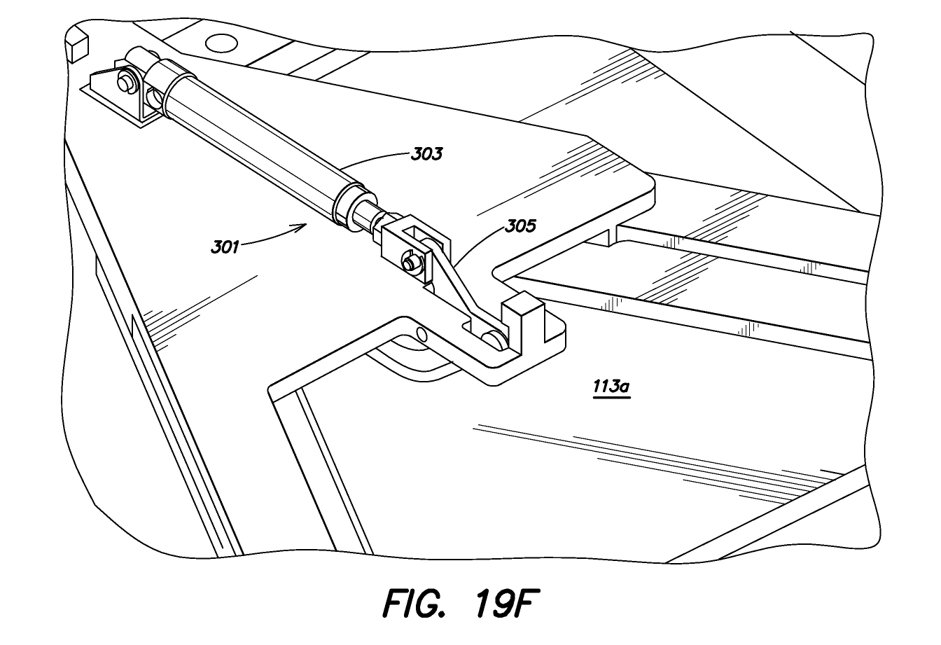

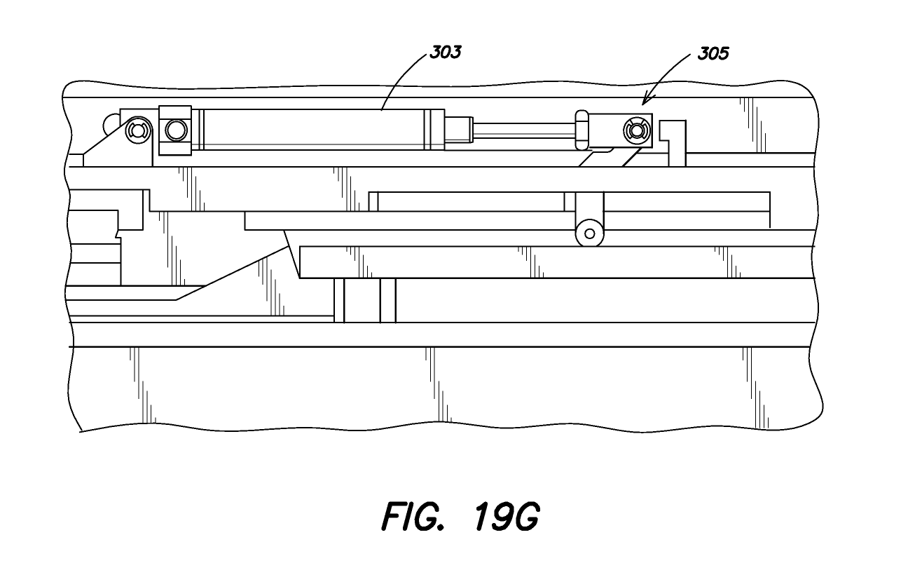

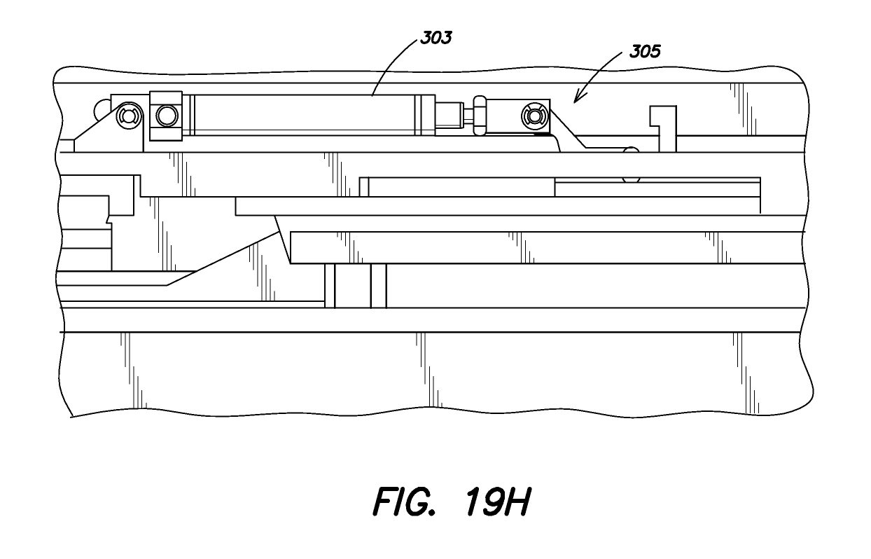

FIGS. 19A-19H illustrate an exemplary clamping mechanism 301 that may be employed to secure the substrate carrier 201a (or any other substrate carrier described herein) relative to the blades 121a, 121b during storage, docking, undocking, etc. of the substrate carrier 201a. With reference to FIGS. 19A-19H, the clamping mechanism 301 includes an actuating mechanism 303 (e.g., a linear actuator such as a pneumatic actuator) coupled to a pivot member 305 (FIGS. 19D-19H). The pivot member 305 includes a contact member 307 (e.g., one or more wheels) adapted to contact the overhead transfer flange 113a of the substrate carrier 201a so as to prevent the substrate carrier 201a from disengaging with the blades 121a, 121b as described below.

In operation, the actuating member 303 is retracted (FIG. 19A) so that the contact member 307 (FIG. 19E) will not interfere with the substrate carrier 201a when it is loaded onto the blades 121a, 121b. The substrate carrier 201a then is loaded onto and supported by the blades 121a, 121b (FIGS. 19A-B and FIG. 19F). The actuating mechanism 303 then is extended so as to pivot the pivot member 305 (FIG. 19E), placing the contact member 307 in contact with the overhead transfer flange 113a of the substrate carrier 201a. The substrate carrier 201a thus is securely held relative to the blades 121a, 121b (e.g., during any docking or undocking movements, or simply during storage of the substrate carrier 201a). To remove the substrate carrier 201a, the actuating member 307 is retracted as shown in FIG. 19F. The substrate carrier 201a then may be removed from the blades 121a, 121b. Note that FIGS. 19A-D illustrate an embodiment of the loadport 219 wherein a notch 309 is formed therein to accommodate the blade 121b and overhead transfer flange 113a.

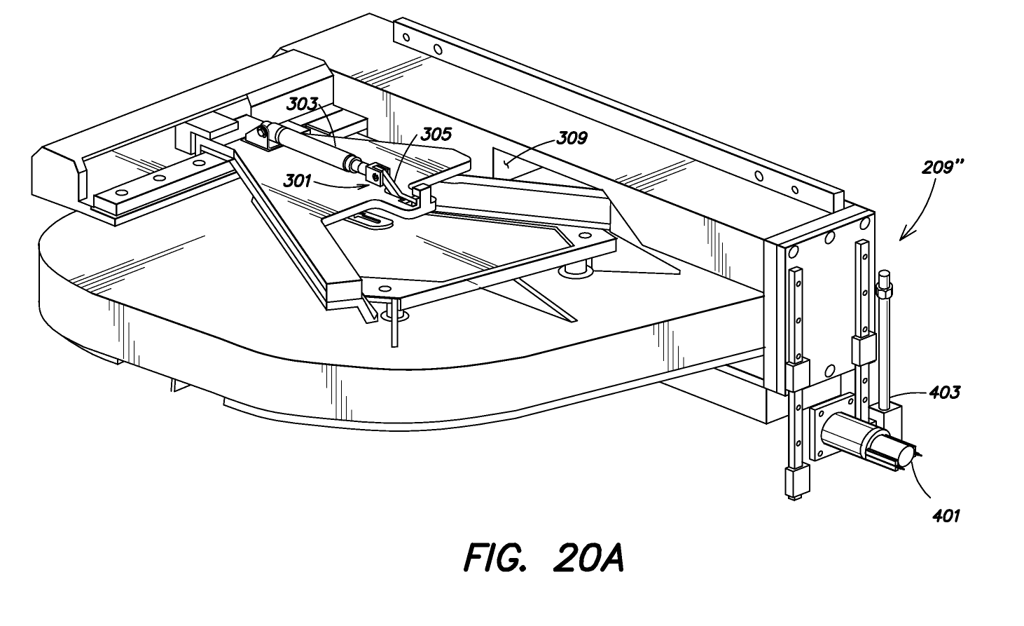

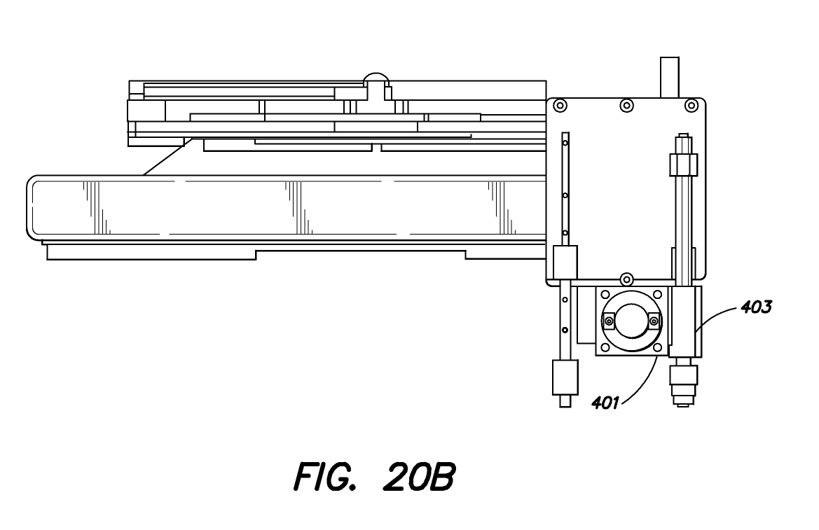

FIGS. 20A-B illustrate a third exemplary embodiment of a door opening mechanism 209″ for opening the door 203 of the substrate carrier 201a. A similar door opening mechanism may be employed with substrate carriers 201b-d. With reference to FIGS. 20A-B, the door opening mechanism 209″ includes a supporting member (not shown) for unlatching and supporting the door 203 of the substrate carrier 201a (in a manner similar to that described with reference to FIGS. 17A-L and FIGS. 18A-L). However, the door opening mechanism 209″ includes a rotation device 401 (e.g., a motor) adapted to rotate the door 203 about a central axis of the door 203 (and/or about a central axis of the supporting member (not shown)); and a linear actuator 403 adapted to lower the door (and/or supporting member) down below the substrate carrier 201a. In this manner, the door 203 may be removed, rotated so as to be approximately horizontal and lowered below the substrate carrier 201a. Note that the door 203 may be rotated by the rotation device 401 after it is lowered via the linear actuator 403. In at least one embodiment, the rotation device 401 may move up and/or down with the door 203 (e.g., via one or more linear slides as shown).

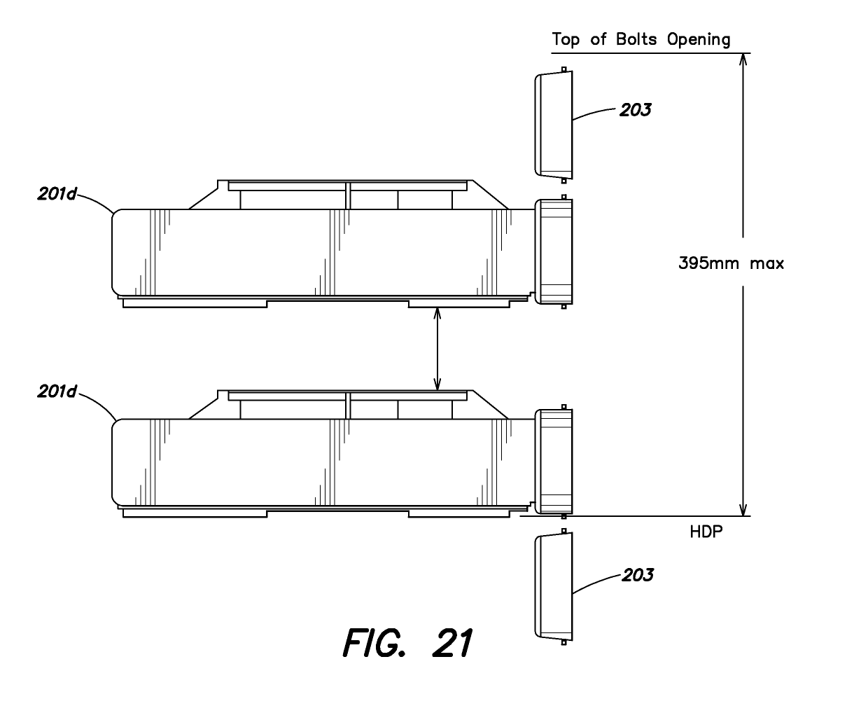

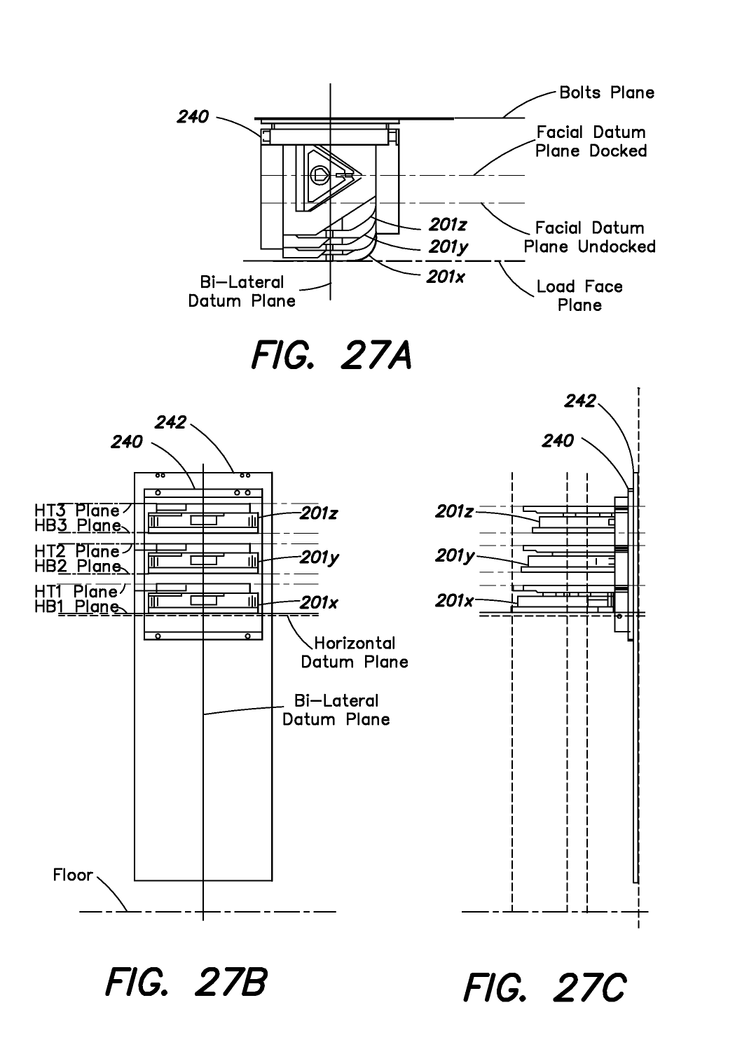

FIG. 21 is a side view illustrating a plurality of 4-substrate, substrate carriers 201d positioned within a Box Opener/Loader to Tool Standard (BOLTS) opening. As introduced above, BOLTS is a well known SEMI standard, defined by the SEMI E63 standard. As is well known in the art, SEMI standards are standards set by the Semiconductor Equipment and Materials International (SEMI), an industrial association largely of semiconductor manufacturers. The SEMI E63 standard specifies the tool side of the mechanical interface between the main part of a process or metrology tool and the component that opens boxes and presents the boxes to the tool wafer handler for unloading and loading 300 mm wafers. The box opener/loader unit may include one or more loadports. A BOLTS opening as defined by the SEMI E63 standard, provides an interface for carriers with a capacity of 13 and 25 wafers (Abstract for SEMI E63). As is also well known in the art, a BOLTS opening is defined by several planes, such as depicted in FIGS. 21, and 27A-C. For instance, the horizontal datum plane (HDP) is the plane from which projects the kinematic-coupling pins on which a substrate carrier may sit, when supported from underneath. Additional substrate carriers may be positioned within a BOLTS opening if smaller size substrate carriers are employed (e.g., 1-, 2- or 3-substrate substrate carriers). As will be discussed in greater detail below, three substrate carriers, for example, each adapted to hold 2 substrates, may be positioned within a standard BOLTS opening. Other numbers of “small lot” substrate carriers may be positioned within a standard BOLTS opening.

As used herein, a “small lot” size substrate carrier refers to a substrate carrier that is adapted to hold significantly fewer substrates than a conventional “large lot” substrate carrier that typically holds 13 or 25 substrates. As an example, in one embodiment, a small lot substrate carrier is adapted to hold 5 or less substrates. Other small lot carriers may be employed (e.g., small lot carriers that hold 1, 2, 3, 4 or more than five substrates, but significantly less than that of a large lot size substrate carrier, generally referring to carriers holding 25 substrates). In general, each small lot substrate carrier may hold too few substrates for human transport of substrates carriers to be viable within a semiconductor device manufacturing facility.

In one or more embodiments, an independently controllable loadport location and/or door opening mechanism (not shown in FIG. 21), such as any of the loadport locations and/or door opening mechanisms described herein or any other suitable loadport location and/or door opening mechanism, may be provided for each substrate location within the BOLTS opening. In this manner, each substrate carrier within the BOLTS opening may be individually and independently docked, opened, accessed, closed, undocked and the like.

Further, in at least one embodiment, substrate positioning within the BOLTS opening may be selected such that:

(a) the top substrate slot within the top substrate carrier positioned within the BOLTS opening occupies a location no higher than the top substrate slot (e.g., slot 1) of a standard 25-substrate, substrate carrier positioned within the BOLTS opening; and

(b) the bottom substrate slot within the bottom substrate carrier positioned within the BOLTS opening occupies a location no lower than the bottom substrate slot (e.g., slot 25) of a standard 25-substrate, substrate carrier positioned within the BOLTS opening.

In this manner, standard equipment front end module (EFEM) substrate handlers or robots may be employed to access each substrate carrier within the BOLTS opening (e.g., as the envelope, or range of motion, of such substrate handlers and/or robots will be adequate to access each substrate position of each substrate carrier within the BOLTS opening). By positioning multiple, small lot substrate carriers with a BOLTS opening, and by limiting substrate positions within such small lot substrate carriers to the position range of substrates within a standard 25-substrate, substrate carrier (and therefore to have the small lot substrate carriers occupy an envelope substantially similar to that of a large lot substrate carrier), existing equipment interfaces for 25-substrate, substrate carriers may be retrofitted in accordance with the present invention for use with small lot substrate carriers.

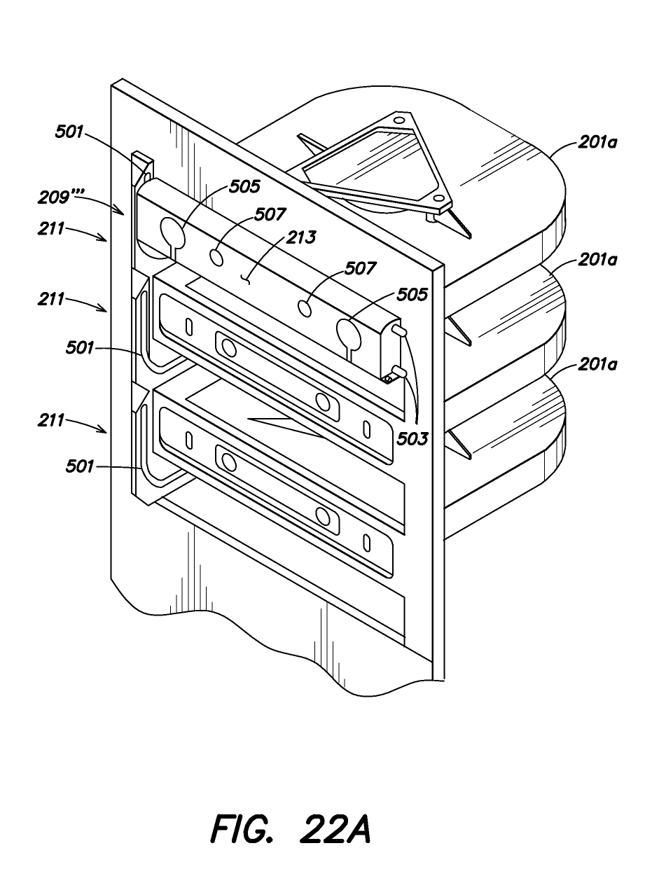

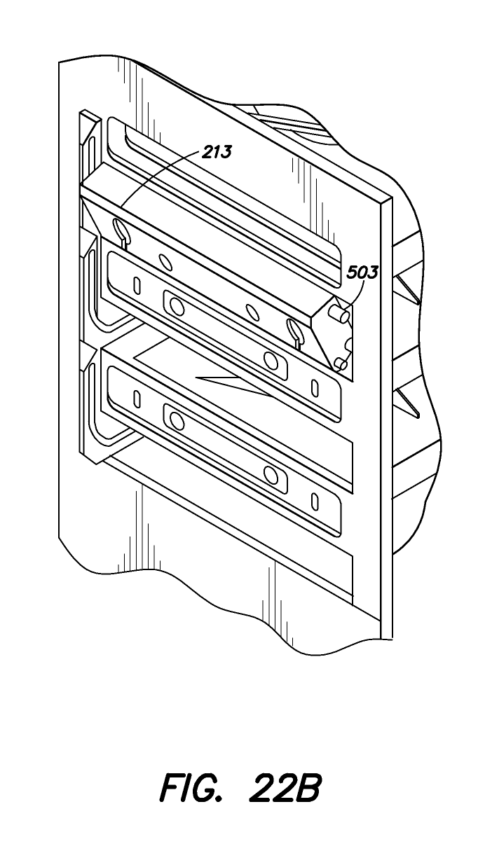

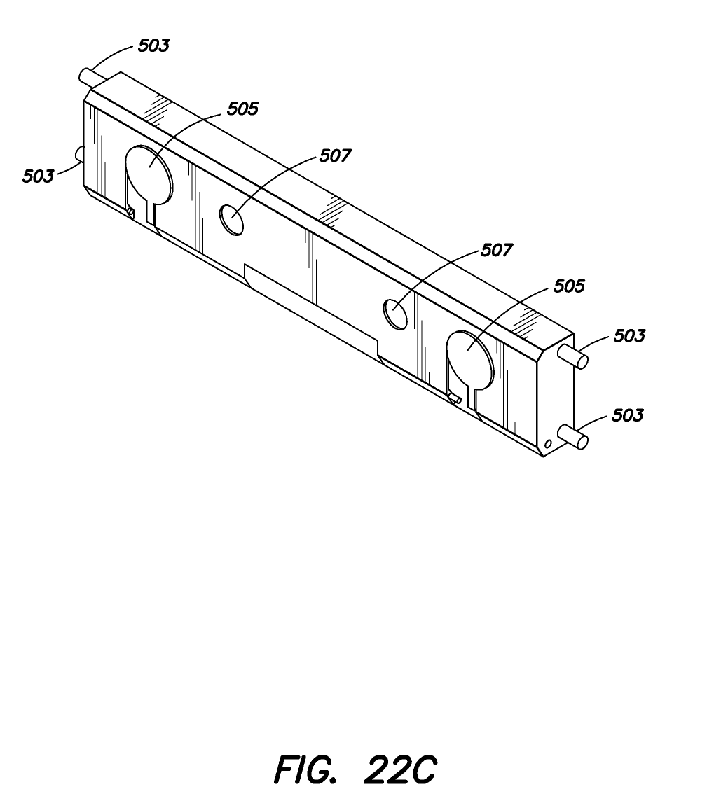

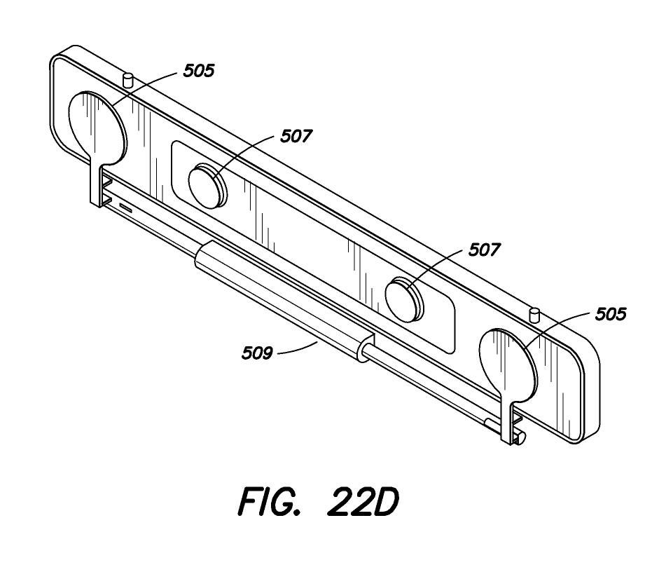

FIGS. 22A-E illustrate a fourth exemplary embodiment of a door opening mechanism 209′″ for opening the door 203 of the substrate carrier 201a. A similar door opening mechanism may be employed with substrate carriers 201b-d. With reference to FIGS. 22A-E, the door opening mechanism 209′″ includes a supporting member 213 (FIG. 22B) that is adapted to contact and support the door 203 of the substrate carrier 201a, and pivot the door 203 below the remainder of the substrate carrier 201a as described further below. One or more sides of a loadport 211 may be provided with a channel 501 (e.g., a cam slot) adapted to accommodate one or more features 503 (e.g., cam followers) of the supporting member 213. The channel 501 may be employed to lower and pivot the door 203 of the substrate carrier 201a below the remainder of the substrate carrier 201a.

In operation, a substrate carrier 201a is docked into contact with the supporting member 213. In the embodiment shown, unlatching features 505 of the supporting member 213 engage latches of the substrate carrier 201a (described below) and unlatch the door 203. Engaging features 507 (e.g., electromagnets in the embodiment shown) contact and hold the door 203 as the substrate carrier 201a is moved away from the loadport 211 (FIG. 22A). An actuating mechanism (not shown) then may lower the supporting member 213 and the door 203 below the substrate carrier 201a using the channel 505 and features 503 of the supporting member 213 (FIG. 22B). In at least one embodiment, a linkage 509 (FIG. 22D) may be employed to move the unlatching features 505 simultaneously.

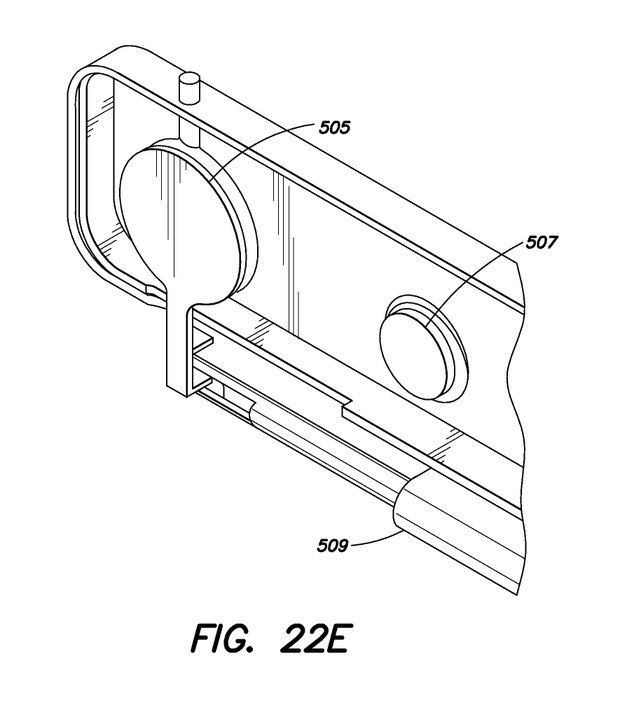

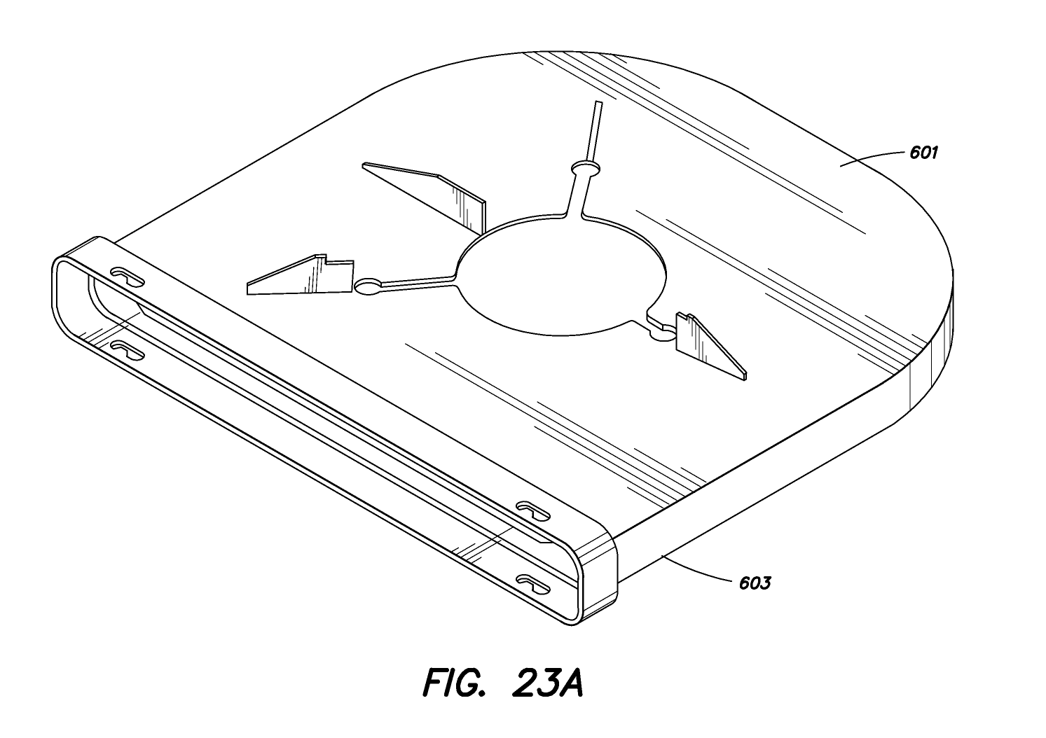

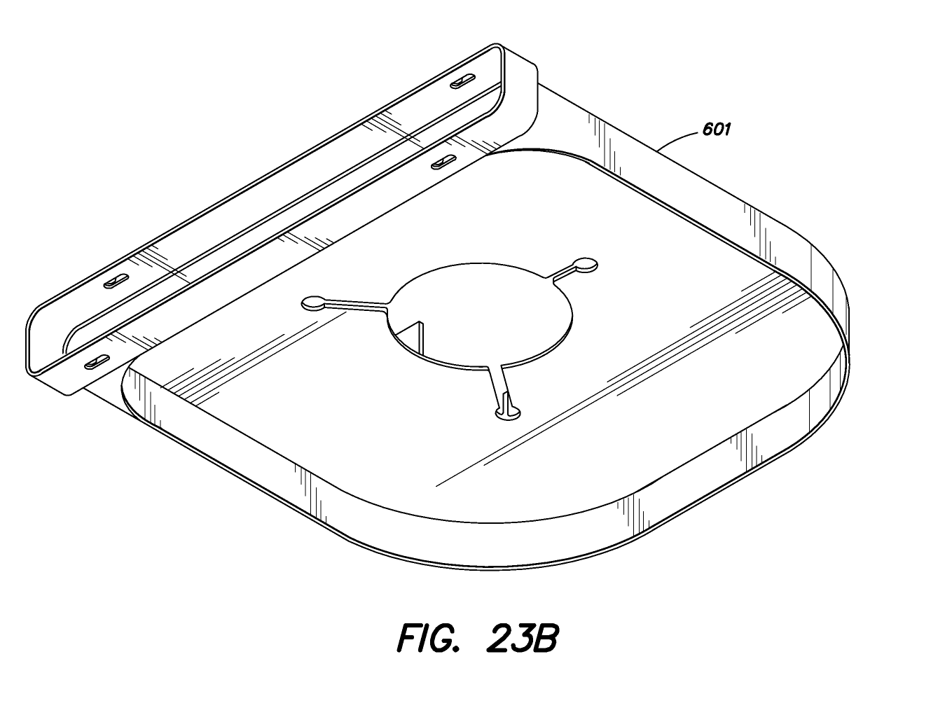

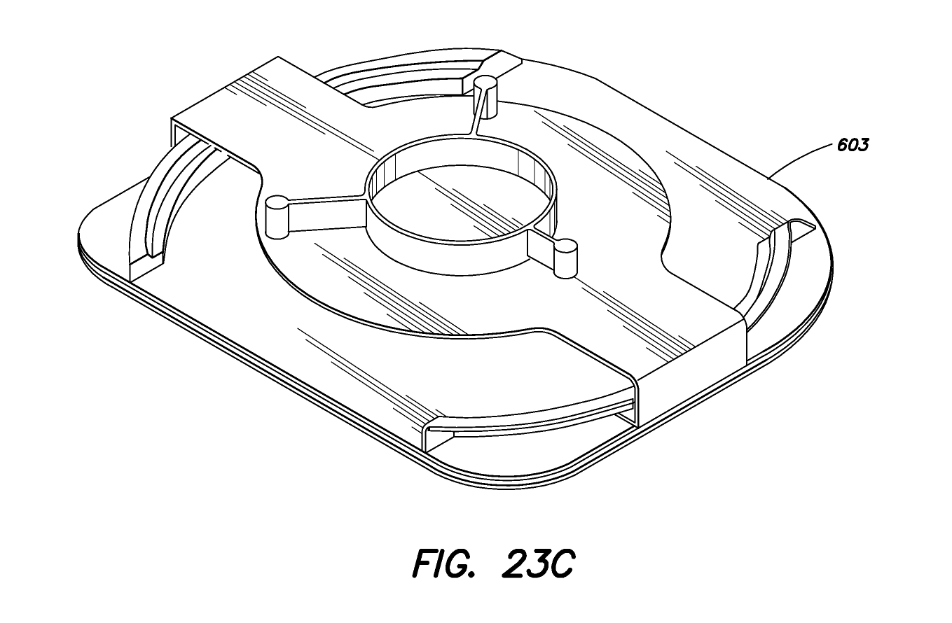

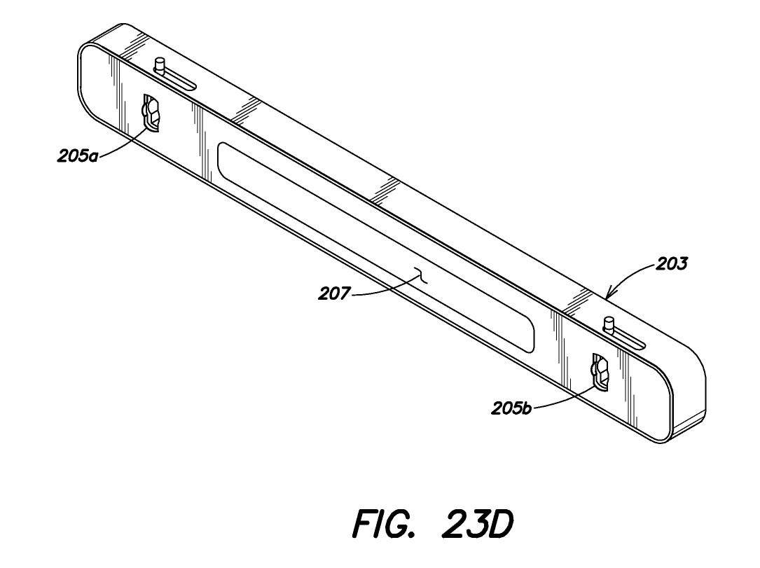

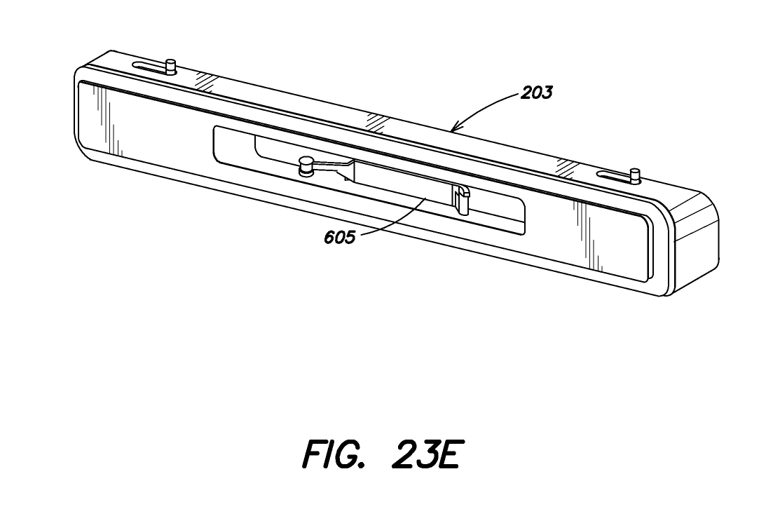

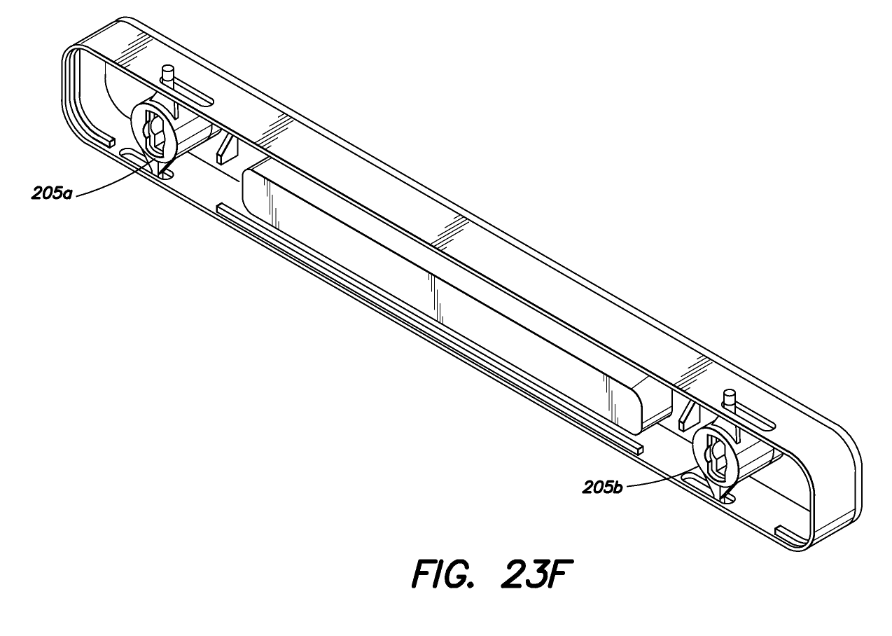

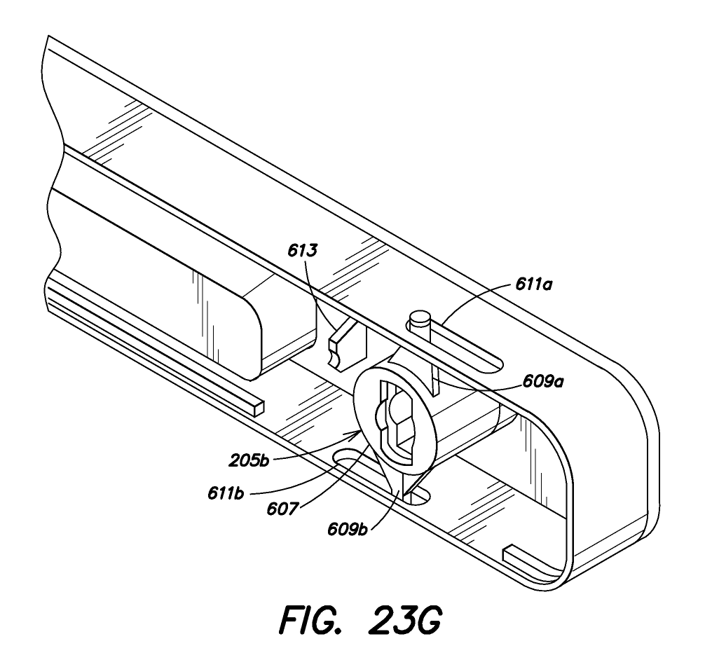

FIGS. 23A-23G illustrate various components of an exemplary substrate carrier 201a. The substrate carriers 201b-d may be similarly configured. With reference to FIGS. 23A-G, the substrate carrier 201a includes a top 601 and a bottom 603. Front and back perspective views of the door 203 are shown in FIGS. 23D-E, respectively. The door 203 includes the latches 205a,b and region 207 described previously, as well as a substrate support member 605 (FIG. 23E) adapted to contact and support a substrate positioned within the substrate carrier 201a when the door is latched thereto. FIGS. 23F-23G illustrate the door 203 with a front cover removed to reveal the latches 205a,b.

FIG. 23G is an enlarged portion of the latch 205b. As shown in FIG. 23G, the latch 205b includes a rotary portion 607 that may be engaged and rotated by an unlatching mechanism of a substrate carrier door opener. First and second extensions 609a, 609b of the rotary portion 607 extend radially from the rotary portion and engage guide features 611a, 611b of the substrate carrier 201a. The guide features 611a, 611b may latch (lock) the door 203 in position (e.g., when the extensions 609a, 609b are in the position illustrated in FIG. 23G). To unlatch the door, the rotary portion 607 may be rotated (clockwise in the embodiment of FIG. 23G) such that the extensions 609a, 609b disengage the guide features 611a, 611b. In at least one embodiment, the rotary portion 607 may be rotated by about 90 degrees so that the extension 609a, 609b lie within an approximately horizontal plane. A retaining feature 613 may be provided that engages one of the extensions 609a, 609b so as to hold the rotary portion 607 in a known position. In such a position, the door 203 may be removed from the substrate carrier 201a.

In at least one embodiment of the invention, the overhead transfer flange 113a may be encoded with information (e.g., regarding the contents of the substrate carrier 201a-d to which the overhead flange 113a is attached, the ID of the substrate carrier 201a-d, processes to be performed on substrates stored within the substrate carrier 201a-d, etc.). For example, a tag or other readable medium (not separately shown) may be attached to the overhead flange 113a and read by a reader (not separately shown) provided at a loadport, storage location, or other location.

Further, in some embodiments, following unlatching of the door 203, when the substrate carrier 201a is moved away from the loadport 219 leaving the door 203 supported by the supporting member 213 (FIGS. 17E-F), the substrate carrier 201a may remain in a tunnel defined by the loadport, and clean air provided by a factory interface (not shown) may flow over the opening of the substrate carrier 201a. For example, an annulus may form between the outer surface of the substrate carrier 201a and an inner surface of the loadport and clean air may flow from the factory interface through the loadport (e.g., between the outer surface of the substrate carrier 201a and the inside surface of the loadport) via the annulus. Clean air flow may prevent particles from contaminating any substrates inside the substrate carrier 201a.

Any of the substrate carriers described herein may be supported by other types of overhead flanges or by other suitable supporting members or supporting member locations. It will be understood that the invention also may be employed with any type of substrates such as a silicon substrate, a glass plate, a mask, a reticule, etc., whether patterned or unpatterned; and/or with apparatus for transporting and/or processing such substrates.

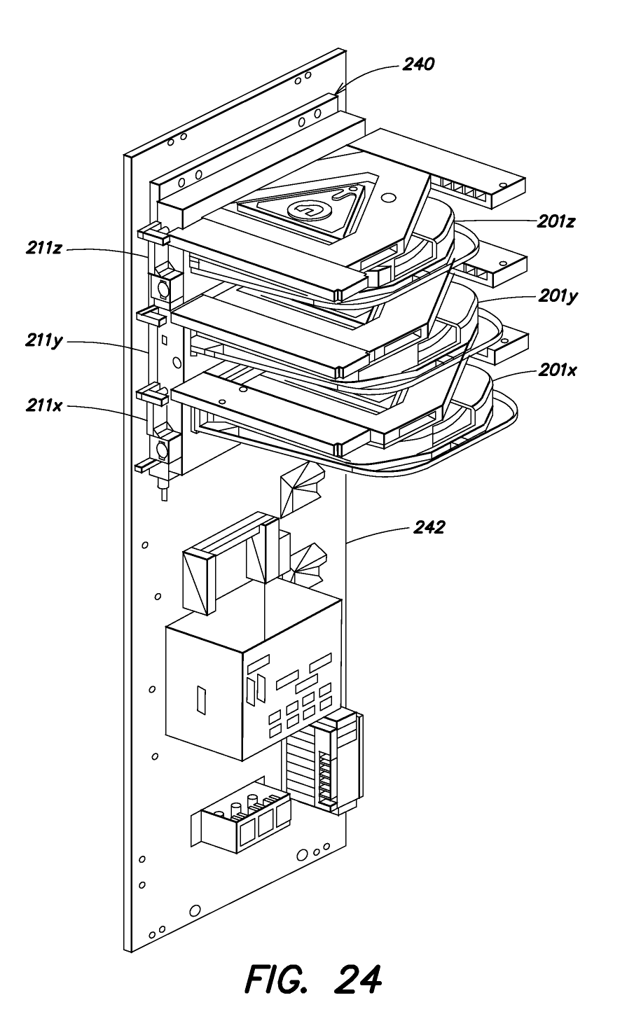

FIG. 24 is a perspective view of an exemplary small lot loadport configuration (SLLC) 240 having three small lot substrate carriers 201x, 201y and 201z. FIG. 24 shows the general concept of a SLLC 240 that has improved compatibility with existing EFEMs that have been designed for use with 25-wafer FOUPs and loadports. The depicted SLLC 240 is capable of manipulating up to 3 small lot carriers 201x-z, such as small lot FOUPs. The SLLC 240 may include a mounting plate 242 for mounting to an EFEM. The mounting plate 242 may include, for instance, all mechanical, electrical, and fluid connections necessary for retrofitting an existing large lot loadport with the SLLC 240 (e.g., AC/DC power, compressed air, vacuum, communication interfaces, mechanical interconnects, etc.). For instance, one or more of these, e.g., AC/DC power, may come from the EFEM. Likewise, since most or all electrical or electro-mechanical components needed for use on the SLLC 240 are available in 24 VDC versions, it may be cost-effective to power the SLLC 240 using 24 VDC directly from the EFEM and eliminate any separate DC power supplies on the SLLC 240. As such, a preferred embodiment of the present invention would provide a 24 VDC version of the SLLC 240.

Mounting plate 242 also may be self-supporting and transportable, such as being supported by a base (not shown) that, for example, may include casters for ease of transport. In such a scenario, the SLLC 240 may be temporarily installed at a large lot loadport of an EFEM by rolling the base into place and connecting all necessary connections between the SLLC 240 and the large lot loadport.

Carriers 201x-z may be, for instance, of a design of carriers 201a-d. With the exception, for example, of the number of substrate slots and the necessitated dimensions, of a 25-substrate FOUP, a small lot substrate carrier 179, 201a-d, 201x-z of the present invention largely may be compatible with FOUP specifications, and hence may be referred to as small lot FOUP when such relative compatibility is desired. Reference to a small lot substrate carrier 179, 201a-d, 201x-z, in general, may but need not indicate such relative compatibility with FOUP specifications.

In addition, the SLLC 240 preferably is capable of manipulating 3 FOUPs 201x-z independently and simultaneously. More specifically, the loadports 211x-z preferably are able to open or close any of the 3 FOUPs 201x-z, and an EFEM robot preferably is able to access substrates, e.g., wafers, from any of the 3 FOUPs 201x-z, regardless of what operation is being performed on the other FOUPs 201x-z. For example, the EFEM robot should be able to access wafers from FOUP 201y, while the loadport is opening FOUP 201x and closing FOUP 201z, and so on.

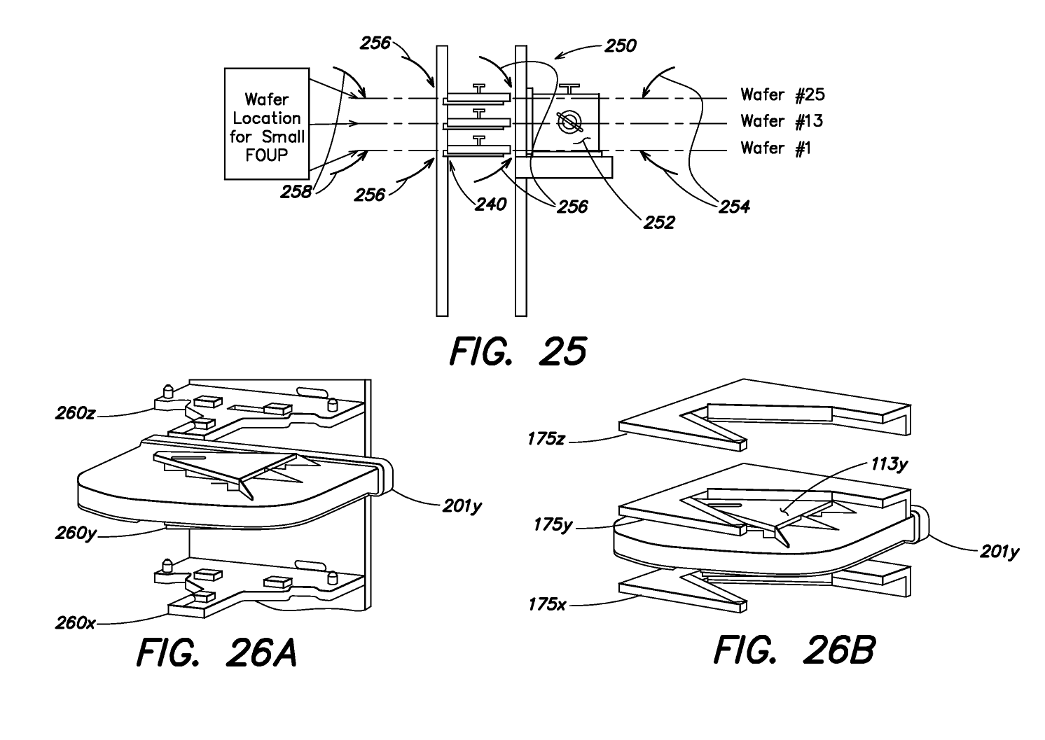

FIG. 25 is a side elevational representation of a small lot loadport configuration 240 compared next to a large lot loadport 250 dimensioned for a 25-substrate large lot substrate carrier 252. This 3-carrier small lot loadport configuration 240 is adapted to fit and operate within a large lot loadport envelope 254, such as is characteristic of a BOLTS opening 256.

By comparison to a BOLTS opening and a 25-substrate FOUP, the present invention allows that:

the example requirements for the hole opening in the EFEM of the tool are substantially the same as specified in SEMI E63, Section 5.3.;

the example requirements for the seal zone between the SLLC 240 and the EFEM of the tool are substantially the same as specified in SEMI E63, Section 5.4.;

the example requirements for the exclusion volume outside the tool from the BOLTS plane are the same as specified in SEMI E63, Section 5.7.; and

the example requirements for the permanent reserved space inside the tool from the BOLTS plane are substantially the same as specified in SEMI E63, Section 5.6.

In general, there typically should be no allowable temporary reserved spaces. The SLLC 240 preferably may not at any time occupy any space inside the tool from the BOLTS plane other than the permanent reserved space defined in Section 2.5.3. SEMI E63, Section 5.6 defines temporary reserved spaces inside the tool from the BOLTS plane. However, the SLLC 240 may deviate from SEMI requirements in order for the 3 door opening mechanisms to be completely independent. More specifically, the EFEM robot may be able to access wafers in a FOUP 201 while other FOUPs 201 at a loadport 211 are opening or closing. Therefore, to avoid any potential interference with the motion of the EFEM robot, the SLLC 240 preferably may not penetrate beyond the BOLTS plane in the robot motion area.

In a FOUP context, the overall envelope for SLLC 240 and the 3 small lot FOUPs fits within the envelope of a SEMI-compliant 25-wafer FOUP, and the wafer positions in the small lot FOUPs are approximately aligned with corresponding wafer positions in a 25-wafer FOUP. The 3-carrier small lot loadport configuration 240 is an example of small lot loadport configuration 240 having a plurality of small lot loadports 211x-z adapted to be coupled to an EFEM and having a small lot loadport envelope 258 substantially similar to the large lot loadport envelope 254, wherein each small lot loadport 211x-z of the configuration 240 is adapted to support a small lot substrate carrier 201x-z.

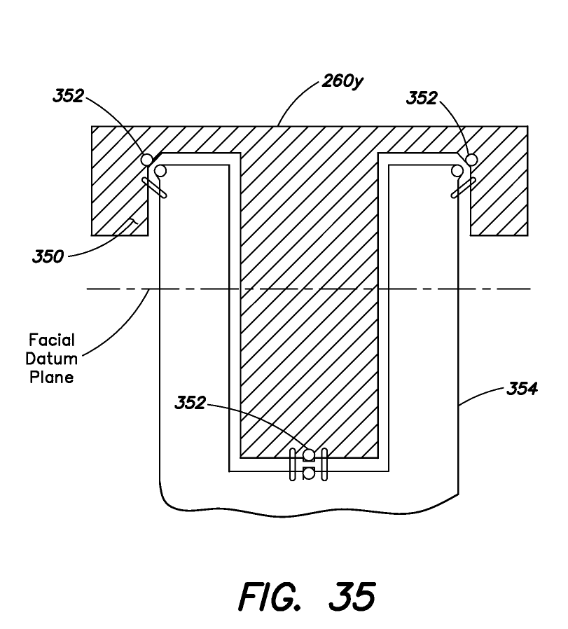

FIGS. 26A and 26B are perspective views of exemplary small lot substrate carriers 201y supported, respectively, from below and above, by corresponding substrate carrier supports 175x-z and 260x-z. In FIG. 26A, the small lot substrate carrier 201y is supported from underneath by a bottom kinematic pin support 260y, discussed in more detail in FIG. 35. In FIG. 26B, the small lot substrate carrier 201y, is supported from the top by a kinematic flange 113y, such as suspended from shelf 175y, akin to loadport 211. Thus, the SLLC 240 may support a FOUP 201x-z from either the bottom using kinematic coupling pins 352, discussed below in reference to FIG. 35, or from the top using a kinematic top flange 113y, discussed above in detail in reference to FIG. 14. While a loadport manufacturer may choose which method to use, it is preferred, however, that all 3 FOUPs 201x-z be supported using the same support and method.

As with current 25-wafer FOUP designs, the top of the small lot FOUP 201y may provide a flange 113a for supporting the small lot FOUP 201y from above. However, while the small lot FOUP 201y may have a top flange 113a, the size and shape of the flange preferably differs from that specified in SEMI E47, such that the small lot FOUP flange 113a is triangular in shape and may have a v-groove that can be used to kinematically secure the FOUP 201y, as discussed above.

FIGS. 27A-C, respectively, are planar, front elevational and side elevational views of a simplified small lot loadport configuration 240. Each of the three illustrated small lot substrate carriers 201x-z is shown at a different stage of docking with the loadport, as is indicated in FIG. 27A. Several datum planes are identified in FIGS. 27A-C that may be used subsequently to specify dimensions and locations of key features of the SLLC 240. In most cases, these datums are substantially identical to datums specified in existing SEMI specifications for 25-wafer FOUPs and loadports. In other cases, new datums have been created that are specific to the SLLC 240.

The Horizontal Datum Plane (HDP) is a horizontal reference plane that is at the load height for 25-substrate FOUPs (900 mm+/−10 mm from the floor) as defined in SEMI E15. This plane is provided for reference and comparison to existing SEMI specs and 25-wafer FOUP/Loadport designs.

The Facial Datum Plane (FDP) is a vertical plane that bisects the substrates and that is parallel to the front side of the carrier 201 (where wafers are removed or inserted). This is substantially the same definition as in SEMI E57. Note that there are two defined positions of the Facial Datum Plane.

The “Undocked” position, depicted by 201x of FIGS. 27A-C, is when the loadport 211x is in position for loading/unloading a FOUP 201x from/to the AMHS. The “Docked” position, depicted by 201z of FIGS. 27A-C, is when the loadport 211z is in position for the EFEM robot to access wafers in the FOUP 201z. The nominal distance between these positions is 70 mm, the same distance defined in SEMI E63. However, this distance may be made to be fully adjustable over a range, e.g., of 70 mm-95 mm, as shown in FIGS. 27A-C, so that all of the loadports 211x-z can be aligned directly beneath an AMHS line of travel even if the EFEM and AMHS are not perfectly aligned.

The Load Face Plane (LFP) is a vertical plane parallel to the Facial Datum Plane and represents the furthest physical boundary plane on the side of the tool where loading of the tool is intended. This is substantially the same definition as in SEMI E15; however, the location of this plane may be defined in this specification, for instance, as 190 mm from the Facial Datum Plane in the undocked position, versus 250 mm in SEMI E15.1.

The Bilateral Datum Plane is a vertical plane that bisects the substrates, e.g., wafers, and is perpendicular to both the Horizontal Datum Plane and Facial Datum Plane. This is substantially the same definition as in SEMI E57.

The BOLTS Plane is a vertical datum plane that is parallel to the Facial Datum Plane near the front of the tool where the loadport 211 is attached to the tool. This is substantially the same definition as in SEMI E63.

The HB1, HB2, and HB3 planes are horizontal planes from which projects kinematic-coupling pins (discussed in FIG. 35) on which each of the three carriers 201x-z sits. HB1 is at the bottom load height for FOUP 201x, HB2 is at the bottom load height for FOUP 201y, and HB3 is at the bottom load height for FOUP 201z. These planes might not be physically realized as a surface. These planes are applicable for Small Lot Loadport Configurations 240 that support the FOUP 201 using the bottom kinematic pin supports 260x-z via bottom kinematic coupling pins.

The HT1, HT2, and HT3 planes are horizontal planes from which projects a delta cradle formed by first and second blade receivers 121a, 121b, in which the top flange 113a of the FOUP 201x-z is captured. HT1 is at the top load height for FOUP 201x, HT2 is at the top load height for FOUP 201y, and HT3 is at the top load height for FOUP 201z. These planes might not be physically realized as a surface. These planes are applicable for SLLC 240 designs that support the FOUP 201 using the top kinematic delta flange 113a.

As the small lot substrate carriers 201x-z begins to dock at the loadports 211x-z, they move from the load face plane towards the BOLTS plane, and the carrier center moves from the facial datum plane undocked to the facial datum plane docked. Also shown are the bilateral datum plane, and the horizontal bottom planes and horizontal top planes of the carriers (e.g., HB1, HBT1; HB2, HT2; HB3, HT3) above the horizontal datum plane (HDP).

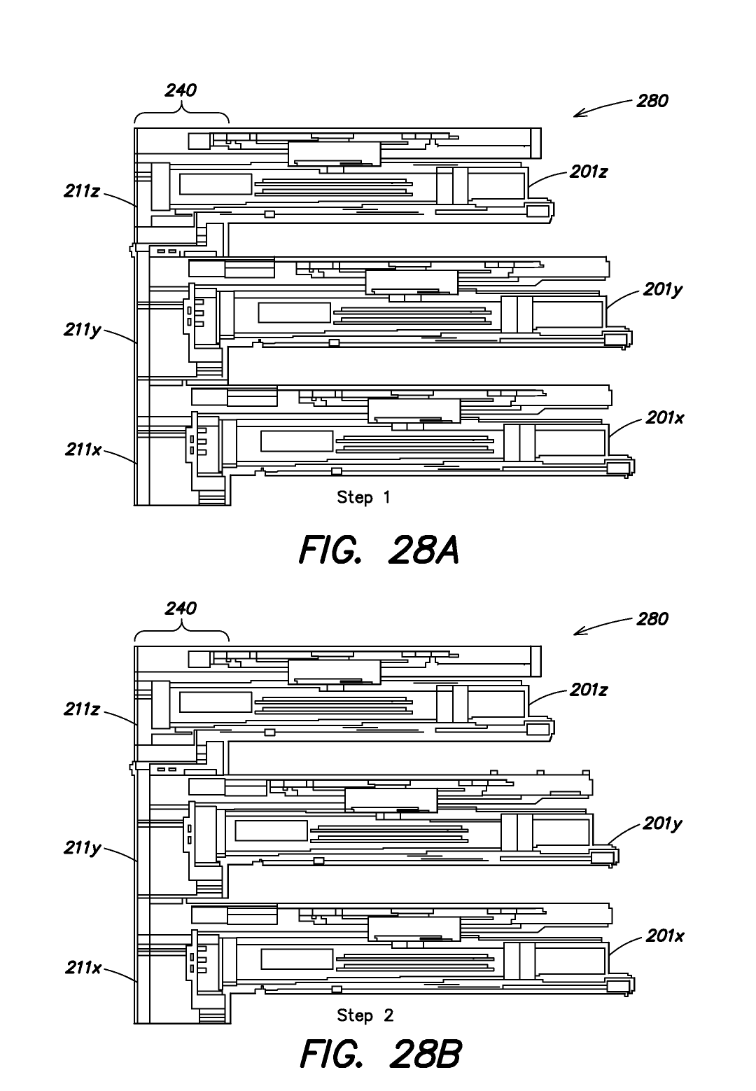

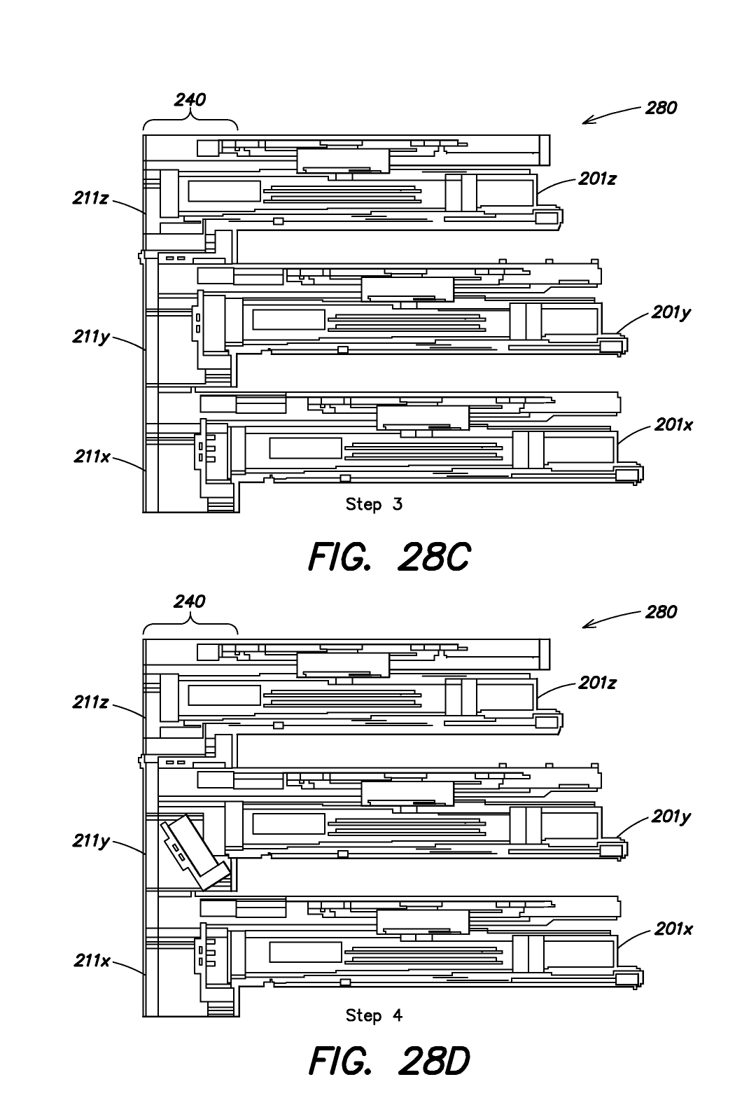

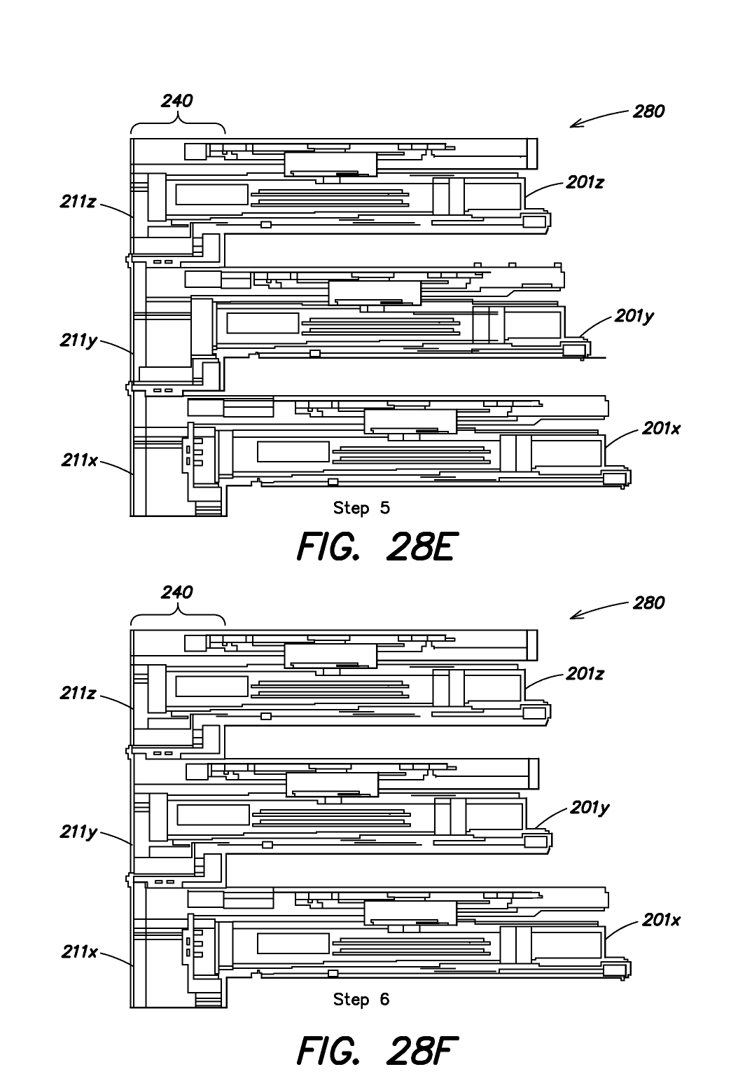

FIGS. 28A-F illustrate cross-sectional side elevational views of exemplary steps 1 to 6 of an exemplary small lot substrate carrier docking and opening sequence 280. In FIGS. 28A-F, the top carrier 201z remains in a docked and open position, whereas bottom carrier 201x remains in an undocked and closed position. Only middle carrier 201y changes positions, from an undocked and closed position in FIG. 28A, to a docked and open position in FIG. 28F.

The sequence shown in FIGS. 28A-F is one method that enables the FOUP 201y to be opened while meeting the general example requirements for independent operation outlined above. A prototype device using this preferred FOUP opening method for the SLLC 240 has been built and demonstrated by Applied Materials. Some of the various other acceptable methods within the scope of the present invention are discussed after the description of the steps.

The individual panels of FIGS. 28A-F show cross-section views of the loadport 211y during 6 steps in the opening sequence using the preferred FOUP opening method 280. In each of these panels, the middle FOUP 201y is being opened, while the top FOUP 201z is already open and in position for wafer transfer, and the bottom FOUP 201x is closed and in position for unloading.

In Step 1, the middle FOUP 211y has been placed on the loadport 211y by the robotic FOUP transfer device (not shown). The FOUP 211y is supported at the loadport 211y using the top kinematic delta flange 113a.

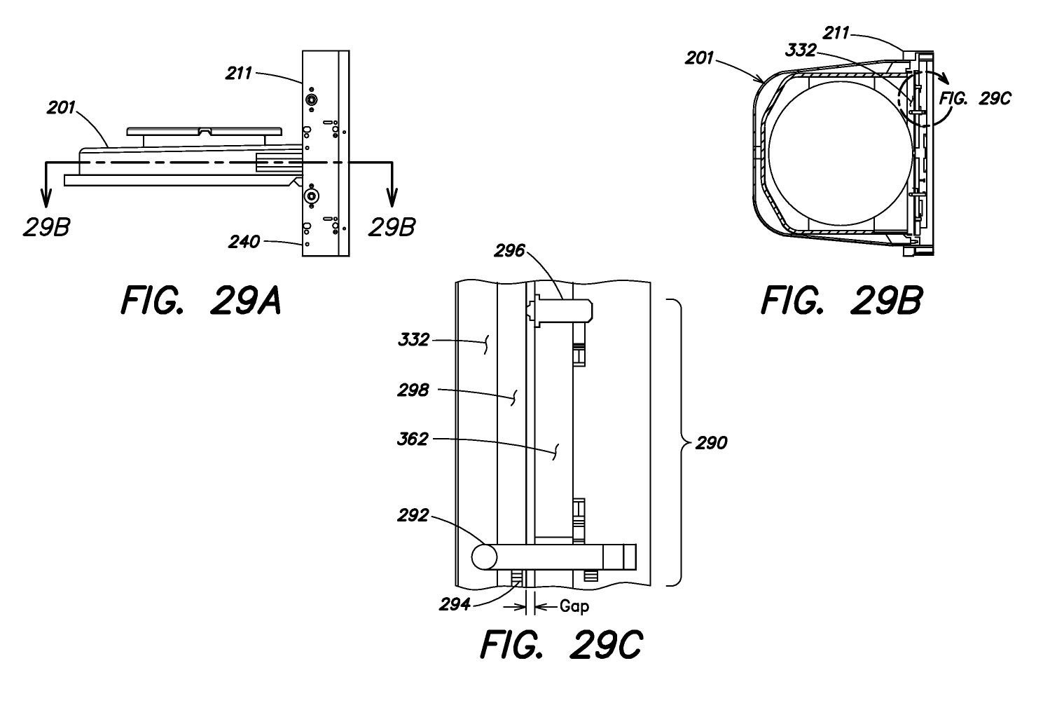

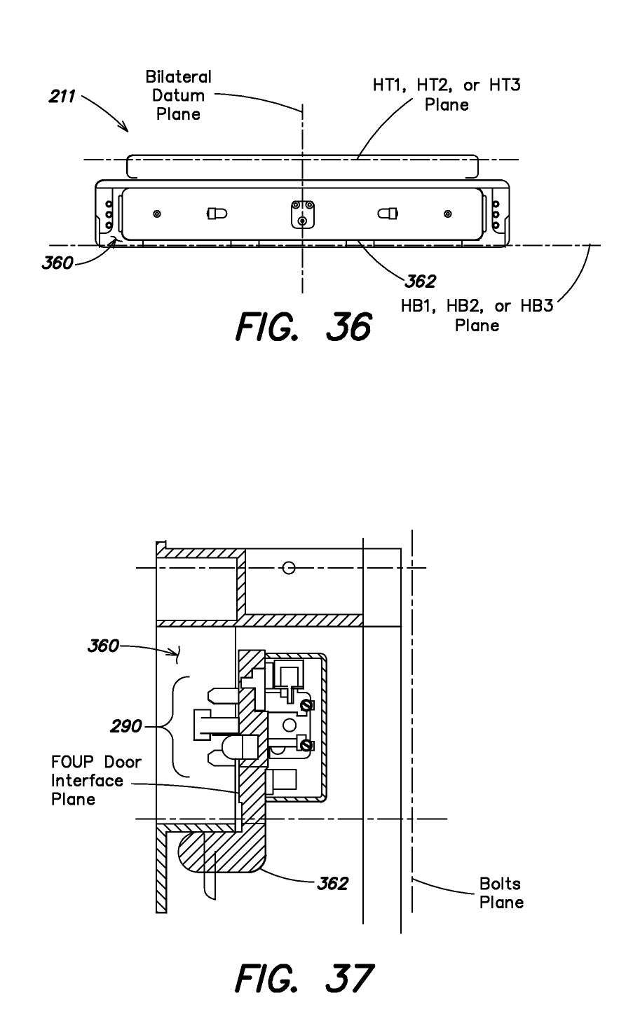

In Step 2, the FOUP 211y has moved forward to mate with a loadport port door 362, discussed in reference to FIGS. 36-38. At this time, the FOUP door 203, 332 can be unlocked and grasped by the loadport port door 362. An exemplary mechanism for locking/unlocking/grasping of the carrier door 203, 332 is disclosed in reference to FIGS. 29A-C, 33A-B, 34A-B, and 36-38. Preferably, mating with the port door 362 may only be completed successfully if the carrier interlock pins 410 and holes 394 are compatible, as discussed in reference to FIGS. 39-41.

In Step 3, the FOUP 201y has moved backward to allow extraction of the FOUP door 203, 332 out from the FOUP front opening. Preferably, the opening of the FOUP 201y may remain within the docking tunnel 360, discussed in reference to FIG. 36. In addition, the FOUP 201y preferably may completely disengage from the carrier interlock pins 410 located on the loadport port door 362. This allows the FOUP door 332 to be rotated to the stowed position in the next step.

In Step 4, the loadport port door 362 and FOUP door 332 begin to rotate toward the stowed position. During this rotation, preferably no part of the loadport mechanism or FOUP door 332 crosses the BOLTS plane. This may be required to ensure no interference with the EFEM robot that may occupy the space immediately adjacent to the BOLTS plane while accessing the other FOUPs 201 at the SLLC 240.

In Step 5, the loadport port door 362 and FOUP door 332 have completed rotating and are in the stowed position. In this position, the FOUP 201y and/or EFEM robot may pass above the door 332 without interfering with either the loadport port door 362 or the FOUP door 332.

In Step 6, the FOUP 201y has moved forward to the position in which the EFEM robot can access wafers in the FOUP 201y. At this point, the opening process is complete.

The preferred FOUP closing method is exactly the opposite of the FOUP opening method 280. The sequence of steps for closing follows the panels in FIGS. 28A-F backward from Step 6 through Step 1. As with the FOUP opening method 280, various other acceptable techniques exist within the scope of the invention.

While steps 1-6 of an exemplary door opening process 280 of FIGS. 28A-F, and door opening mechanism 290 discussed in reference to FIGS. 29A-C, involve a downward rotation of the carrier door 203 away from the carrier 201 (variations of which also are depicted in door opening mechanism 209′ of FIG. 18A-L, door opening mechanism 209″ of FIG. 20A-B and door opening mechanism 209′″ of FIGS. 22A-E), other door opening mechanisms are possible as well, such as:

rotating the door 203 upward away from the carrier 201 (such as mirror images along a horizontal plane of the mechanisms of FIGS. 18A-L, 22A-B, and 28A-F);

rotating the door 203 downward toward the carrier 201 (as shown in door opening mechanism 209 of FIGS. 17A-L);

rotating the door 203 upward toward the carrier 201 (such as a mirror image along a horizontal plane of the mechanism shown in FIGS. 17A-L);

displacing the door vertically, such as sliding it up or down after removal;

displacing the door horizontally, such as sliding it left or right after removal; and

other variations of displacement of the door 203 relative to the carrier 201 that would be within average design parameters selected by a person of ordinary skill in the art.

The door opening mechanisms 209, 209′, 209″, 209′″ and 290 are advantageous, however, to the extent that they permit opening and removal of the door 203 with minimal or no crossing of the BOLTS plane, as discussed above in reference to FIG. 25. By not crossing the BOLTS plane, the risk is reduced that the door opening mechanism would interfere with an EFEM robot, such as during an opening or closing sequence concurrent with a substrate extraction sequence, as mentioned in reference to FIG. 24.

A key functional difference between current 25-wafer loadport designs and the example requirements for the SLLC 240 is that the present invention may be able to independently operate each of the 3 door openers, regardless of the state of the other door openers. More specifically, the processes of opening, closing, loading, or unloading a FOUP 201 preferably may meet the following general example requirements:

be able to occur simultaneously with other actions on any other FOUP at the loadport;

have no affect on position or status of any of the other FOUPs at the loadport; and

have no mechanisms or components that cross the wafer planes of other FOUPs at the loadports.

FIGS. 29A-C illustrate an exemplary door opening mechanism 290 of a small lot substrate carrier 201. Respectively, FIG. 29A illustrates a side elevational view of a carrier 201 docked at a loadport 211; FIG. 29B illustrates a cross-sectional planar view of section A-A in FIG. 29A; and FIG. 29C illustrates an enlarged cross-sectional planar view of detail portion B in FIG. 29B. Door opening mechanism 290 includes an exemplary FOUP-compatible method of gripping the carrier door.

This document specifies a FOUP locking and unlocking mechanism 290 different than what is currently used on 25-wafer FOUPs and loadports, in which a key is turned to activate the lock/unlock mechanism. For the small lot FOUP 201y and small lot FOUP loadport 211y, a linear key motion may be used to activate the lock/unlock mechanism 290. There are 2 main reasons for specifying this change. The first is reliability.

Due to higher frequencies of use relative to higher capacity large lot substrate carriers, the cycle life example requirements for small lot devices are much higher than those for comparable 25-wafer devices. High reliability is extremely important for the SLLC 240. Because the small lot FOUP capacity is much smaller than the large lot FOUP capacity, the rate of FOUP open/close cycles may dramatically increase in order to maintain tool throughput. For example, an EFEM with 3 loadports must open/close each 25-wafer loadport 2.4× per hour to support high throughput (up to 180 wph) process equipment. The same EFEM must open/close each SLLC 240 an average of 30× per hour (10× per hour for each door opener) when 2-wafer FOUPs 201b are used.

Therefore, to meet the same MTBF specifications, the SLLC 240 may need to be able to perform 12.5× more cycles than current large FOUP loadport designs. The example requirements for SLLC 240 reliability preferably are as follows:

MTBF: 125,000 hours @80% confidence level

Assume 30 open/close cycles per hour (10 per hour at each door opener);

MTTR: less than 3 hours; and

Annual Failure Rate: less than 3%.

Most current 25-wafer loadports use a linear actuator with a mechanism to translate the actuator motion into key rotation. In addition, the large lot FOUP door may contain an additional mechanism to translate the key rotation into linear motion of the locking mechanism. By specifying a linear key motion, the translation mechanisms in the loadport and FOUP door can be eliminated, thereby simplifying the designs and improving inherent reliability. The second reason is space. As can be seen in the door opening sequence 280 in FIGS. 28A-F, the total thickness of the loadport port door 362 and the FOUP door 332 may be critical for achieving the desired 120 mm vertical FOUP spacing. By eliminating the translation mechanisms from the design, both the loadport port door 362 and the FOUP door 332 can be made thinner.

The process of unlocking the FOUP 201y preferably occurs at Step 2 of the sequence shown in FIGS. 28A-F. To unlock the FOUP 201y, the loadport 211y may first insert a key 292 into a mating keyhole 294 in the FOUP door 332. This should be done by positioning the key 292, which protrudes from the loadport port door 362, directly in front of a keyhole 294 while the FOUP 201y is in the loading/unloading position, and then moving the FOUP 201y forward to mate against the loadport port door 362. The key 292 should then be translated laterally toward the bilateral datum plane. The motion of the key 292 should activate the unlocking mechanism in the FOUP door 332, and the door 332 should unlock. The FOUP body can then be moved backward to extract the door 332 from the FOUP opening, and the remainder of the FOUP opening steps can continue.

The process of locking the FOUP 201y should occur at Step 2 of the reverse sequence shown in FIGS. 28A-F. To lock the FOUP 201y, the FOUP body should be moved forward to re-insert the FOUP door 332 into the FOUP opening and compress the seal between the FOUP door 332 and FOUP body. The key 292 should then be translated laterally away from the bilateral datum plane. The motion of the key 292 should activate the locking mechanism in the FOUP door 332, and the door 332 should lock. The locked FOUP 201y can then be moved backward away from the loadport port door 362 to the load/unload position.

The loadport port door 362 preferably may securely grip the FOUP door 332 between the time that the door 332 is unlocked and the time the door 332 is re-inserted into the FOUP 201 and locked. Many current 25-wafer loadport designs use vacuum and suction cups to provide this functionality. This present invention, however, discloses a novel preferred method for gripping the door discussed below.

FIGS. 29A-C show a diagram of the preferred door gripping mechanism, an aspect of door opening mechanism 290. Most of this discussion will focus on the “Detail View B” panel of the FIG. 29C, which shows a close-up cross-section view of the FOUP door 332 and loadport port door 362. In this view, the FOUP 201 is mated against the port door 362 and the FOUP door 332 is closed. Gripping of the FOUP door 332 preferably would occur in the way described as follows.

The FOUP 201 first may slide forward from the load/unload position to mate against the loadport port door 362 and latching keys 292 are aligned with keyholes 294 in the door 332. As the FOUP 201 slides forward, the door 332 will make contact with one or more spring-loaded gripping plungers 296. The FOUP 201 should continue to slide forward, compressing the gripping plungers until the gap between the FOUP door 332 and loadport port door 362 is negligible.

At this point, the FOUP door 332 is flush against the loadport port door 362, the gripping plungers 296 are compressed, and the latch keys 292 have been engaged with the latching mechanism in the FOUP door 332. Furthermore, the thickness of the FOUP door cover 298 preferably should be such that lateral latch key motion will not cause the keys 292 to rub against the inner surface of the FOUP door cover 298.

The latch keys 292 then move laterally to unlock the door 332. At this point, the lobes of the keys 292 will be directly behind, but not touching, the FOUP door cover 298.

The FOUP body preferably then moves backward to extract the FOUP door 332 from the mouth of the FOUP 201. During the initial portion of this motion, the spring-loaded plungers 296 will push against the FOUP door 332 causing it to also move backward slightly. The FOUP door 332 will move until the interior surface of the FOUP door cover 298 makes contact with the lobes of the latch keys 292 that were previously inserted into the door 332.

At this point, the FOUP door cover 298 is pinched between the lobes of the latch keys 292 and the gripping plungers 296, and will no longer move. The FOUP body continues to move backward, leaving the FOUP door 332 gripped by the loadport port door 362.

This method 290 may be the preferred method for door gripping for several reasons. For example, the door 332 remains gripped even if power or facilities are lost for an extended period of time. Other methods, particularly those that employ vacuum, are susceptible to dropping the door 332 when vacuum pressure is lost due to tool shutdown, EMO, leaky facilities lines, etc. Also, this method 290 eliminates consumables such as suction cups that typically must be replaced frequently. When a small lot AMHS is used, a local buffer may be located in front of each EFEM, which could severely restrict access to the loadports. Therefore, the SLLC 240 preferably is designed with minimal requirements for preventative maintenance (such as replacement of consumable components). In addition, this method 290 eliminates additional active components, actuators, and sensors that are necessary for gripping the door 332, which simplifies the design, reduces cost, and enables a thinner port door design.

Alternatively, the vacuum and suction cup gripping method can be used if a loadport supplier chooses. In addition, other acceptable methods fall within the scope of the general invention.

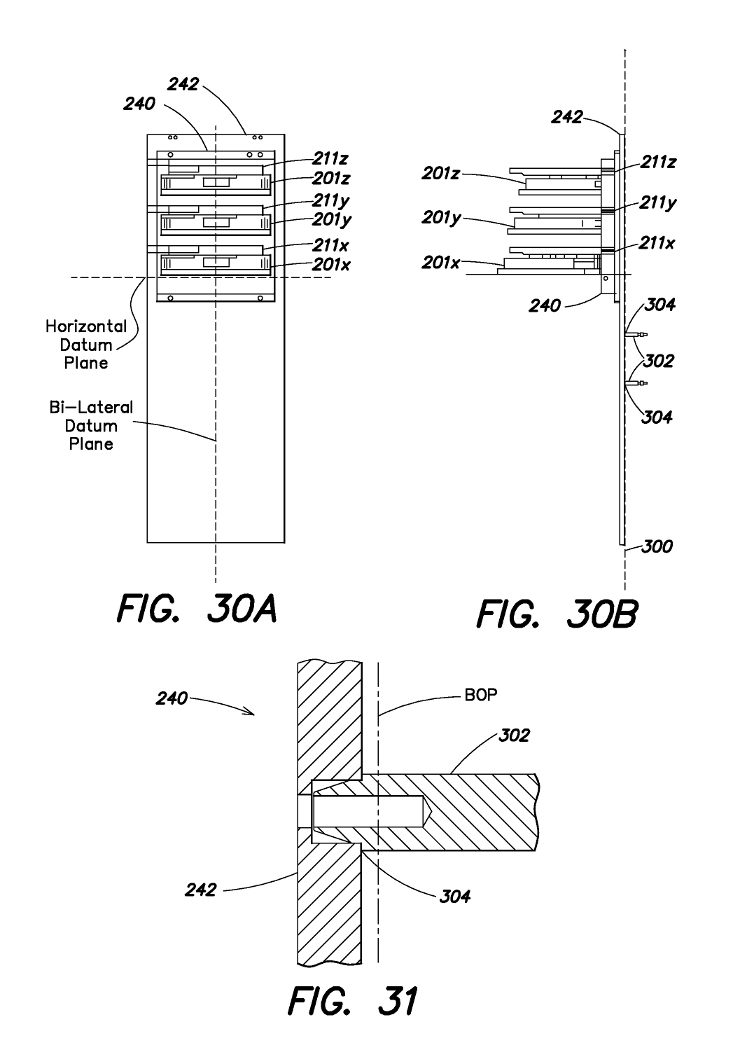

FIGS. 30A and 30B illustrate, respectively, a front elevational view and a side elevational view of an exemplary small lot loadport configuration (SLLC) 240 as it may mount on an equipment front end module (EFEM) 300 (represented by mounting posts 302 from the EFEM 300). The mounting posts 302 comprise an exemplary mounting interface 304 for mounting the SLLC 240 to EFEM 300. The SLLC 240 may be able to be mounted to the EFEM 300 using at least 3 of the 6 bolt holes specified in SEMI E63, Section 5.5. In addition, the SLLC 240 may comply with a datum plate post-mounting method. To comply with this mounting method, the SLLC 240 preferably has the features defined as shown in FIGS. 30A-B and 31.

FIG. 31 illustrates an enlarged cross-sectional side elevational view of a detail portion of FIG. 30B. An exemplary mounting interface 304 between the SLLC 240 and the EFEM 300 is shown in greater detail.

FIG. 32 depicts a cross-sectional side elevational view of exemplary small lot substrate carriers 201x-z supported by shelves 175x-z at various stages of docking at loadports 211x-z on an SLLC 240. FIG. 32 and FIG. 28E depict similar stages of three small lot substrate carriers 201x-z. FIG. 32, however, also depicts details of three exemplary FOUP-style carriers 201x-z adapted to fit and operate within a large lot loadport envelope 254 of a large lot loadport 250 conforming to a standard BOLTS opening 256 for a 25-substrate FOUP-style carrier 252. The key overall clearances and dimensions are shown for exemplary FOUPs 201x-z that are of 2-substrate capacity sort such as small lot carriers 201b. Whereas FIGS. 27A-C depict categorical plane definitions, FIG. 32 depicts details of an exemplary FOUP-compatible embodiment of small lot loadport configuration 240.

As shown in FIGS. 27A-C, which identify relevant datum planes for the SLLC 240, the vertical spacing between the 3 FOUPs 201x-z and door opening mechanisms preferably may be a predefined dimension, e.g., 120 mm. This spacing was chosen so that 3 FOUPs 201x-z and opening mechanisms can fit in the envelope of a current 25-wafer FOUP and opening mechanism. With this spacing, the bottom wafer in the lower FOUP 201x will be at the same plane as wafer #1 in a 25-wafer FOUP. Furthermore, the bottom wafer in the upper FOUP 201z will be at the same plane as wafer #25 in a 25-wafer FOUP (the top wafer will be at the wafer #26 position).

The SLLC 240 may maintain adequate clearances for the end-effector of the robotic device that delivers/removes FOUPs 201 from the loadports 211, as well as clearances for the FOUPs 201 themselves. FIG. 32 shows an example of the overall dimensions of the SLLC 240 to meet the minimum clearance example requirements for a preferred embodiment of the FOUP and robotic end-effector. The illustration in FIG. 32 assumes that the loadports 211x-z support the FOUPs 201x-z using the top kinematic flange 113a. Bottom kinematic pin supports 260x-z are also acceptable, provided that the key clearances remain the same.

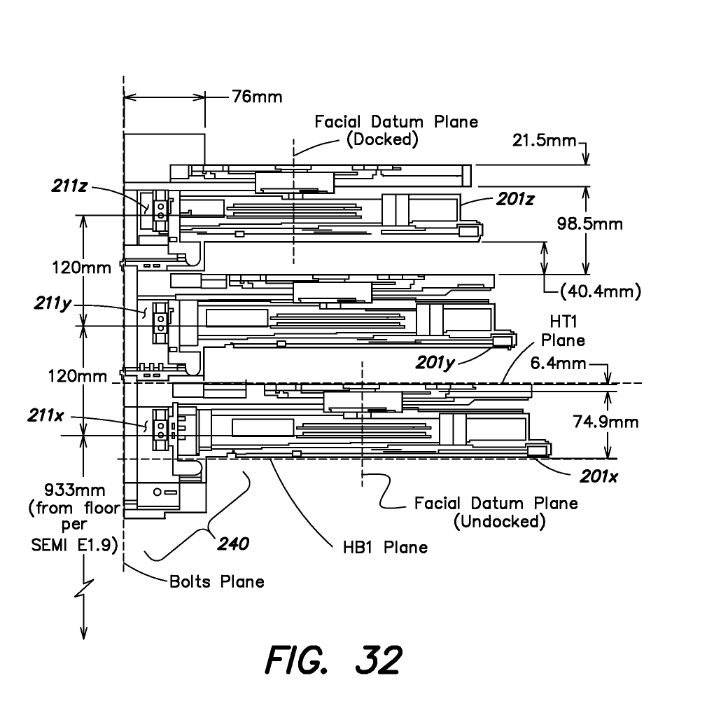

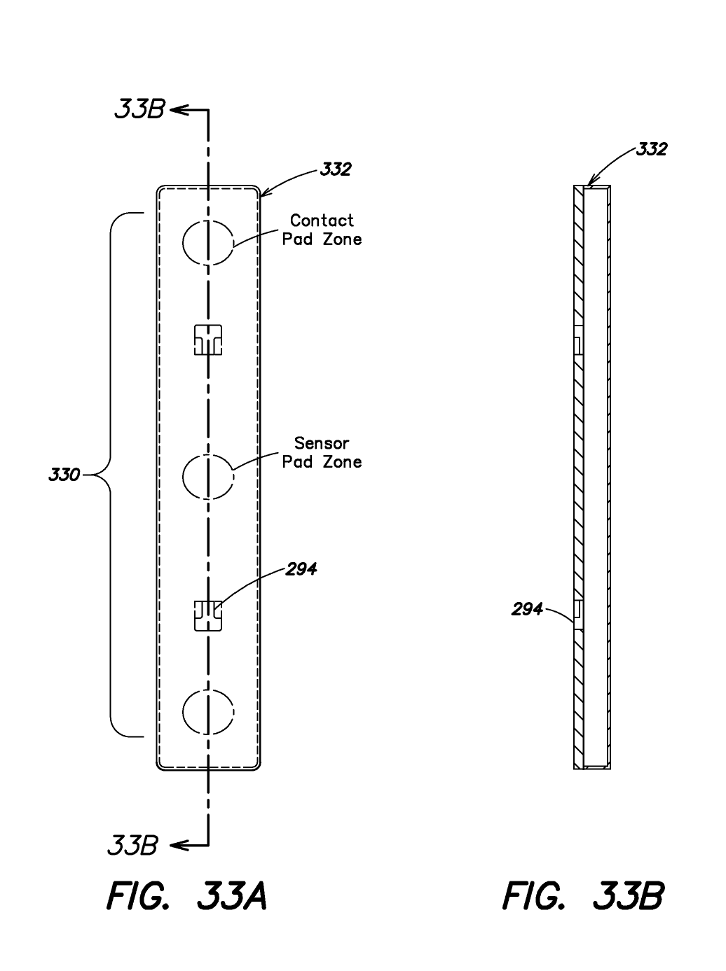

FIGS. 33A and 33B illustrate, respectively, a front exterior elevational view and a cross-sectional planar view of an exemplary carrier door and exemplary loadport port door interface 330 designed to be FOUP-compatible. Loadport port door interface 330 is the interface between carrier door 332 and a port door of the loadport 211. Interface 330 interoperates with the port door to open and close access to an attached small lot substrate carrier 201. Details of the port door are provided in FIGS. 36 and 37.

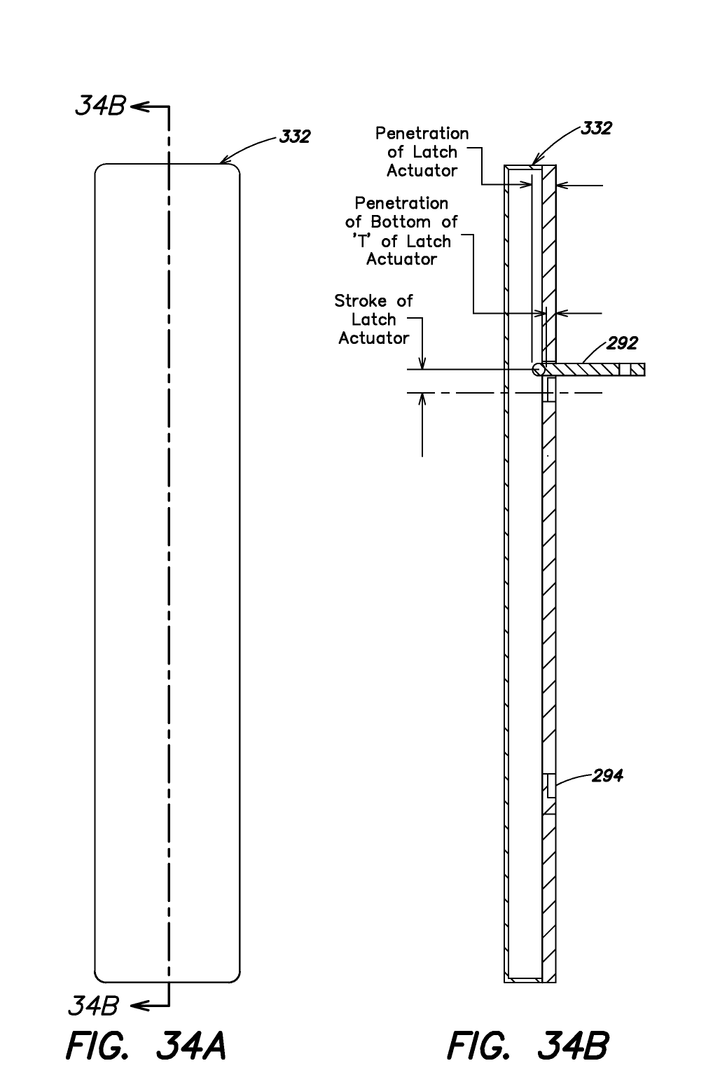

The interface between the loadport port door 362 and FOUP door 332 preferably provides features for (1) Insertion of the latch key from the port door into the latching mechanism in the FOUP; (2) Surface for a door presence sensor; and (3) Surfaces for contact points or vacuum points for gripping the FOUP door. The locations and dimensions of each of these features are defined in FIGS. 33-34.

Whereas FIGS. 22A-E illustrate a fourth exemplary embodiment of a door opening mechanism 209′″ for opening the door 203 of the substrate carrier 201a, FIGS. 33A and 33B relate to the exemplary embodiment of small lot substrate carrier 201 shown in FIGS. 27A-C and the related loadport 211 of an SLLC 240 designed to FOUP-compatible. Otherwise, much of the general description of the door opening mechanism 209′″ may be applied the exemplary loadport port door interface 330.

FIGS. 34A and 34B illustrate, respectively, a rear interior elevational view and a cross-sectional planar view of the exemplary carrier door and exemplary loadport port door interface of FIGS. 33A and 33B. FIG. 34B depicts the penetration and stroke of action of an exemplary latch actuator 292 used to open the door 332. As shown also in FIGS. 29B and 29C, two latch actuators 292, also referred to as keys or latch keys, extend from the loadport 211 and engage the door 332 to open it.

FIG. 35 illustrates a front planar view of an exemplary kinematic pin support 260y comprising a loadport shelf 350 and kinematic coupling pins 352. Use of kinematic coupling pins 352 is described in more detail in related U.S. patent application Ser. No. 10/650,310, filed Aug. 28, 2003, and titled “System For Transporting Substrate Carriers” (Attorney Docket No. 6900) and related U.S. patent application Ser. No. 10/988,175, filed Nov. 12, 2004, and titled “Kinematic Pin With Shear Member And Substrate Carrier For Use Therewith” (Attorney Docket No. 8119). Kinematic pins 352 couple the loadport shelf 350 and a small lot substrate carrier 201 as the pins 352 align with corresponding kinematic pin mating features (not shown) as a robot blade 354 transfers the carrier 201 to the shelf 350.

As with current 25-wafer FOUP designs, the bottom of the FOUP preferably provides grooves for capturing primary and secondary kinematic coupling pins 352. Similarly, the bottom of the small lot FOUP 201 also provides grooves for primary and secondary kinematic coupling pins 352; however, the position of these grooves is different from that specified in SEMI E57, as discussed in related U.S. patent application Ser. No. 10/988,175, filed Nov. 12, 2004, and titled “Kinematic Pin With Shear Member And Substrate Carrier For Use Therewith” (Attorney Docket No. 8119). Nonetheless, the size and shape of the pins substantially conforms to the SEMI E57, Section 5.1.

These primary and secondary pins 352 can be used such that the loadport 211 can support the FOUP 201 from below using a first set of pins 352, and the robotic device that delivers FOUPs 201 to the loadport 211 can support the FOUP 201 from below using another set of pins 352. FIG. 35 shows the space allocated for a shelf 260y that supports the FOUP 201 using the bottom kinematic coupling pins 352.

FIG. 36 illustrates a front elevational view of an exemplary loadport tunnel 360 of the exemplary loadport 211 of the exemplary SLLC 240. Within loadport tunnel 360 is loadport port door 362

FIG. 37 illustrates an enlarged side elevational cross-sectional view of the loadport tunnel 360 and an exemplary door opening mechanism 290 associated with the loadport port door 362.

As discussed above, the FOUP opening sequence 280 defined in FIGS. 28A-F specifies that the FOUP 201y be moved backward after the FOUP door is unlocked and gripped to extract the door 332 from the body of the FOUP 201y. Note that this motion is not required or allowed in current 25-wafer loadport designs because the door is moved backward while the FOUP body is held stationary. During this motion of the FOUP 201y in sequence 280, it is extremely important for particle performance that dirty air from outside the loadport area may not enter the FOUP 201y. Therefore, the opening of the FOUP 201y preferably may remain inside a clean “tunnel” 360 at all times while the door 332 is unlocked. The tunnel 360 preferably may extend, at minimum, from the face of the loadport port door 362 to a distance greater than the FOUP travel during door extraction, as is depicted in FIGS. 36 and 37.

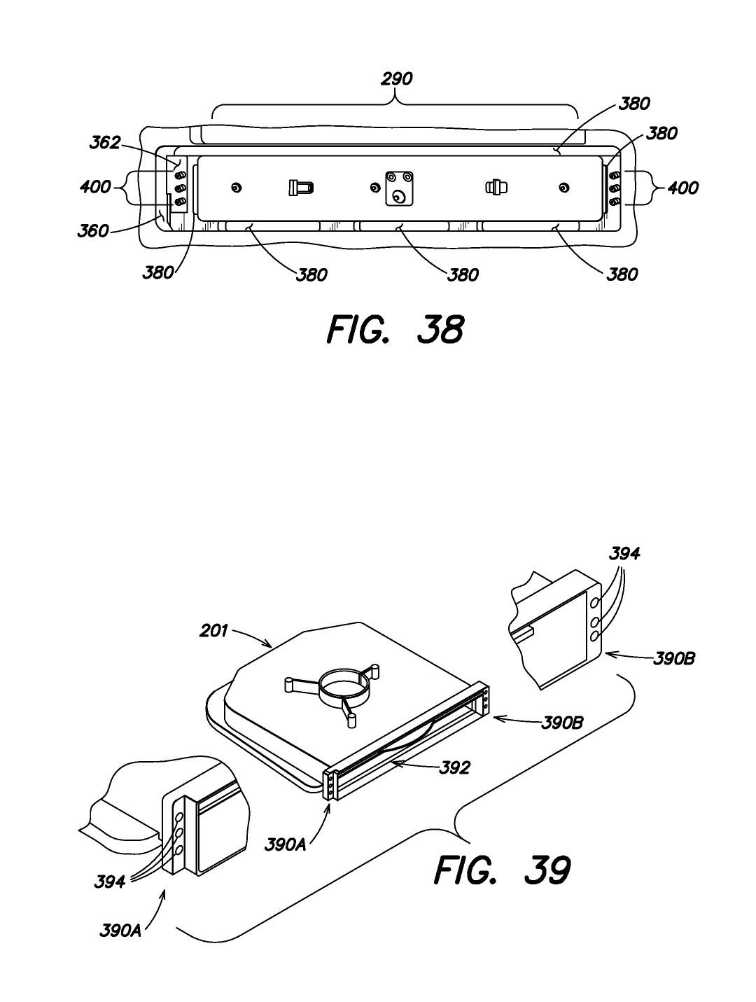

FIG. 38 illustrates a front perspective view of the loadport tunnel 360, loadport port door 362 and external aspects of the door opening mechanism 290. Also depicted are airflow slots 380 in the loadport port door 362 adapted for use in supplying clean air under pressure to keep dust and contaminants out of the system.

Analysis and experience with current 25-wafer FOUP and loadport designs has shown that the motion of extracting the door from the FOUP opening produces a slight low pressure region inside the FOUP, causing air to be drawn into the FOUP from around the perimeter of the door. The volume of air that is drawn in is equal to the displaced volume of the FOUP door. Many loadport suppliers have carefully tuned the motion profile of the door extraction to minimize this effect.

For the small lot substrate carrier 201, it is expected that this problem may be even more severe, since the volume of the small lot FOUP door 332 relative to the interior cavity of the FOUP 201 is much larger. Therefore, it is preferred that the loadport port door 362 have slots 380, gaps, or other openings located around the perimeter of the FOUP door 332 so that air from inside the EFEM can flow through the loadport port door 362 and bathe the perimeter of the FOUP door 332 with clean air. This will ensure that any air that is drawn into the FOUP 201 during door extraction will be clean air from inside the EFEM, and not dirty air from the surrounding environment. FIG. 38 shows a possible implementation of such features. The exact size, shape, and location of these features are at the discretion of the loadport supplier. However, experimental data and/or flow modeling analysis for a given design preferably should show that airflow through the loadport port door 362 is sufficient to prevent dirty air from entering the FOUP 201.

FIG. 39 illustrates a front perspective view of an exemplary small lot substrate carrier 201 with enlarged cut-away views of carrier configuration features 390A and 390B. Carrier configuration features 390A and 390B are to the left and right, respectively, of the substrate access port 392 of the carrier 201. Carrier configuration feature 390A is shown as being offset from a plane of the substrate access port 392, whereas carrier configuration feature 390B is shown as being coplanar with the substrate access port 392. The carrier configuration features 390A,B may include, for instance, front carrier interlock holes 394 as means of identifying the carrier configuration and limiting interoperability of the carrier 201y to loadports having corresponding configuration features. Carrier interlock features are features that can be configured to prevent particular types of FOUPs 201 from being opened at an incompatible tool type.

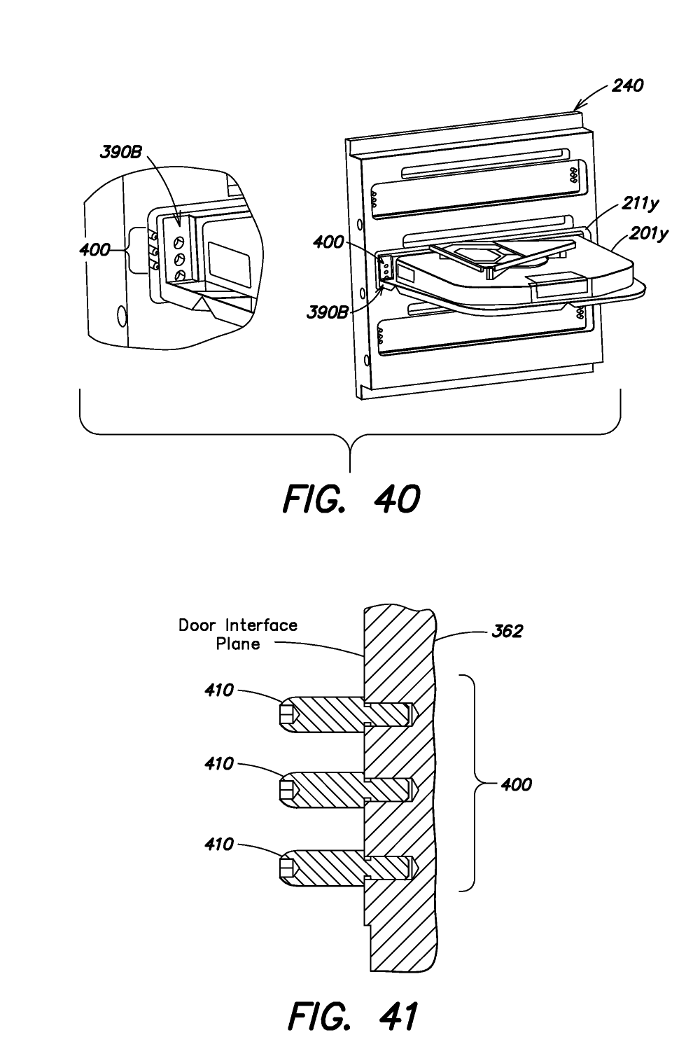

FIG. 40 illustrates a front perspective view and an enlarged cut-away view of an exemplary small lot loadport configuration 240 and an exemplary small lot substrate carrier 201y. The exemplary small lot substrate carrier 201y is shown in position relative to loadport 211y for docking or loading to the carrier opening mechanism 290, whereby the carrier 201y would move forward to the loadport 211y toward the door opener for docking. As shown in the enlarged cut-away view, depicting the carrier configuration feature 390B and corresponding configuration feature 400 of carrier opening mechanism 290 on the loadport 211y, a match between the carrier configuration feature 390B and corresponding configuration feature 400 will allow the carrier opening mechanism 290 to open the carrier 201y.

In current 25-wafer loadports, carrier interlock features are called “InfoPads,” and consist of a configurable set of pins that are placed on the loadport near the kinematic coupling pins and mate with configurable holes on the bottom of the FOUP. If an attempt is made to place a FOUP on a loadport with a pin configuration that is incompatible with the FOUP's hole configuration, the pin(s) will prevent proper placement of the FOUP on the loadport. In this case, FOUP handoff fails and the AMHS must pick the FOUP up and await further instruction, or simply stop and wait for operator intervention.

For the SLLC 240, similar interlock functionality is preferred; however, FOUP handling by the AMHS and/or local buffer robot preferably is not be affected by incompatible interlock features. In the 25-wafer example from the previous paragraph, the interlock features prevented successful FOUP handoff, and as such, the AMHS was stuck, which would be a very undesirable result for a small lot AMHS. For the SLLC 240, FOUP handoff preferably is not be affected—only successful opening of the FOUP preferably is prevented.

FIG. 39 shows a generic model of a small lot substrate carrier 201 that has configurable forward-facing interlock hole features 390A and 390B. FIG. 40 shows the mating of these hole features 394 with corresponding features 400 in the form of rear-facing interlock pins 410 on the loadport. Using this feature configuration, the FOUP 201y may always be successfully placed on the loadport using either the bottom kinematic coupling pins 352 or top kinematic flange 113a, regardless of the interlock pin/hole configuration. However, the FOUP 201y only may be able to slide successfully forward and mate with the loadport door opening mechanism if the pin/hole configurations are compatible. In the case where the pins/holes may not be compatible, the loadport 211y may (1) recognize that the FOUP 201y was not able to mate with the door opening mechanism; (2) return the FOUP 201y to the position for loading/unloading by the AMHS and prepare for unloading; and (3) report the appropriate error message to the EFEM 300.

FIGS. 36 and 38 show examples of the key size and location dimensions for the interlock pin features on each port door plate of the SLLC 240. Note that these features are located on the loadport port door plate, as opposed to the port door 362, and engage with the FOUP 201 when the FOUP 201 moves forward to the FOUP Interface Plane to mate with the door opening mechanism 290.

FIG. 41 illustrates an enlarged cross-sectional side elevational view of the corresponding configuration feature 400. Corresponding configuration feature 400 may include one or more interlock pins 410 adapted to fit within front carrier interlock holes 394.

Unlike current 25-wafer loadports, the SLLC 240 is not intended for manual loading/unloading of FOUPs 201 by human operators. Furthermore, a local FOUP buffer preferably is located in front of each EFEM 300 on which the SLLC 240 is used. This local buffer completely will enclose the loadport exclusion volume, may block operator access to the loadport, and likely may prevent viewing of the SLLC 240 from outside the tool. As such, there may be no requirement for status indicator LEDs/lamps or operation switches on the SLLC 240, and the recommended placement locations for these features as specified in SEMI E110 may not apply. A power indicator LED/lamp may be provided at the discretion of the loadport supplier.

The following non-exhaustive list discloses various loadport status conditions that preferably may be detectable by the loadport. It is left to the discretion of the loadport supplier to determine what sensors (encoders, opto switches, through-beam sensors, etc.) to use to determine each condition:

FOUP present (at each opener)

FOUP well placed (at each opener);

FOUP docked against loadport port door (at each opener);

FOUP at AMHS load/unload position (at each opener);

FOUP at EFEM wafer access position (at each opener);

FOUP door gripped by loadport port door (at each opener);

Port door latch key in locked position (at each opener);

Port door latch key in unlocked position (at each opener);

Port door in closed position (at each opener);

Port door in open position (at each opener);

Loadport vacuum supply OK (if loadport requires vacuum for operation);

Loadport CDA supply OK (if loadport requires CDA for operation);

FOUP clamped (at each loadport, if loadport provides optional clamping mechanism); and

FOUP released (at each loadport, if loadport provides optional clamping mechanism).

The following additional status conditions optionally may be detectable at the discretion of the loadport supplier: (1) Carrier interlock flag (i.e. infopad) status (at each opener); (2) Crash beam (at each opener); and (3) Safety frame sensor (at each opener).

Accordingly, while the present invention has been disclosed in connection with exemplary embodiments thereof, it should be understood that other embodiments may fall within the spirit and scope of the invention, as defined by the following claims.

The invention claimed is:

1. A system comprising:
an equipment front end module (EFEM) designed for use with a large lot substrate carrier and having a large lot loadport envelope; and
a small lot loadport configuration having a plurality of small lot loadports adapted to be coupled to the EFEM and having a combined envelope substantially similar to the large lot loadport envelope,
wherein each small lot loadport adapted to dock with a small lot substrate carrier.

2. A substrate handling apparatus comprising:
a small lot loadport configuration (SLLC) including a plurality of small lot loadports, each small lot loadport adapted to dock with a small lot substrate carrier;
wherein the SLLC is adapted to be coupled to an equipment front end module (EFEM) designed for use with a large lot substrate carrier and having a large lot loadport envelope; and
wherein the SLLC has a combined envelope substantially similar to the large lot loadport envelope.

3. A method comprises:
docking of a small lot substrate carrier at a small lot loadport within a small lot loadport configuration coupled to an equipment front end module (EFEM) designed for use with a large lot substrate carrier and having a large lot loadport envelope, where the small lot loadport configuration includes a plurality of small lot loadports adapted to be coupled to the EFEM and has a combined envelope substantially similar to the large lot loadport envelope, where each small lot loadport is adapted to dock with a small lot substrate carrier.

4. The method of claim 3 further comprising:
undocking, opening and/or closing of the small lot substrate carrier by the small lot loadport.
